(19) United States
(12) Patent Application Publication
(10) Pub. No.: US 2023/0413593 A1
(43) Pub. Date: Dec. 21, 2023

(54) ORGANIC ELECTROLUMINESCENT DEVICE AND DISPLAY DEVICE

(71) Applicants: KunShan Go-Visionox Opto-Electronics Co., Ltd, Kunshan (CN); TSINGHUA UNIVERSITY, Beijing (CN)

(72) Inventors: Minghan CAI, Jiangsu (CN); Lian DUAN, Jiangsu (CN); Guomeng LI, Jiangsu (CN); Mengzhen LI, Jiangsu (CN); Hongyu WANG, Jiangsu (CN); Fangyi CAO, Jiangsu (CN)

(73) Assignees: KunShan Go-Visionox Opto-Electronics Co., Ltd, Kunshan (CN); TSINGHUA UNIVERSITY, Beijing (CN)

(21) Appl. No.: 18/461,717

(22) Filed: Sep. 6, 2023

Related U.S. Application Data
(63) Continuation of application No. PCT/CN2022/115460, filed on Aug. 29, 2022.

(30) Foreign Application Priority Data
Dec. 31, 2021 (CN) 2021116813079

(51) Int. Cl. H10K 50/12; H10K 85/60; C09K 11/06

(52) U.S. Cl. CPC H10K 50/121; H10K 85/658; C09K 11/06; C09K 2211/1018

(57) ABSTRACT

An organic electroluminescent device and a display device. The organic electroluminescent device includes a first functional layer, a light-emitting layer, and a second functional layer that are sequentially stacked. The light-emitting layer includes a host material, a sensitizer, and a dye; the light-emitting layer includes N sections in a stacking direction, with a first section being in contact with the first functional layer and a N^{th} section being in contact with the second functional layer, N>1; where among the N sections, a section with the highest dye content is the highest critical section, where D₁<Dₘₐₓ and D₁≤Dₒₜₕₑᵣ, and/or D_{N}<Dₘₐₓ and D_{N}≤Dₒₜₕₑᵣ. The special composition of the light-emitting layer of the organic electroluminescent device can effectively reduce a probability that carriers are captured by the dye, thereby making the organic electroluminescent device have high luminescence efficiency by suppressing exciton quenching.

### CROSS-REFERENCE TO RELATED APPLICATIONS

The present application is a continuation of International Application No. PCT/CN2022/115460, filed on Aug. 29, 2022, which claims priority to Chinese patent application No. 202111681307.9, filed with China National Intellectual Property Administration on Dec. 31, 2021, titled with “ORGANIC ELECTROLUMINESCENT DEVICE AND DISPLAY DEVICE”. Both of the above applications are hereby incorporated by reference in their entireties.

### TECHNICAL FIELD

The present application relates to an organic electroluminescent device and a display device, belonging to the field of organic electroluminescence technology.

### BACKGROUND

Organic electroluminescent device is a device for achieving a purpose of luminescence through current driving. Specifically, the organic electroluminescent device includes a cathode, an anode, and a functional layer (such as a light-emitting layer) located between the cathode and anode. When applying voltage, electrons from the cathode and holes from the anode will migrate towards the light-emitting layer and combine to produce excitons respectively, emitting light with different wavelengths based on properties of the light-emitting layer.

Currently, the blue light-emitting materials used in the organic electroluminescent device on the production line are mainly common triplet-triplet annihilation (TTA) material, which uses the annihilation effect of triplet excitons to increase a total amount of singlet excitons. In theory, an extreme efficiency of TTA can only reach 62.5%, and in practical application, its exciton utilization rate is often lower than 62.5%. The red and green light-emitting materials are mainly phosphorescent material. However, the phosphorescent material has defects such as large half-peak width and poor color purity, and the phosphorescent material is too high in cost and not environmentally friendly due to the presence of precious metals therein.

In addition, Thermally Activated Delayed Fluorescence (TADF) material is widely applied to the luminescent material for organic electroluminescent device. The TADF material can simultaneously use the singlet exciton with a probability of 25% and the triplet exciton with a probability of 75%, but there is still a problem that the luminescence efficiency of the device cannot meet the demand in TADF device.

### SUMMARY

The present application provides an organic electroluminescent device and a display device with the characteristics of high luminescence efficiency.

The present application provides an organic electroluminescent device, including a first functional layer, a light-emitting layer, and a second functional layer that are sequentially stacked, the light-emitting layer includes a host material, a sensitizer, and a dye; the light-emitting layer includes N sections in a stacking direction, with a first section being in contact with the first functional layer and a N^{th} section being in contact with the second functional layer, N>1; where among the N sections, a section with the highest dye content is the highest critical section,
where, D₁<Dₘₐₓ and D₁≤Dₒₜₕₑᵣ, and/or D_{N}<Dₘₐₓ and D_{N}≤Dₒₜₕₑᵣ,
where, D₁ is a dye content in the first section, D_{N} is a dye content in the N^{th} section, Dₘₐₓ is a dye content in the highest critical section, and Dₒₜₕₑᵣ is a dye content in other section.

The organic electroluminescent device of the present application includes the first functional layer, the light-emitting layer, and the second functional layer that are sequentially stacked, where the dye contents of the sections of the light-emitting layer in contact with the first functional layer and second functional layer respectively are relatively low. Therefore, even if these two sections have a high carrier concentration, the lower dye content in these two sections will significantly reduce a probability that carriers are captured by the dye, so that the luminescence efficiency can be significantly improved by increasing the utilization rate of excitons.

### BRIEF DESCRIPTION OF DRAWINGS

FIG. 1 is a front view of multi-source co-evaporation of a light-emitting layer for an organic electroluminescent device according to Example 1 of the present application.

FIG. 2 is a top view of FIG. 1.

FIG. 3 is a front view of multi-source co-evaporation of a light-emitting layer for an organic electroluminescent device according to Comparative Example 1 of the present application.

FIG. 4 is a top view of FIG. 3.

FIG. 5 is a schematic diagram of distribution patterns (P1 to P6) of the dye content in a light-emitting layer of an organic electroluminescent device according to an embodiment of the present application.

FIG. 6 is a schematic diagram of distribution patterns (P3, P7, and P8) of the dye content in a light-emitting layer of an organic electroluminescent device according to an embodiment of the present application.

FIG. 7 is a schematic diagram of distribution patterns (P3, P9, and P10) of the dye content in a light-emitting layer of an organic electroluminescent device according to an embodiment of the present application.

FIG. 8 is a schematic diagram of distribution patterns (P3, and P21 to P24) of the dye content in a light-emitting layer of an organic electroluminescent device according to an embodiment of the present application.

FIG. 9 is a schematic diagram of distribution patterns (P3, and P11 to P13) of the dye content in a light-emitting layer of an organic electroluminescent device according to an embodiment of the present application.

FIG. 10 is a schematic diagram of distribution patterns (P3, and P14 to P16) of the dye content in a light-emitting layer of an organic electroluminescent device according to an embodiment of the present application.

FIG. 11 is a schematic diagram of distribution patterns (P3, and P17 to P20) of the dye content in a light-emitting layer of an organic electroluminescent device according to an embodiment of the present application.

### DETAILED DESCRIPTION OF EMBODIMENTS

In order to make the purpose, technical solution, and advantages of the present application clearer, the following will provide a clear and complete description of the technical solution in the embodiments of the present application in combination with the embodiments of the present application. Obviously, the described embodiments are a part of the embodiments of the present application, not all of them. Based on the embodiments of the present application, all other embodiments obtained by ordinary technical person in the art without creative work fall within the protection scope of the present application.

A first aspect of the present application provides an organic electroluminescent device including an anode, a first functional layer, a light-emitting layer, a second functional layer, and a cathode that are sequentially arranged on a substrate. Where, the substrate, anode, and cathode can use materials commonly used in the art. For example, the substrate can be made of glass or a polymer material with excellent mechanical strength, thermal stability, waterproofing, and transparency; the anode material can use a transparent conductive material such as indium tin oxide (ITO), indium zinc oxide (IZO), tin dioxide (SnO₂), zinc oxide (ZnO), and other oxide and any combination thereof; the cathode material can use a metal or an alloy such as magnesium (Mg), silver (Ag), aluminum (Al), aluminum-lithium (Al—Li), calcium (Ca), magnesium-indium (Mg—In), magnesium-silver (Mg—Ag), and any combination thereof.

The first functional layer of the present application is provided between the anode and the light-emitting layer, and is mainly used to transmit the holes generated by the anode to the light-emitting layer. Further, according to its composition, the first functional layer can also intercept the entry of electrons from the cathode. Specifically, the first functional layer includes a hole injection layer and/or a hole transmission layer along a direction of the anode towards the light-emitting layer, and further includes an electron blocking layer.

The second functional layer of the present application is provided between the light-emitting layer and the cathode, and is mainly used to transmit electrons generated by the cathode to the light-emitting layer. Further, according to its composition, the second functional layer can further intercept the entry of holes from the anode. Specifically, the second functional layer includes an electron injection layer and/or an electron transmission layer along a direction of the cathode towards the light-emitting layer, and further includes a hole blocking layer.

The light-emitting layer of the present application includes a host material, a sensitizer, and a dye. In a thickness direction of the light-emitting layer, the light-emitting layer of the present application includes N sections (N>1). In an implementation, N sections can be obtained by cutting the light-emitting layer along a horizontal tangent line that gradually moves in the thickness direction (an extension direction of the horizontal tangent line is perpendicular to the thickness direction). The N sections that form the light-emitting layer all contain dye, but the dye contents of respective sections are not exactly the same. The present application does not limit the physical meaning of the dye content, for example, it may be g/cm², mol/cm², etc., as long as it can be used for parallel numerical comparison between respective sections.

Specifically, the section with the highest dye content among the N sections is called the highest critical section; the section in contact with the first functional layer is called the first section; and the section in contact with the second functional layer is called the N^{th} section. Sections other than the highest critical section, the first section and the N^{th} section are called other sections. In the present application, the dye content of the first section is D₁, the dye content of the second section is D_{N}, the dye content of the highest critical section is Dₘₐₓ, and the dye content of other section is Dₒₜₕₑᵣ.

The organic electroluminescent device of the present application contains the sensitizer, so it is possible to improve the luminescence efficiency by sensitizing the dye to emit light. Specifically, the difference between the HOMO (Highest Occupied Molecular Orbital) energy level and LUMO (Lowest Unoccupied Molecular Orbital) energy level of the host material is greater than that of the sensitizer, and the difference between the HOMO energy level and LUMO energy level of the sensitizer is greater than that of the dye. Therefore, excitons can complete energy transfer between the host material and sensitizer, and energy transfer between the sensitizer and dye, and ultimately jump back to the ground state to release visible light with enhanced luminescence efficiency. In addition, an uneven distribution of the dye is also the main reason for improving the luminescence efficiency of the organic electroluminescent device of the present application.

Due to the fact that the anode and first functional layer are the sites for releasing and transmitting holes, while the cathode and second functional layer are the sites for releasing and transmitting electrons, there is often aggregation of a large amount of holes near the first functional layer side (the first section) and aggregation of a large amount of electrons near the second functional layer side (the N^{th} section). The present application provides an ordered limitation on the distribution of the dye in the light-emitting layer, that is, D₁<Dₘₐₓ and D₁≤Dₒₜₕₑᵣ, and/or D_{N}<Dₘₐₓ and D_{N}≤Dₒₜₕₑᵣ. For the entire light-emitting layer, the lower dye distribution in the first section and/or N^{th} section will significantly suppress a probability that holes and/or electrons are directly captured by the dye in the first section and/or N^{th} section, which can not only suppress a quenching phenomenon caused by the collision between excitons in the dye and the captured carriers, but also allow more carriers to be captured by the host material and to generate more excitons for promoting sensitized luminescence. Therefore, the present application achieves an improvement in the luminescence efficiency of the organic electroluminescent device by improving the utilization rate of excitons.

It should be noted that the present application does not limit the number of highest critical sections, which may be one or more, and the dye contents of multiple highest critical sections are equal to each other. In addition, the number of other sections is not limited, and there is no limit on the size relationship between the dye contents of respective other sections. However, D₁ and D_{N} are both less than or equal to the minimum dye content of the other sections.

In a specific implementation, 0.1≤D₁/Dₘₐₓ≤0.9, and/or 0.1≤D_{N}/Dₘₐₓ≤0.9. At this point, the probability that carriers are captured in the first section and/or N^{th} section is lower, which in turn causes more carriers to be captured by the host material to produce excitons, further improving the luminescence efficiency of the organic electroluminescent device. In an implementation, 0.2≤D₁/Dₘₐₓ≤0.8, and/or 0.2≤D_{N}/Dₘₐₓ≤0.8.

In a specific implementation, in order to more effectively make a qualitative and quantitative analysis on the composition of the light-emitting layer, the dye in the light-emitting layer of the organic electroluminescent device for the present application contains boron (B) element, specifically the dye is selected from a fluorescent dye containing the element B or a resonant type TADF material containing the element B. In specific analysis, for example, semi-quantitative/quantitative analysis of the content of element B in each section of the light-emitting layer can be performed using the Time of Flight Secondary Ion Mass Spectrometer (TOF-SIMS) and Focused Ion Beam Scanning Electron Microscope Energy Spectrometer System (FIB-SEM-EDS) analysis methods.

The present application does not make specific limitation on the fluorescent dye containing element B, for example, it may be a compound represented by General Formula I or General Formula II.

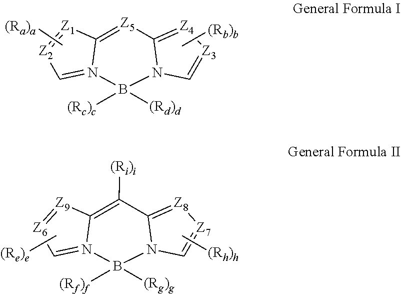

in General Formula I and General Formula II, Z₁, Z₂, Z₃, Z₄, Z₅, Z₆, Z₇, Z₈, and Z₉ are each independently selected from N or *—CR;
R, Rₐ, R_{b}, R_{c}, R_{d}, Rₑ, R_{f}, R_{g}, Rₕ, and Rᵢ are each independently selected from hydrogen atom, deuterium atom, halogen atom, cyano, hydroxyl, nitryl, amino, amidino, hydrazino, hydrazonoyl, carboxylic group or its salt, sulfonic group or its salt, phosphate group or its salt, substituted or unsubstituted silyl, substituted or unsubstituted alkyl of 1-60 carbon atoms, substituted or unsubstituted cycloalkyl of 3-30 carbon atoms, substituted or unsubstituted alkenyl of 2-60 carbon atoms, substituted or unsubstituted alkynyl of 2-60 carbon atoms, substituted or unsubstituted alkoxy of 1-60 carbon atoms, substituted or unsubstituted heterocyclic alkyl of 3-10 carbon atoms, substituted or unsubstituted cycloalkenyl of 3-10 carbon atoms, substituted or unsubstituted heterocyclic alkenyl of 1-10 carbon atoms, substituted or unsubstituted aryloxy of 6-60 carbon atoms, substituted or unsubstituted aryl thiol of 6-60 carbon atoms, substituted or unsubstituted aryl of 6-60 ring-forming carbon atoms, or substituted or unsubstituted heteroaryl of 2-60 ring-forming carbon atoms, substituted or unsubstituted group capable of binding to adjacent group to form a ring, *—Si(Q₁)(Q₂)(Q₃), *—B(Q₁)(Q₂), *—N(Q₁)(Q₂), *—P(Q₁)(Q₂), *—C(═O)(Q₁), *—S₂(Q₁)(Q₃), *—P(═O)(Q₁)(Q₂), and *—P(═S)(Q₁)(Q₂), where, Q₁, Q₂, and Q₃ are each independently selected from hydrogen atom, deuterium atom, halogen atom, cyano, hydroxyl, nitryl, amino, amidino, hydrazino, hydrazonoyl, C1-C60 alkyl, C2-C60 alkenyl, C2-C60 alkynyl, C1-C60 alkoxy, C3-C10 cycloalkyl, C1-C10 heterocyclic alkyl, C3-C10 cycloalkenyl, C1-C10 heterocyclic alkenyl, C6-C60 aryl, C6-C60 aryloxy, C6-C60 aryl thiol, C1-C60 heteroaryl, C1-C60 heteroaryloxy, C1-C60 heteroaryl thiol, univalent non-aromatic fused polycyclic group, univalent non-aromatic fused heteropolycyclic group, biphenyl group, and triphenyl group.

Where, a. b, c, d, e, f, g, h, and i are each independently an integer greater than or equal to 0.

Furthermore, the compound of the fluorescent dye containing element B may be, for example, selected from compounds represented by B-1 to B-17.

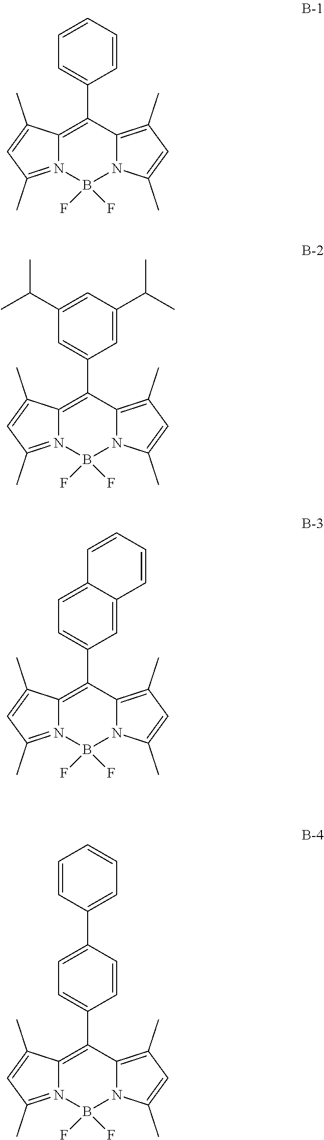

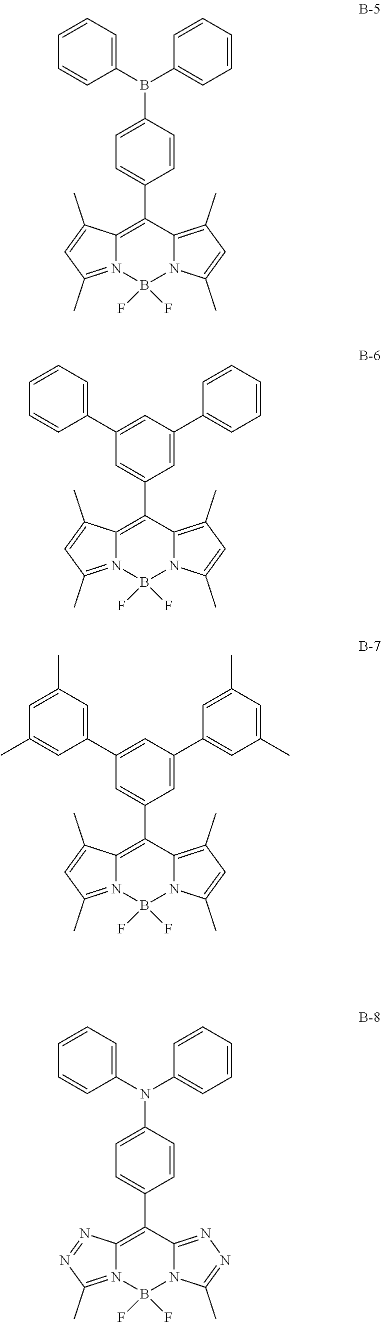

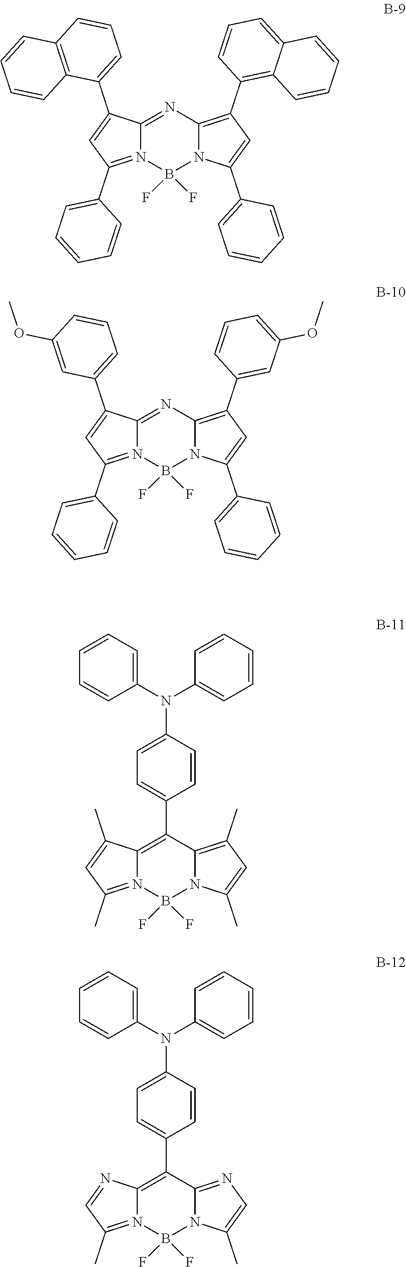

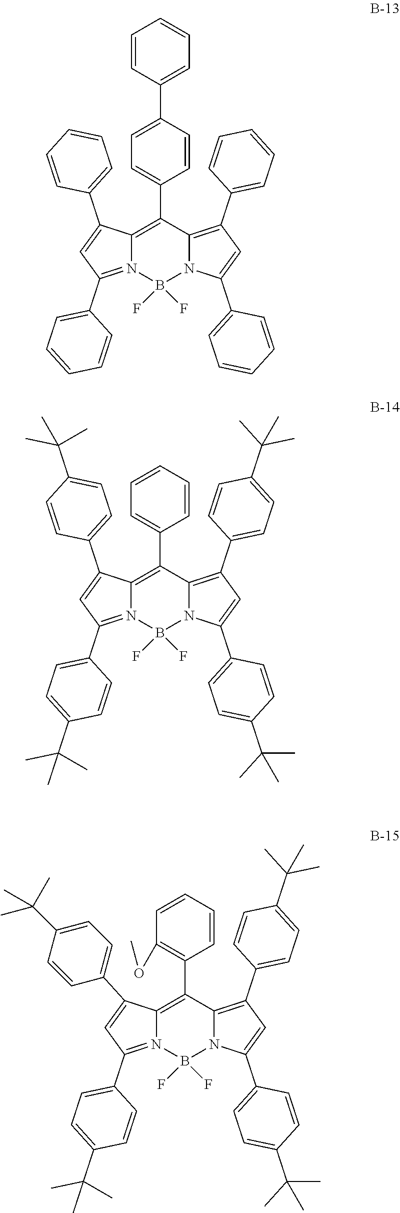

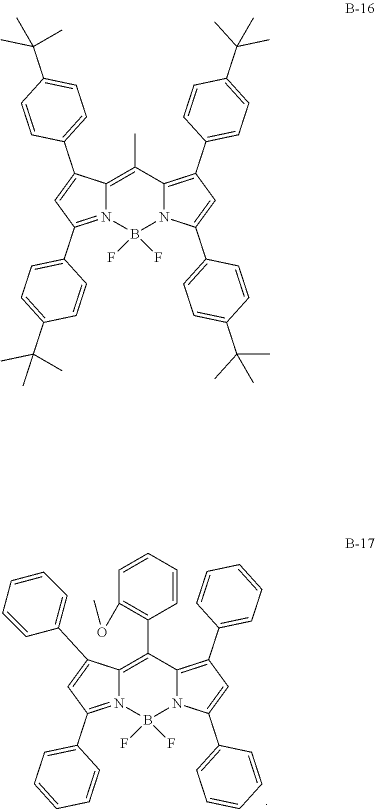

When the resonance type TADF material containing element B is used as the dye, the utilization rate of excitons can be further improved. Because the energy level difference between the singlet state and the triplet state of the resonant type TADF material containing element B is smaller, the triplet exciton of the resonant type TADF material containing element B will undergo reverse intersystem crossing to the first excited singlet state and then jump back to the ground state for luminescence by absorbing environmental heat.

The resonant type TADF material containing element B of the present application refers to a material containing B atom and having small energy level difference between the singlet state and the triplet state (≤0.5 eV). Therefore, this type of material has weak intramolecular charge transfer and high stability. For example, it may be a compound represented by one of the following General Formula III to General Formula V.

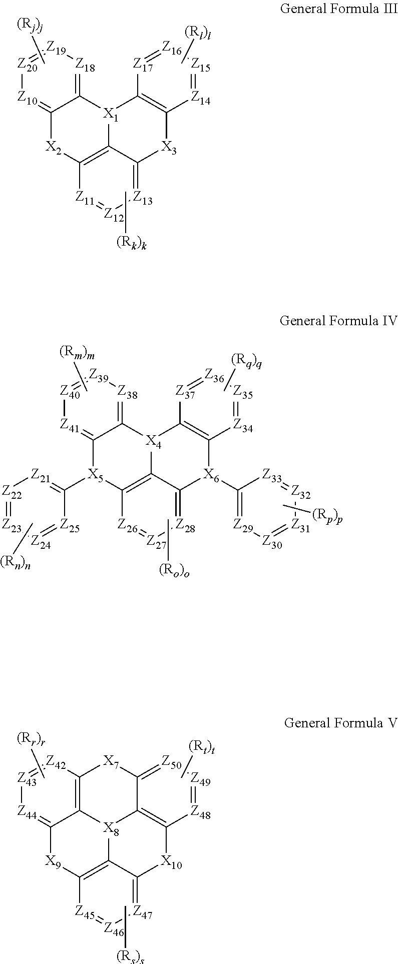

In the above General formulas III, IV and V, X₁, X₄, X₅, X₆, and X₈ are each independently selected from B, N, P, P═O, *—P═S, Al, Ga, As, *—SiR₁, or *—GeR₁, with at least one B atom being present, where R₁ is an aryl with a carbon number of 6-12 or an alkyl with a carbon number of 1-6; X₂, X₃, X₇, X₉, and X₁₀ are each independently selected from O, *—NR₂, S, or Se, where R₂ is an aryl with a carbon number of 6-12, a heteroaryl with a carbon number of 2-15, or an alkyl with a carbon number of 1-6; Z₁-Z₅₀ are each independently selected from N or *—CR; the definitions of R and Rⱼ-Rₜ are same as those of R and Rₐ-Rᵢ in the above General Formula I respectively, where j to t are each independently an integer greater than or equal to 0.

Furthermore, the resonant type TADF material containing element B may be, for example, a compound represented by one of Formulas T1 to T19 and Formulas B-19 to B-30, and a derivative thereof:

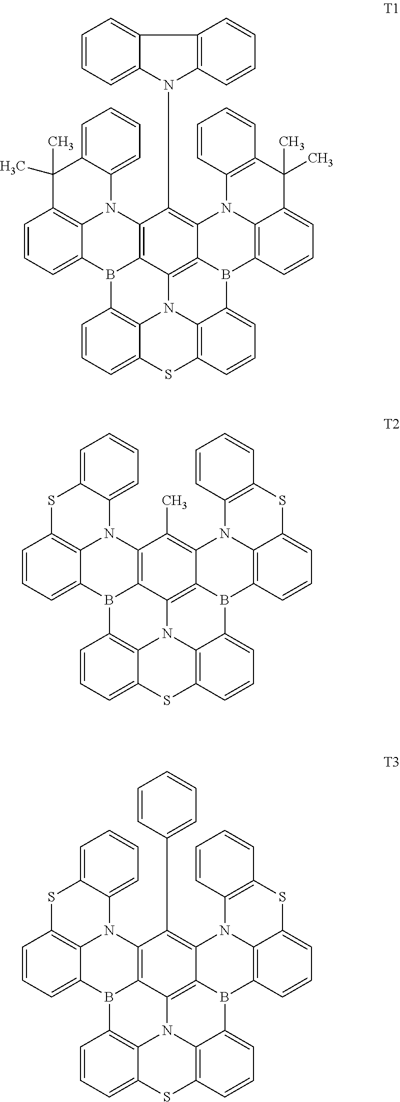 [SMILES: CC1(C)c2ccccc2N2c3c(cccc31)B1c3cccc4c3N3c5c(cccc5B5c6cccc7c6N(c6ccccc6C7(C)C)c6c5c3c1c2c6-n1c2ccccc2c2ccccc21)S4 ; Cc1c2c3c4c5c1N1c6ccccc6Sc6cccc(c61)B5c1cccc5c1N4c1c(cccc1B3c1cccc3c1N2c1ccccc1S3)S5 ; c1ccc(-c2c3c4c5c6c2N2c7ccccc7Sc7cccc(c72)B6c2cccc6c2N5c2c(cccc2B4c2cccc4c2N3c2ccccc2S4)S6)cc1]

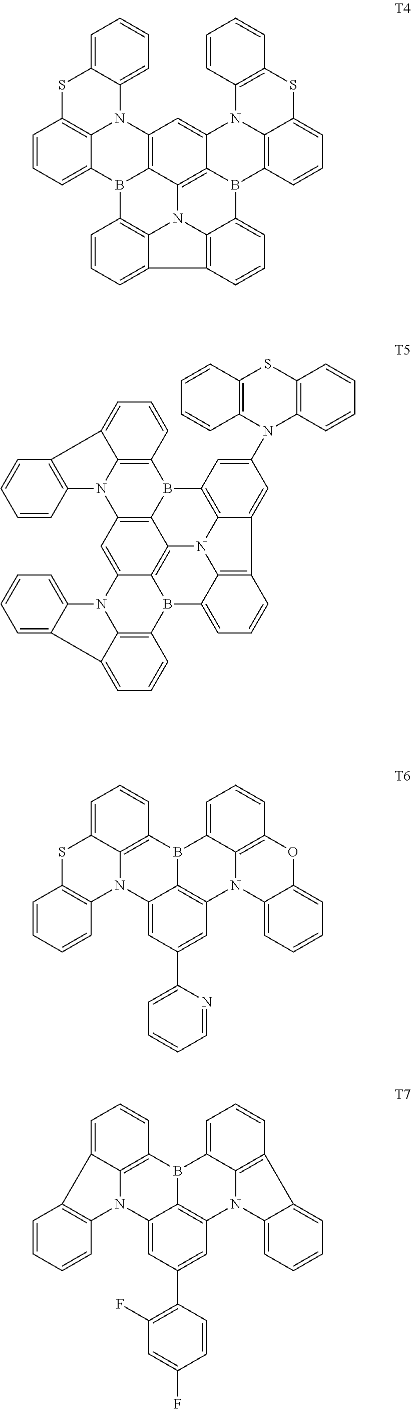 [SMILES: c1ccc2c(c1)Sc1cccc3c1N2c1cc2c4c5c1B3c1cccc3c6cccc(c6n-5c13)B4c1cccc3c1N2c1ccccc1S3 ; c1ccc2c(c1)Sc1ccccc1N2c1cc2c3c(c1)c1cccc4c1n3-c1c3c(cc5c1B2c1cccc2c6ccccc6n-5c12)-n1c2ccccc2c2cccc(c21)B34 ; c1ccc(-c2cc3c4c(c2)N2c5ccccc5Sc5cccc(c52)B4c2cccc4c2N3c2ccccc2O4)nc1 ; Fc1ccc(-c2cc3c4c(c2)-n2c5ccccc5c5cccc(c52)B4c2cccc4c5ccccc5n-3c24)c(F)c1]

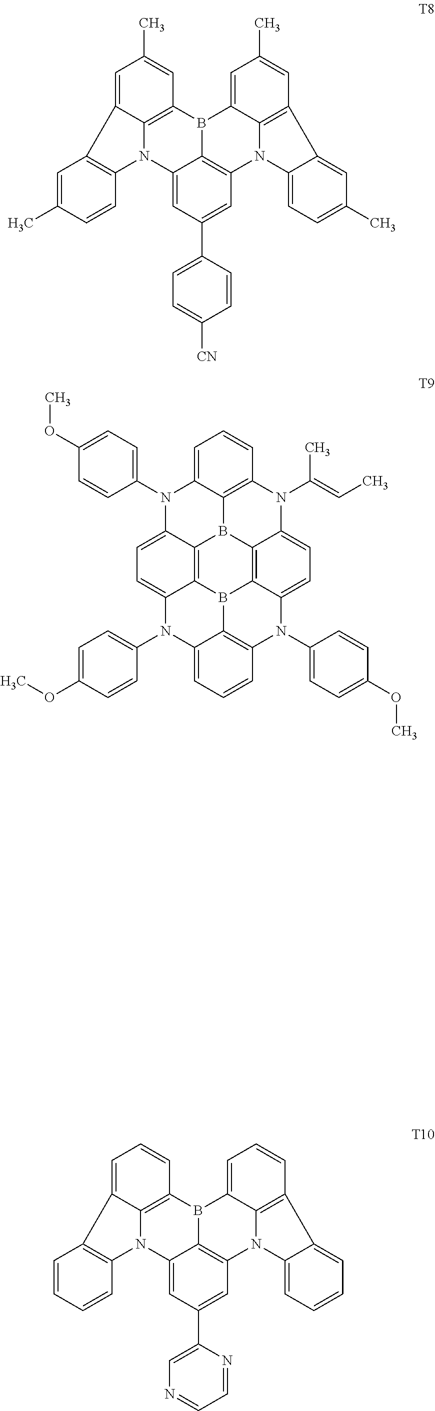

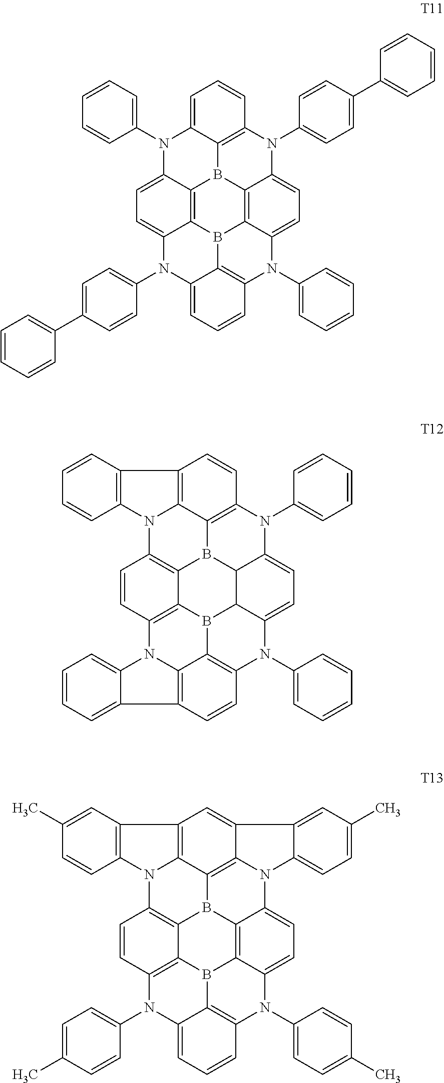

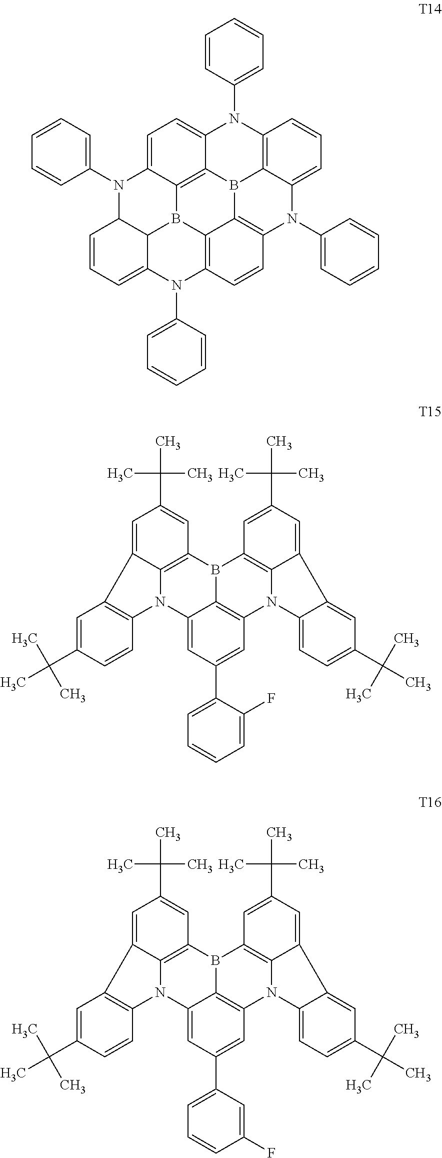

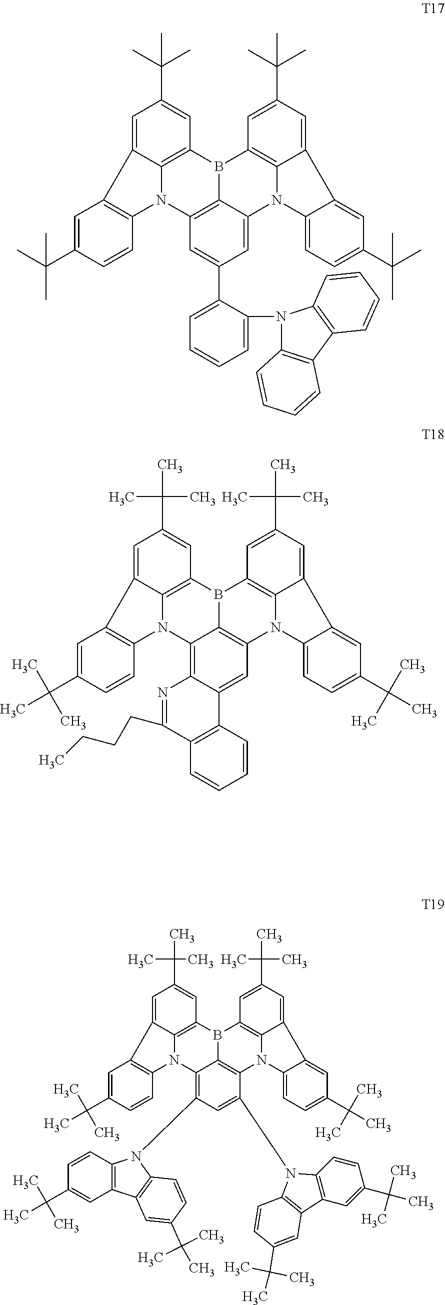

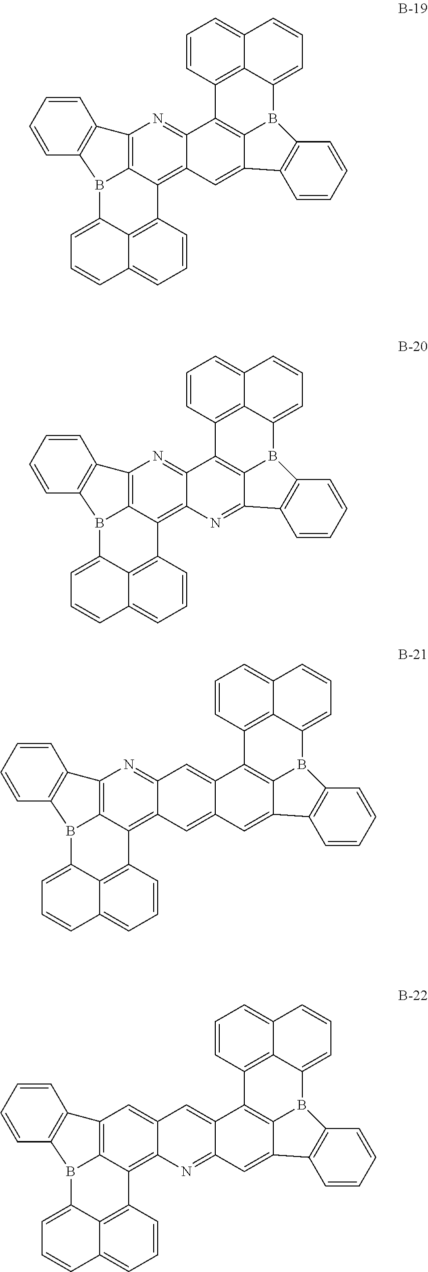 [SMILES: c1ccc2c(c1)B1c3c-2cc2c4c5c(nc2c3-c2cccc3cccc1c23)-c1ccccc1B5c1cccc2cccc-4c12 ; c1ccc2c(c1)B1c3c-2nc2c4c5c(nc2c3-c2cccc3cccc1c23)-c1ccccc1B5c1cccc2cccc-4c12 ; c1ccc2c(c1)B1c3c-2cc2cc4c5c6c(nc4cc2c3-c2cccc3cccc1c23)-c1ccccc1B6c1cccc2cccc-5c12 ; c1ccc2c(c1)B1c3c-2cc2nc4c5c6c(cc4cc2c3-c2cccc3cccc1c23)-c1ccccc1B6c1cccc2cccc-5c12]

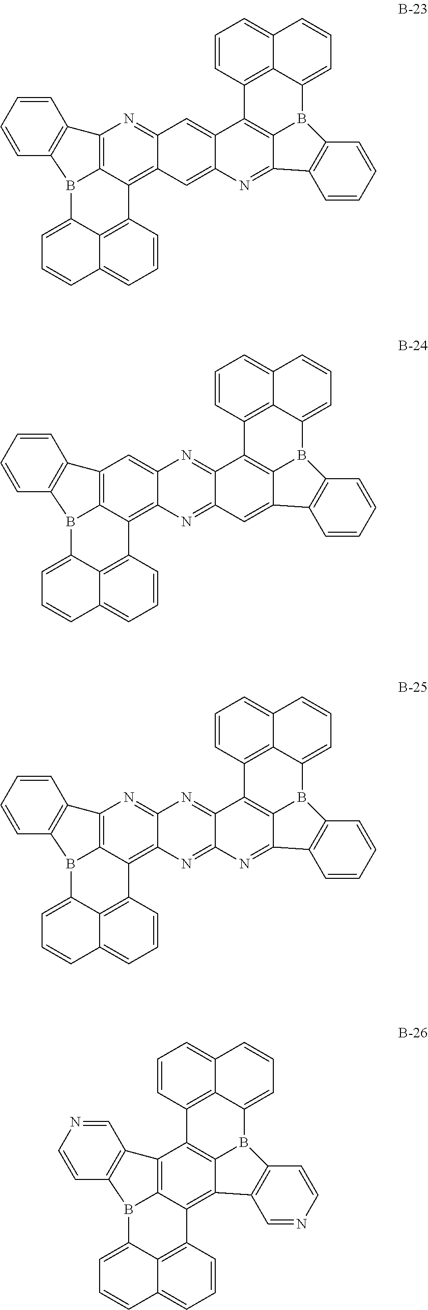 [SMILES: c1ccc2c(c1)B1c3c-2nc2cc4c5c6c(nc4cc2c3-c2cccc3cccc1c23)-c1ccccc1B6c1cccc2cccc-5c12 ; c1ccc2c(c1)B1c3c-2cc2nc4c5c6c(cc4nc2c3-c2cccc3cccc1c23)-c1ccccc1B6c1cccc2cccc-5c12 ; c1ccc2c(c1)B1c3c-2nc2nc4c5c6c(nc4nc2c3-c2cccc3cccc1c23)-c1ccccc1B6c1cccc2cccc-5c12 ; c1cc2c3c(cccc3c1)-c1c3c(c4c5c1-c1cnccc1B5c1cccc5cccc-4c15)-c1cnccc1B32]

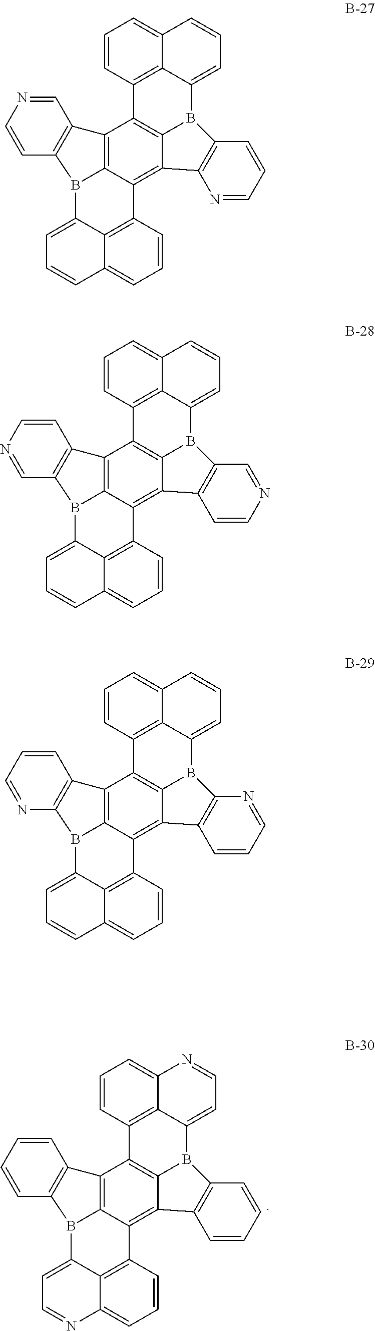 [SMILES: c1cnc2c(c1)B1c3c-2c2c4c(c3-c3cccc5cccc1c35)-c1cnccc1B4c1cccc3cccc-2c13 ; c1cc2c3c(cccc3c1)-c1c3c(c4c5c1-c1ccncc1B5c1cccc5cccc-4c15)-c1ccncc1B32 ; c1cnc2c(c1)-c1c3c(c4c5c1-c1cccc6cccc(c16)B5c1ncccc1-4)-c1cccc4cccc(c14)B23 ; c1ccc2c(c1)B1c3c-2c2c4c(c3-c3cccc5nccc1c35)-c1ccccc1B4c1ccnc3cccc-2c13]

On one hand, the energy level difference between the singlet state and triplet state of the resonant type TADF material containing element B is very small, so that more triplet excitons are prone to up-conversion migration to singlet state, resulting in delayed fluorescence; and on the other hand, due to its planar aromatic rigid structure and the absence of obvious donor and acceptor groups in the molecule, the resonant type TADF material has good planar conjugation, weak intramolecular charge transfer, and high stability, which is benefit to narrow the spectrum of the device and improve the color purity of the device.

In a specific implementation, the sensitizer of the present application is selected from the TADF material or a phosphorescent material.

Where, the TADF material used as the sensitizer refers to a material that the energy level difference between the singlet state and the triplet state is less than 0.3 eV and can then lead to reverse intersystem crossing. The phosphorescent material refers to a material containing rare metal (such as Ir, Pt, Au, Ag, Os, Cu and other metal elements) and then can use the triplet exciton.

When using the TADF sensitizer in the present application, it can be understood that the energy level of the first excited singlet state of the host material is greater than that of the TADF sensitizer, and the energy level of the first excited singlet state of the TADF sensitizer is greater than that of the dye; the energy level of the first excited triplet state of the host material is greater than that of the TADF sensitizer, and the energy level of the first excited triplet state of the TADF sensitizer is greater than that of the dye. Because the energy level of the first excited singlet state and the energy level of the first excited triplet state of each of the host material, the TADF sensitizer and the dye have the aforementioned relationships, the first excited singlet exciton and the first excited triplet exciton of the host material will respectively jump to the first excited singlet state and the first excited triplet state of the TADF sensitizer after the electroluminescent device is electrically excited, and based on the property of the reverse intersystem crossing of the TADF sensitizer, the exciton in the first excited triplet state of the TADF sensitizer will convert to that in the first excited singlet state via reverse intersystem crossing. Finally, the excitons from the host material and the TADF sensitizer jump to the first excited singlet state of the dye via Foster energy transfer from the TADF sensitizer to the dye, and jump back to the ground state to generate fluorescence. That is, the luminescence efficiency and stability of the organic electroluminescent device are improved by increasing the exciton utilization, specifically, the improvement in stability is manifested by an extension of the service life.

When using a phosphorescent sensitizer in the present application, it can be understood that the energy level of the first excited singlet state of the host material is greater than that of the phosphorescent sensitizer, and the energy level of the first excited singlet state of the phosphorescent sensitizer is greater than that of the dye; the energy level of the first excited triplet state of the host material is greater than that of the phosphorescent sensitizer, and the energy level of the first excited triplet state of the phosphorescent sensitizer is greater than that of the first excited singlet/triplet state of the dye. Since the energy level of the first excited singlet state and the energy level of the first excited triplet state of each of the host material, phosphorescent sensitizer and dye have the aforementioned relationships, the first excited singlet exciton and the first excited triplet exciton of the host material will jump to the first excited singlet state and the first excited triplet state of the phosphorescent sensitizer after the organic electroluminescent device is electrically excited, and based on the property of the reverse intersystem crossing of the phosphorescent sensitizer, the exciton in the first excited singlet state of the phosphorescent sensitizer will convert to the first excited triplet state via reverse intersystem crossing, and finally transfer energy to the dye mainly through Förster energy transfer to emit light.

The present application does not limit the specific selection of the TADF sensitizer. In an implementation, it may be selected from at least one of the following compounds of T-1 to T-89.

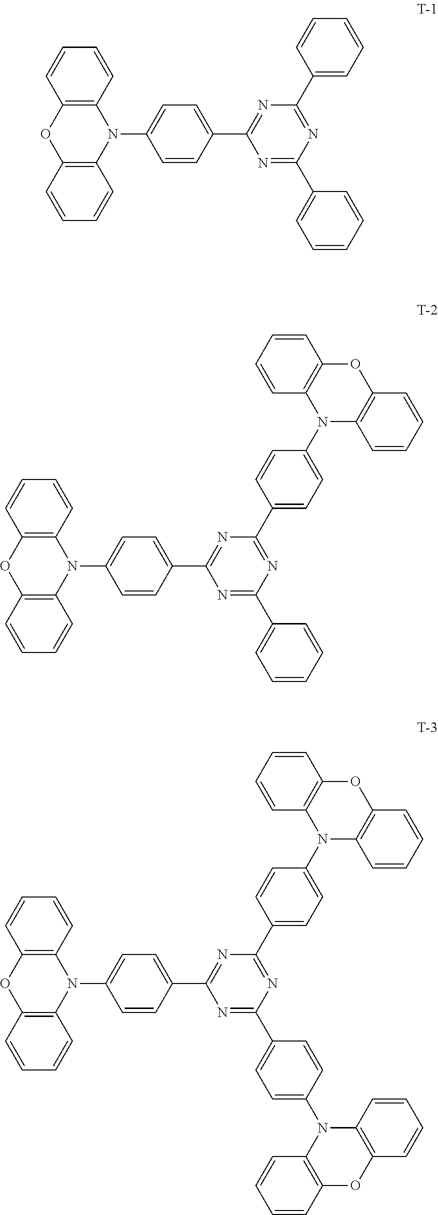 [SMILES: c1ccc(-c2nc(-c3ccccc3)nc(-c3ccc(N4c5ccccc5Oc5ccccc54)cc3)n2)cc1 ; c1ccc(-c2nc(-c3ccc(N4c5ccccc5Oc5ccccc54)cc3)nc(-c3ccc(N4c5ccccc5Oc5ccccc54)cc3)n2)cc1 ; c1ccc2c(c1)Oc1ccccc1N2c1ccc(-c2nc(-c3ccc(N4c5ccccc5Oc5ccccc54)cc3)nc(-c3ccc(N4c5ccccc5Oc5ccccc54)cc3)n2)cc1]

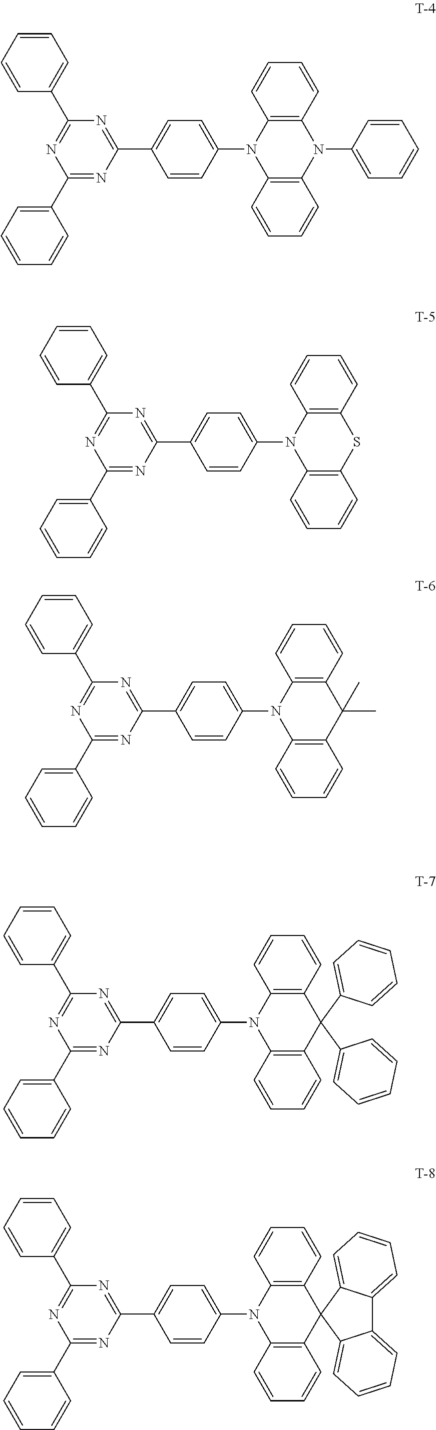

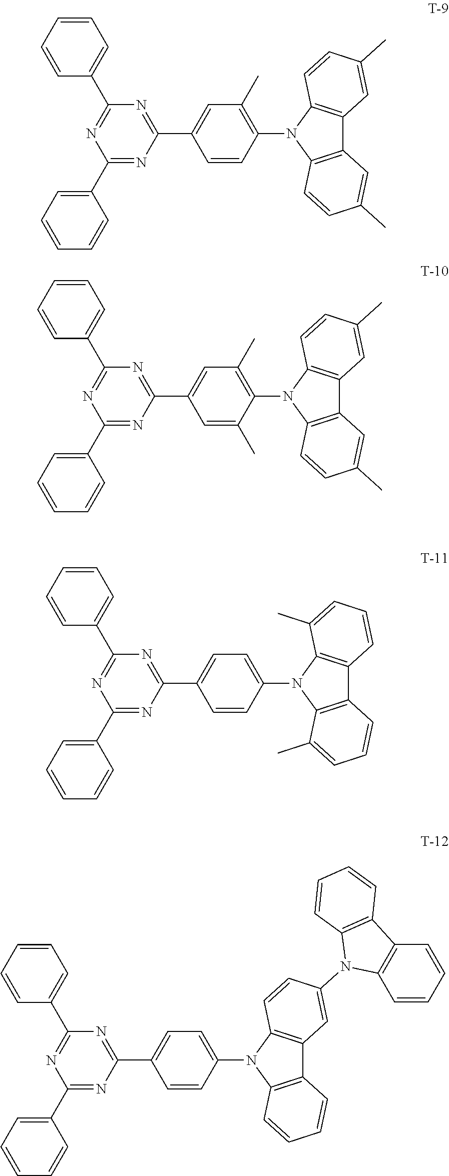

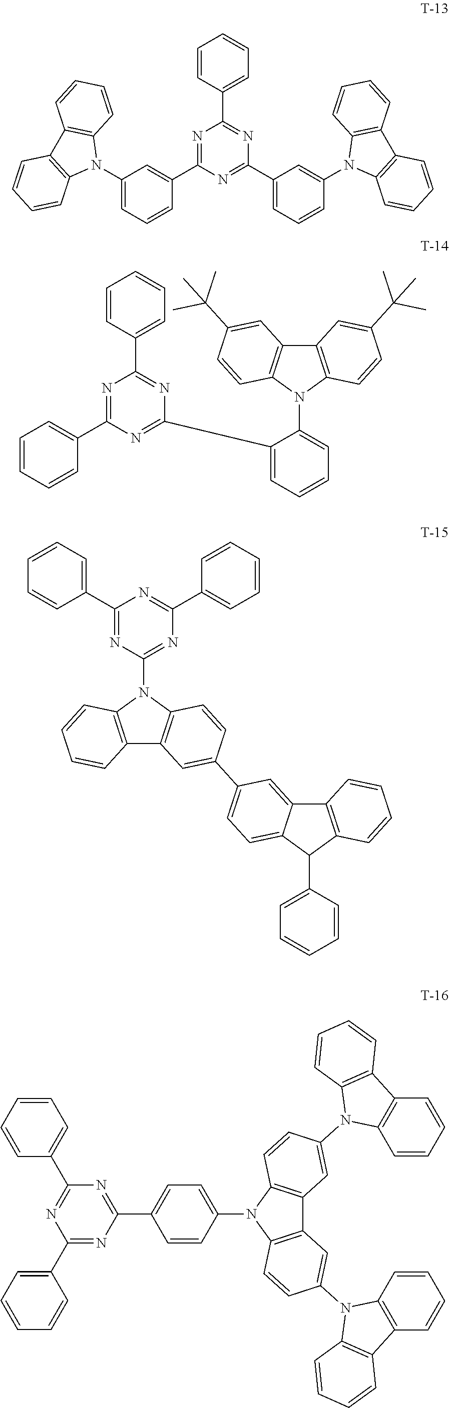 [SMILES: c1ccc(-c2nc(-c3cccc(-n4c5ccccc5c5ccccc54)c3)nc(-c3cccc(-n4c5ccccc5c5ccccc54)c3)n2)cc1 ; CC(C)(C)c1ccc2c(c1)c1cc(C(C)(C)C)ccc1n2-c1ccccc1-c1nc(-c2ccccc2)nc(-c2ccccc2)n1 ; c1ccc(-c2nc(-c3ccccc3)nc(-n3c4ccccc4c4cc(-c5ccc6c(c5)-c5ccccc5C6c5ccccc5)ccc43)n2)cc1 ; c1ccc(-c2nc(-c3ccccc3)nc(-c3ccc(-n4c5ccc(-n6c7ccccc7c7ccccc76)cc5c5cc(-n6c7ccccc7c7ccccc76)ccc54)cc3)n2)cc1]

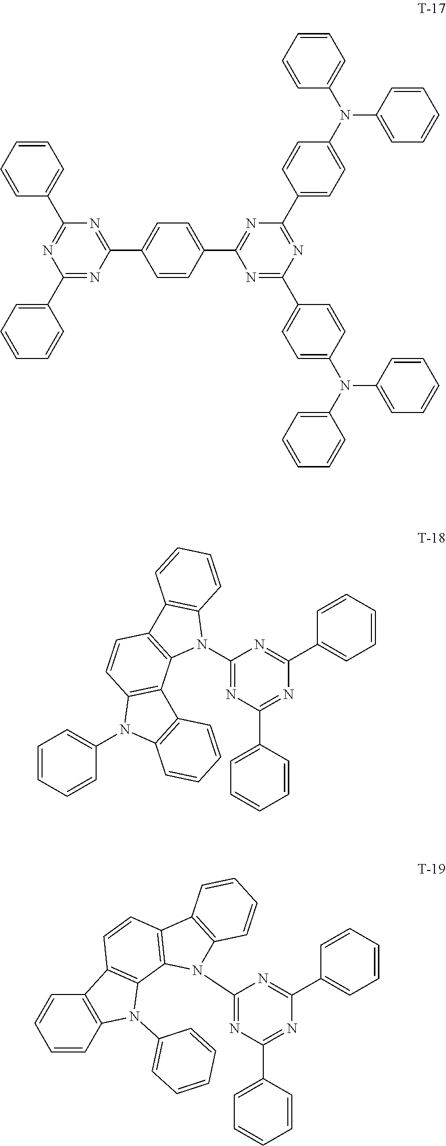 [SMILES: c1ccc(-c2nc(-c3ccccc3)nc(-c3ccc(-c4nc(-c5ccc(N(c6ccccc6)c6ccccc6)cc5)nc(-c5ccc(N(c6ccccc6)c6ccccc6)cc5)n4)cc3)n2)cc1 ; c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4ccc5c6ccccc6n(-c6ccccc6)c5c43)n2)cc1]

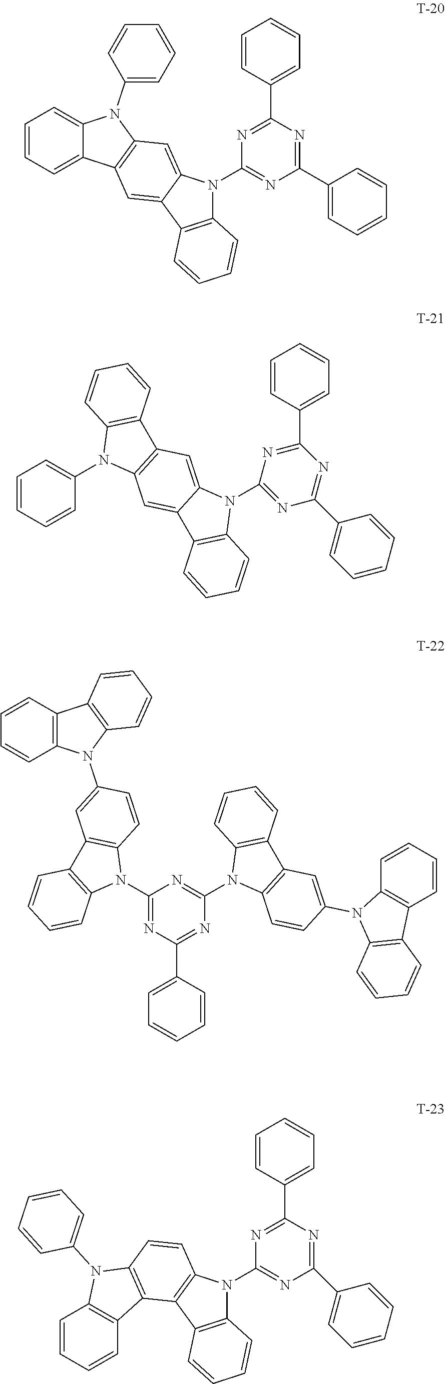 [SMILES: c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-n3c4ccccc4c4cc5c(cc43)c3ccccc3n5-c3ccccc3)n2)cc1 ; c1ccc(-c2nc(-n3c4ccccc4c4cc(-n5c6ccccc6c6ccccc65)ccc43)nc(-n3c4ccccc4c4cc(-n5c6ccccc6c6ccccc65)ccc43)n2)cc1 ; c1ccc(-c2nc(-c3ccccc3)nc(-n3c4ccccc4c4c5c6ccccc6n(-c6ccccc6)c5ccc43)n2)cc1]

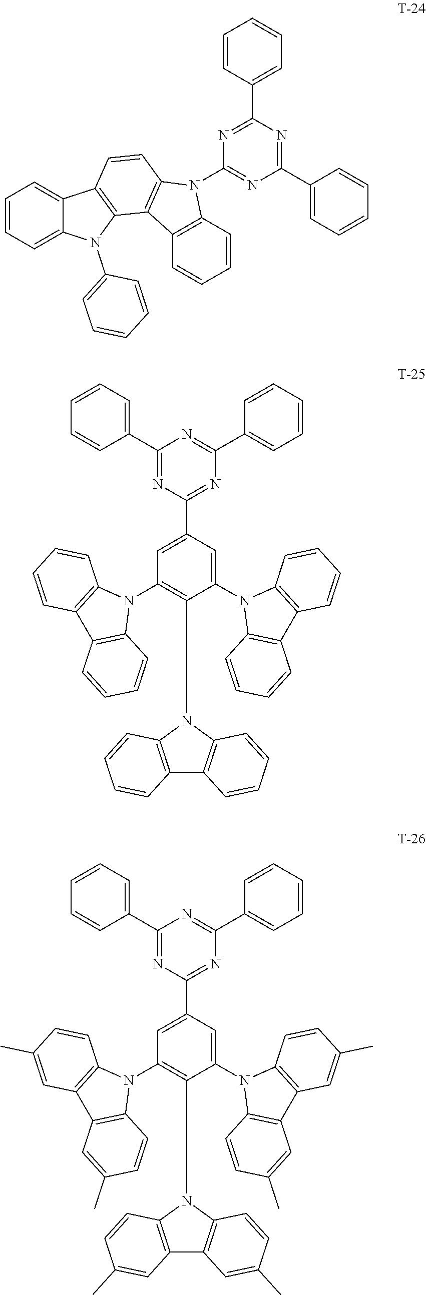

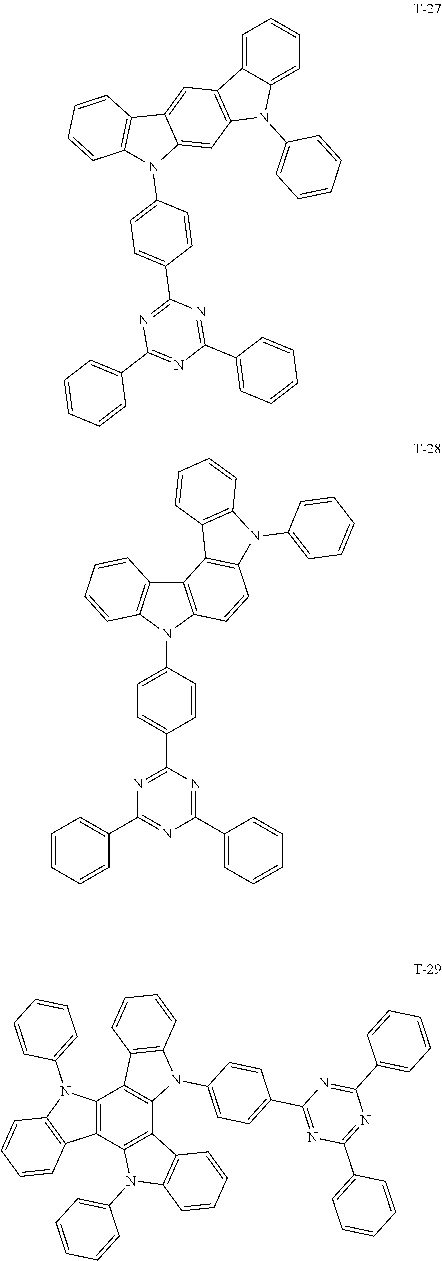 [SMILES: c1ccc(-c2nc(-c3ccccc3)nc(-c3ccc(-n4c5ccccc5c5cc6c7ccccc7n(-c7ccccc7)c6cc54)cc3)n2)cc1 ; c1ccc(-c2nc(-c3ccccc3)nc(-c3ccc(-n4c5ccccc5c5c6c7ccccc7n(-c7ccccc7)c6ccc54)cc3)n2)cc1 ; c1ccc(-c2nc(-c3ccccc3)nc(-c3ccc(-n4c5ccccc5c5c6c(c7ccccc7n6-c6ccccc6)c6c(c7ccccc7n6-c6ccccc6)c54)cc3)n2)cc1]

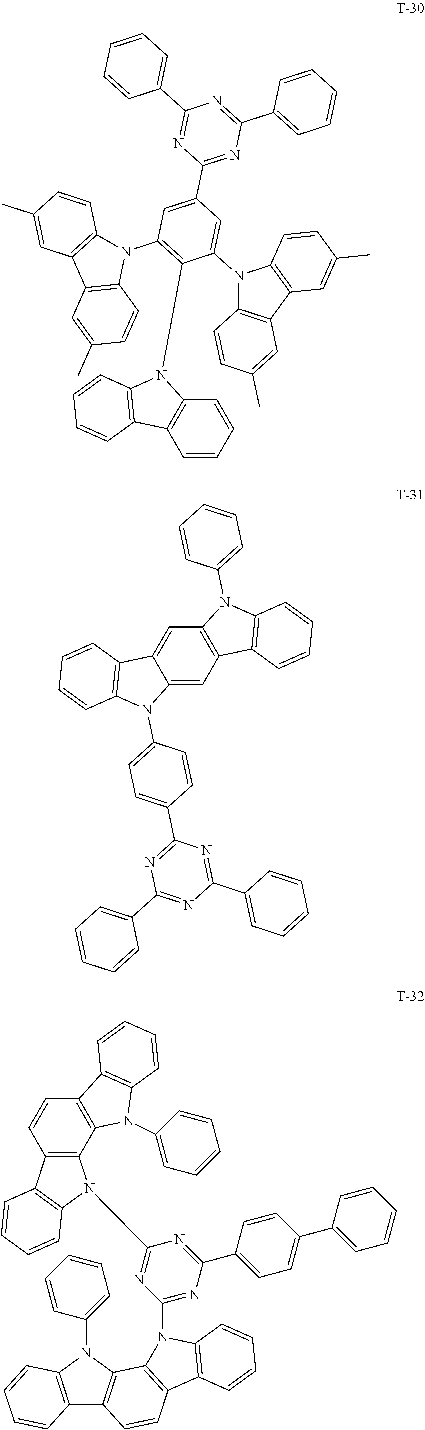

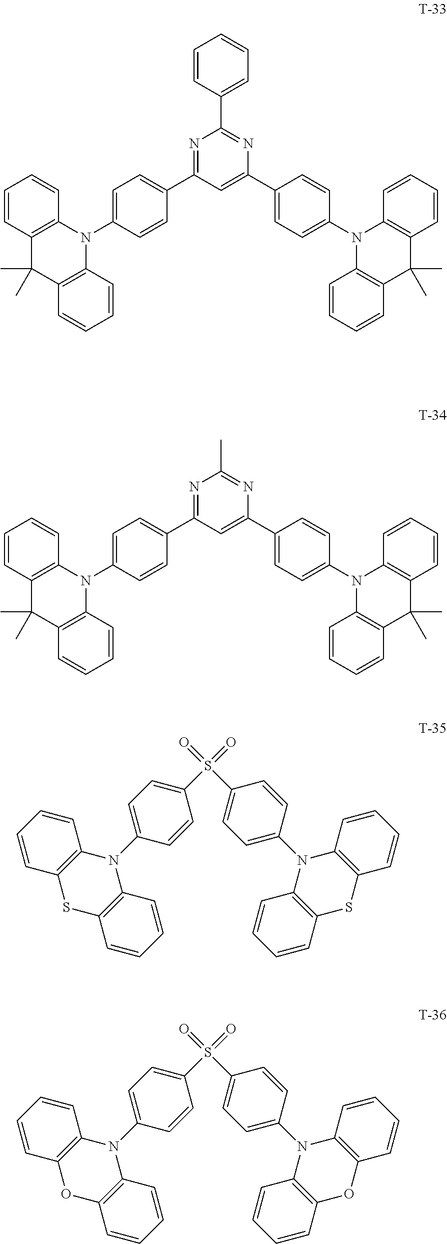

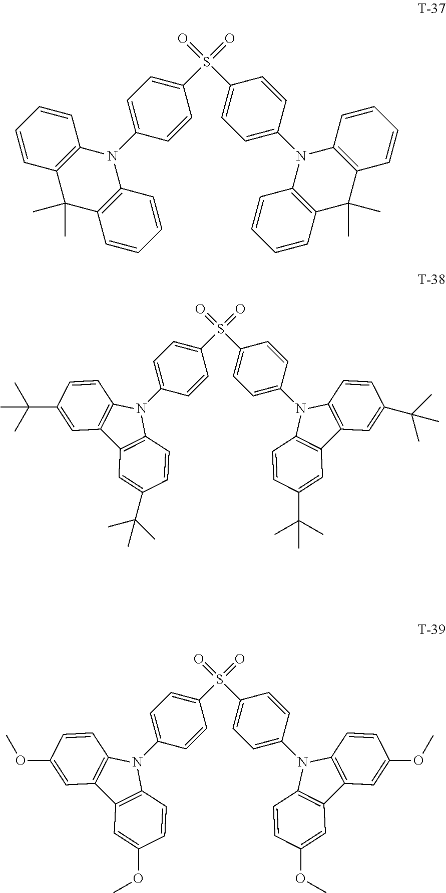

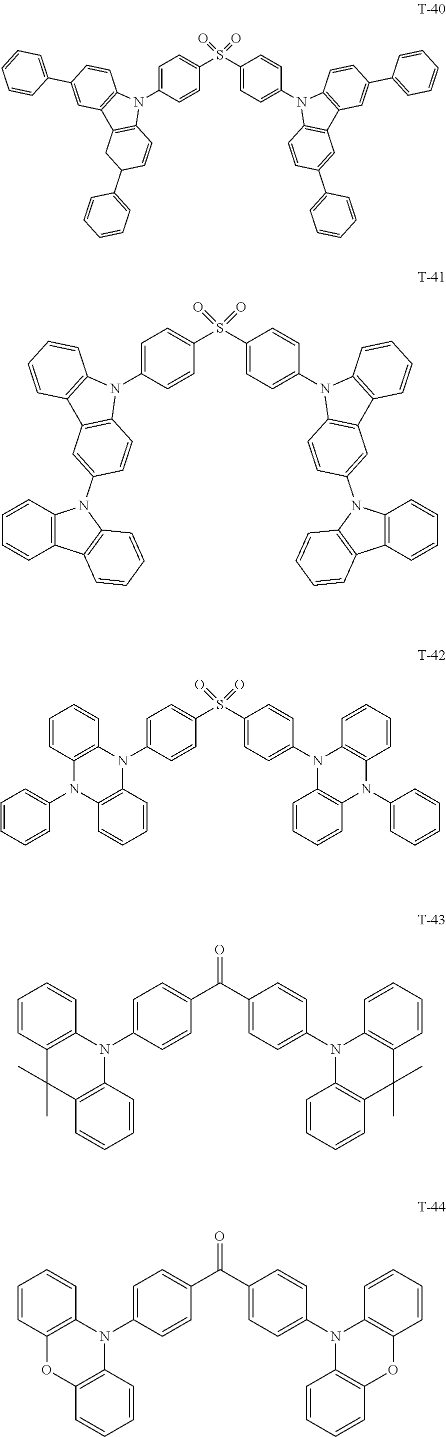 [SMILES: O=S(=O)(c1ccc(-n2c3c(c4cc(-c5ccccc5)ccc42)CC(c2ccccc2)C=C3)cc1)c1ccc(-n2c3ccc(-c4ccccc4)cc3c3cc(-c4ccccc4)ccc32)cc1 ; O=S(=O)(c1ccc(-n2c3ccccc3c3cc(-n4c5ccccc5c5ccccc54)ccc32)cc1)c1ccc(-n2c3ccccc3c3cc(-n4c5ccccc5c5ccccc54)ccc32)cc1 ; O=S(=O)(c1ccc(N2c3ccccc3N(c3ccccc3)c3ccccc32)cc1)c1ccc(N2c3ccccc3N(c3ccccc3)c3ccccc32)cc1 ; CC1(C)c2ccccc2N(c2ccc(C(=O)c3ccc(N4c5ccccc5C(C)(C)c5ccccc54)cc3)cc2)c2ccccc21 ; O=C(c1ccc(N2c3ccccc3Oc3ccccc32)cc1)c1ccc(N2c3ccccc3Oc3ccccc32)cc1]

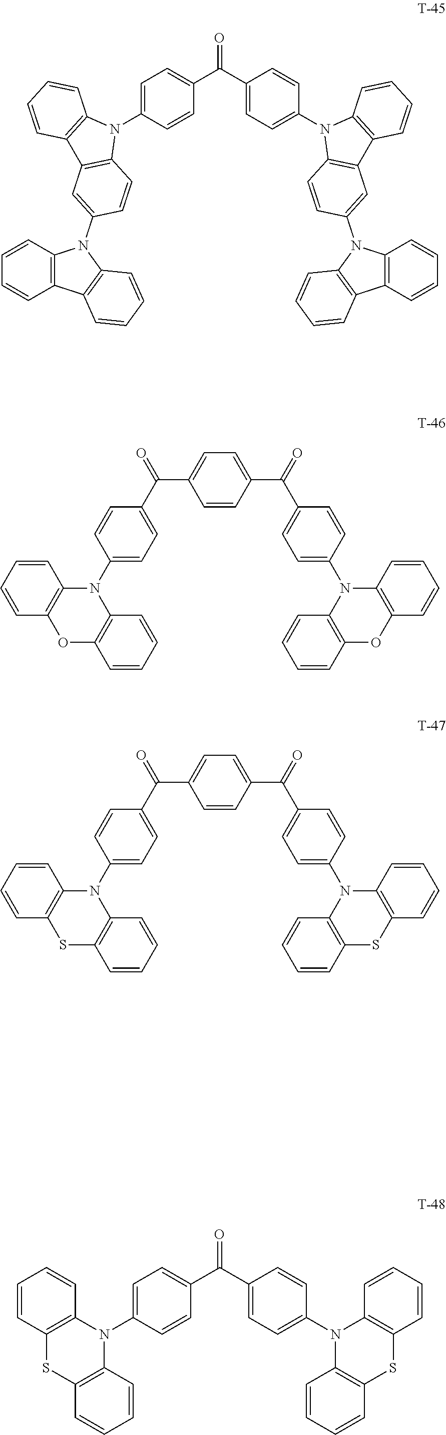 [SMILES: O=C(c1ccc(-n2c3ccccc3c3cc(-n4c5ccccc5c5ccccc54)ccc32)cc1)c1ccc(-n2c3ccccc3c3cc(-n4c5ccccc5c5ccccc54)ccc32)cc1 ; O=C(c1ccc(C(=O)c2ccc(N3c4ccccc4Oc4ccccc43)cc2)cc1)c1ccc(N2c3ccccc3Oc3ccccc32)cc1 ; O=C(c1ccc(C(=O)c2ccc(N3c4ccccc4Sc4ccccc43)cc2)cc1)c1ccc(N2c3ccccc3Sc3ccccc32)cc1 ; O=C(c1ccc(N2c3ccccc3Sc3ccccc32)cc1)c1ccc(N2c3ccccc3Sc3ccccc32)cc1]

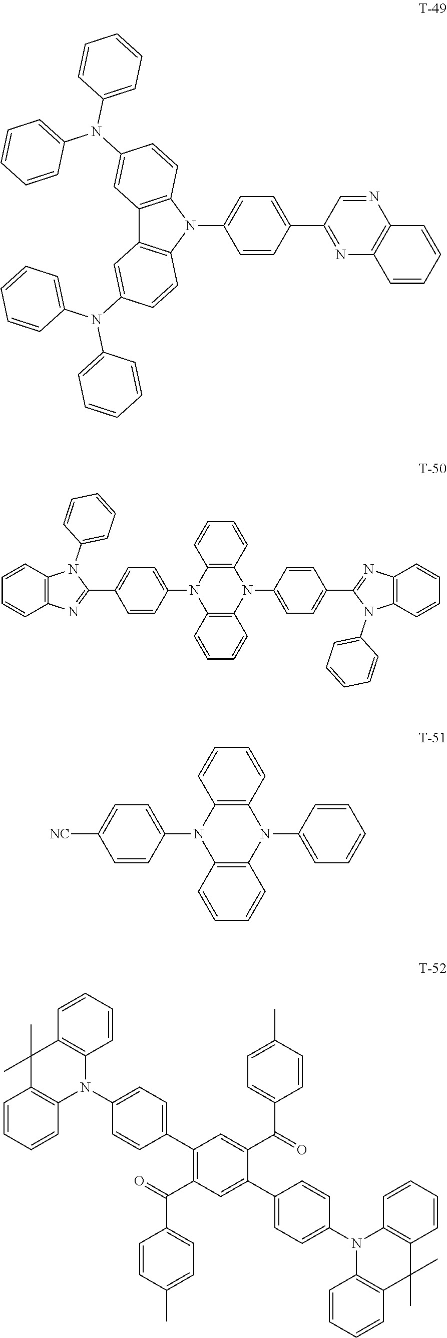

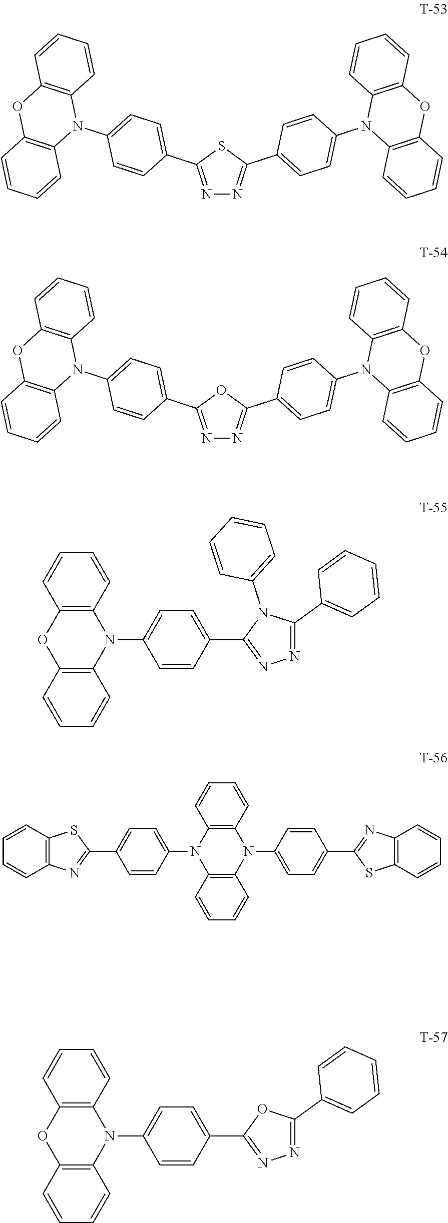

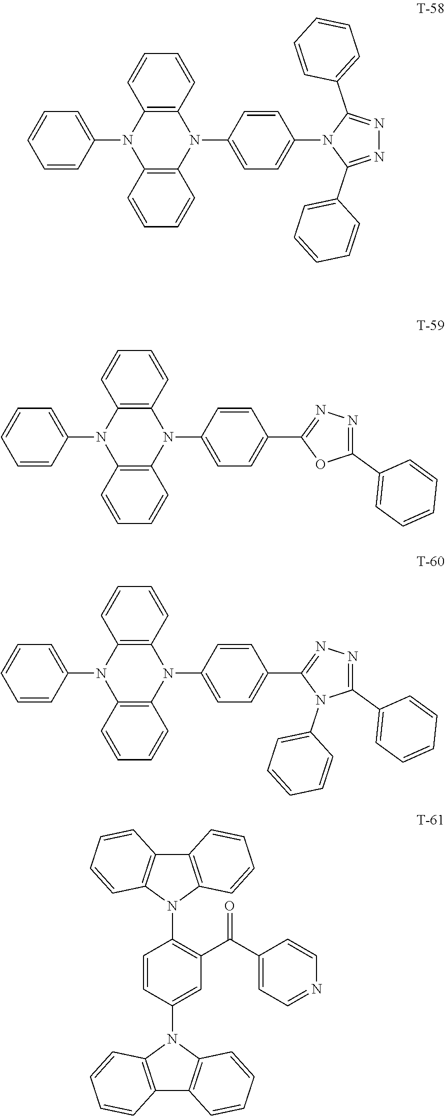

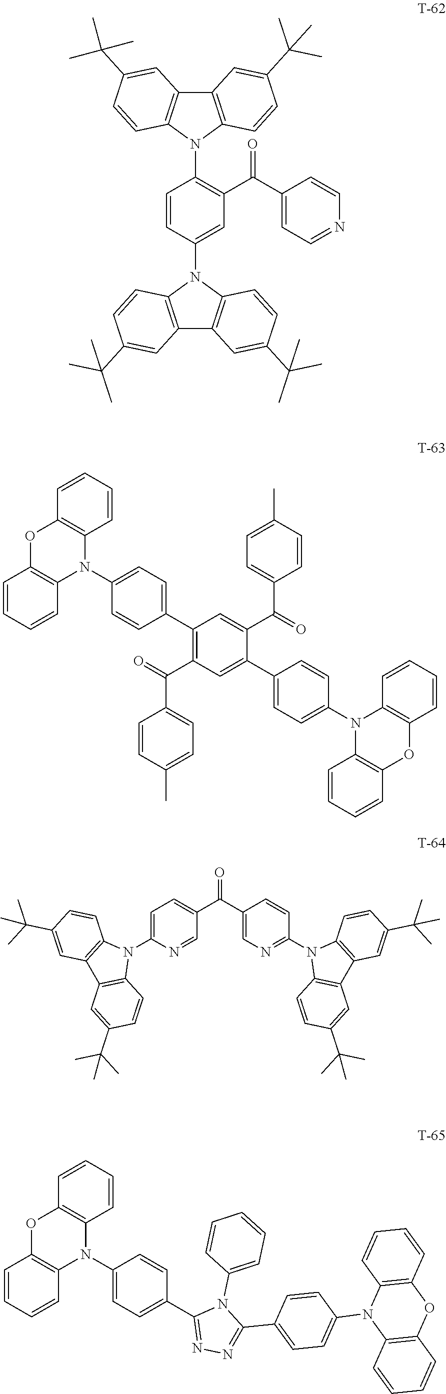 [SMILES: CC(C)(C)c1ccc2c(c1)c1cc(C(C)(C)C)ccc1n2-c1ccc(-n2c3ccc(C(C)(C)C)cc3c3cc(C(C)(C)C)ccc32)c(C(=O)c2ccncc2)c1 ; Cc1ccc(C(=O)c2cc(-c3ccc(N4c5ccccc5Oc5ccccc54)cc3)c(C(=O)c3ccc(C)cc3)cc2-c2ccc(N3c4ccccc4Oc4ccccc43)cc2)cc1 ; CC(C)(C)c1ccc2c(c1)c1cc(C(C)(C)C)ccc1n2-c1ccc(C(=O)c2ccc(-n3c4ccc(C(C)(C)C)cc4c4cc(C(C)(C)C)ccc43)nc2)cn1 ; c1ccc(-n2c(-c3ccc(N4c5ccccc5Oc5ccccc54)cc3)nnc2-c2ccc(N3c4ccccc4Oc4ccccc43)cc2)cc1]

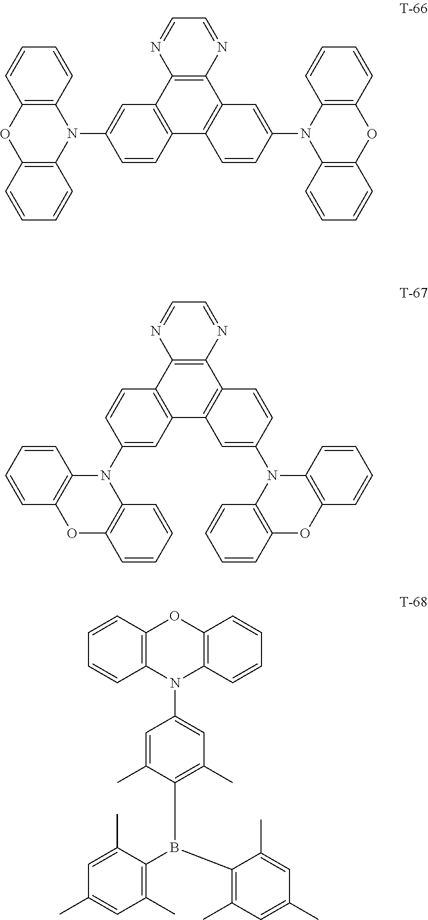

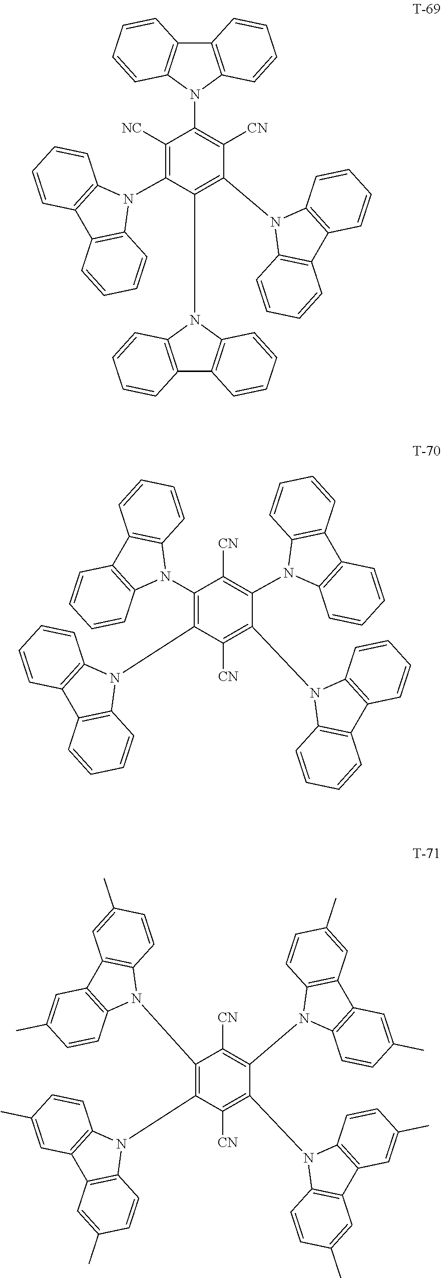

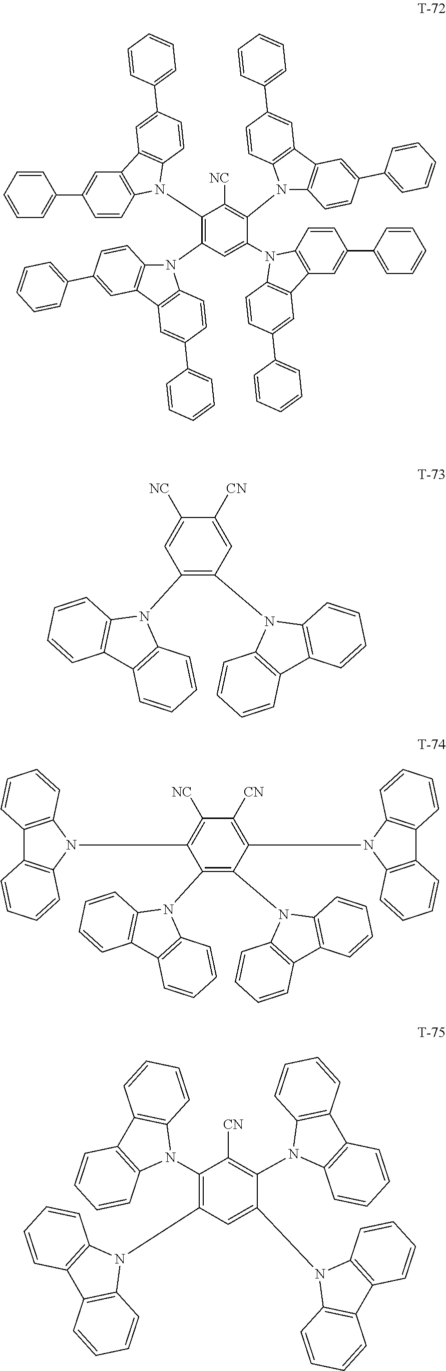

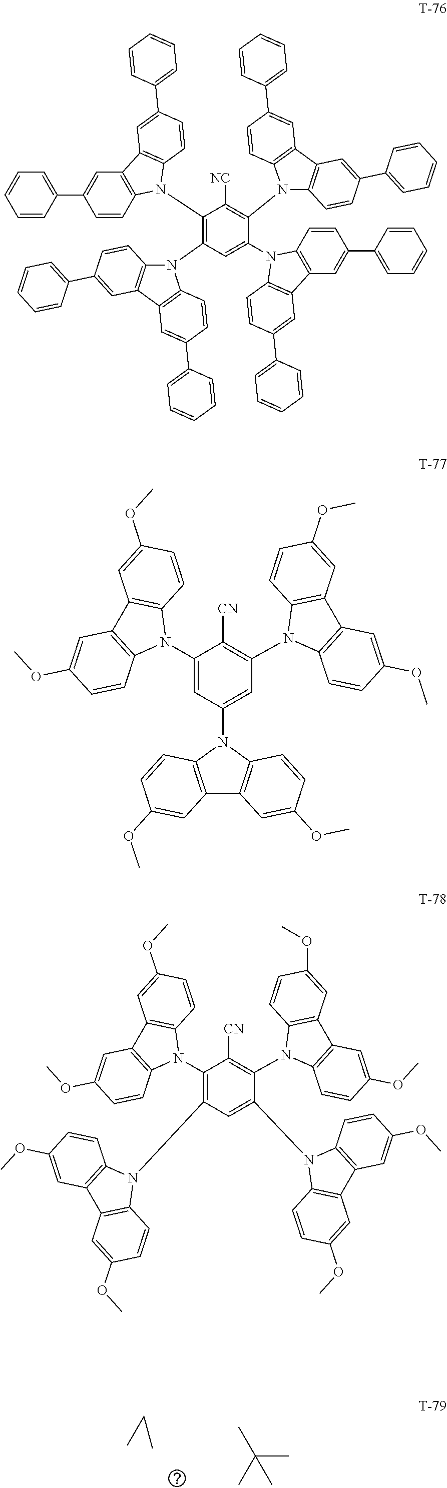

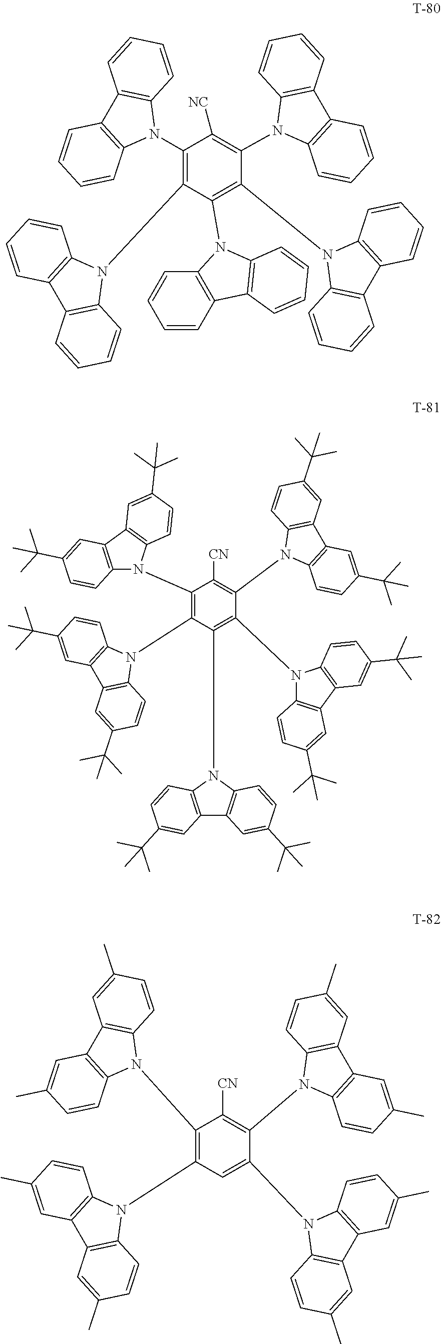

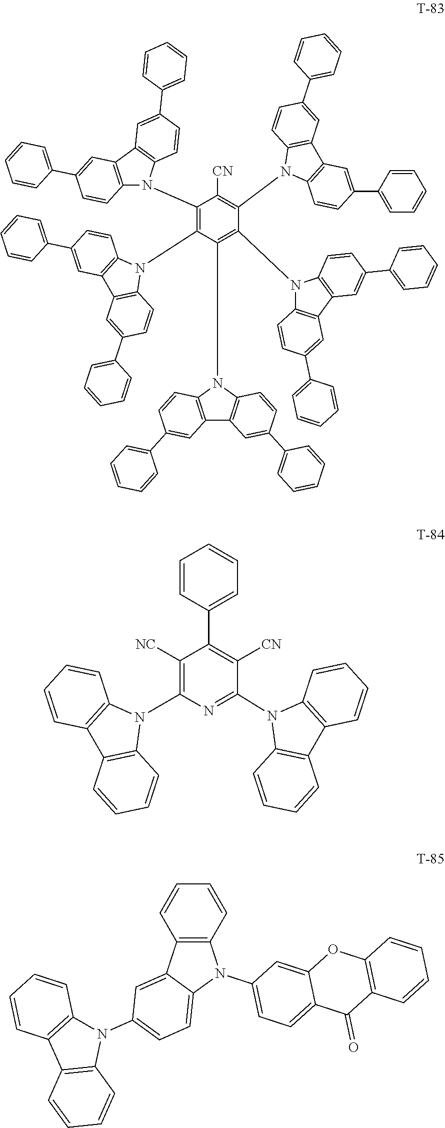 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(-n2c3ccc(-c4ccccc4)cc3c3cc(-c4ccccc4)ccc32)c(-n2c3ccc(-c4ccccc4)cc3c3cc(-c4ccccc4)ccc32)c1-n1c2ccc(-c3ccccc3)cc2c2cc(-c3ccccc3)ccc21 ; N#Cc1c(-n2c3ccccc3c3ccccc32)nc(-n2c3ccccc3c3ccccc32)c(C#N)c1-c1ccccc1 ; O=c1c2ccccc2oc2cc(-n3c4ccccc4c4cc(-n5c6ccccc6c6ccccc65)ccc43)ccc12]

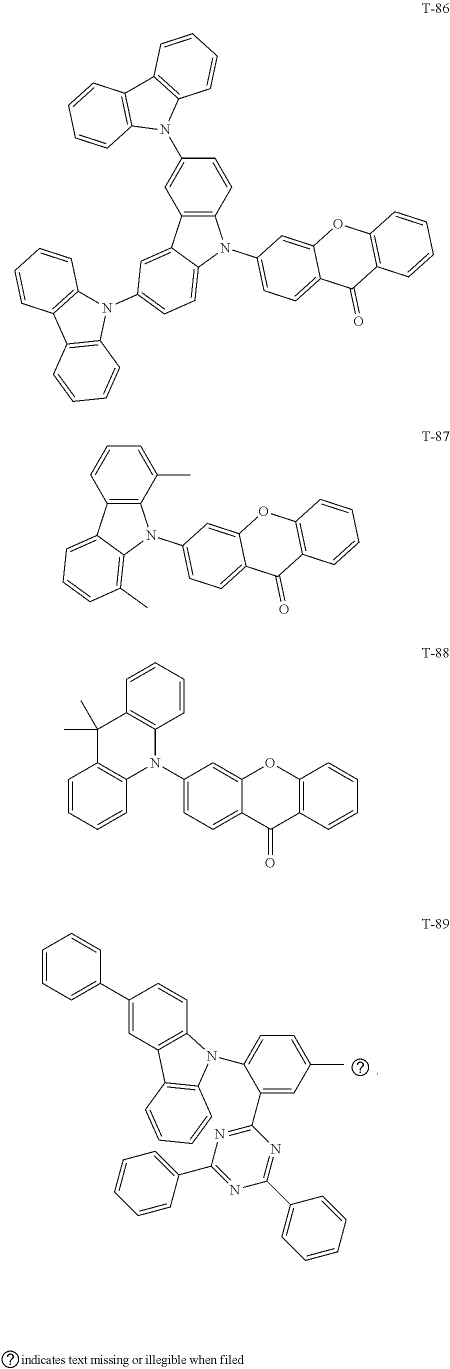 [SMILES: O=c1c2ccccc2oc2cc(-n3c4ccc(-n5c6ccccc6c6ccccc65)cc4c4cc(-n5c6ccccc6c6ccccc65)ccc43)ccc12 ; Cc1cccc2c3cccc(C)c3n(-c3ccc4c(=O)c5ccccc5oc4c3)c12 ; CC1(C)c2ccccc2N(c2ccc3c(=O)c4ccccc4oc3c2)c2ccccc21 ; Cc1ccc(-n2c3ccccc3c3cc(-c4ccccc4)ccc32)c(-c2nc(-c3ccccc3)nc(-c3ccccc3)n2)c1]

The present application does not limit the specific selection of the phosphorescent sensitizer. In an implementation, it may be selected from at least one of the following compounds P1 to P41.

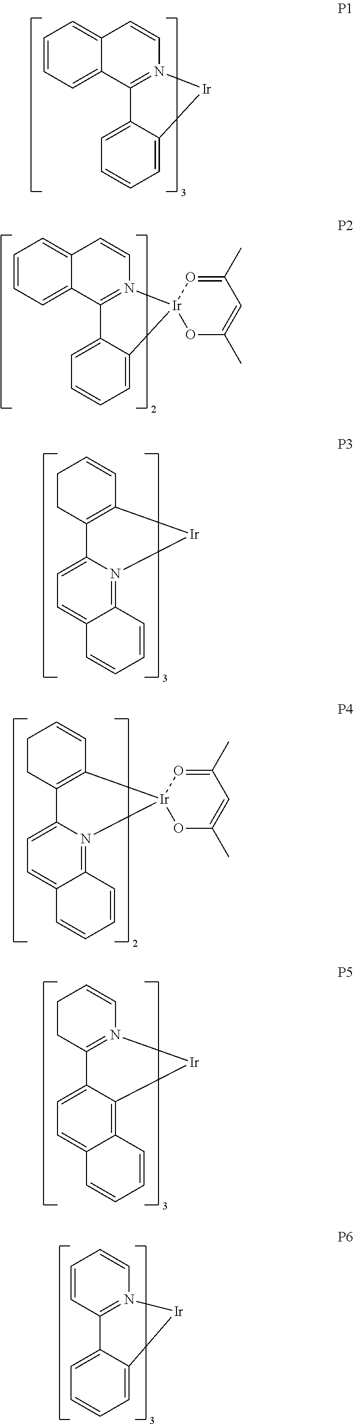

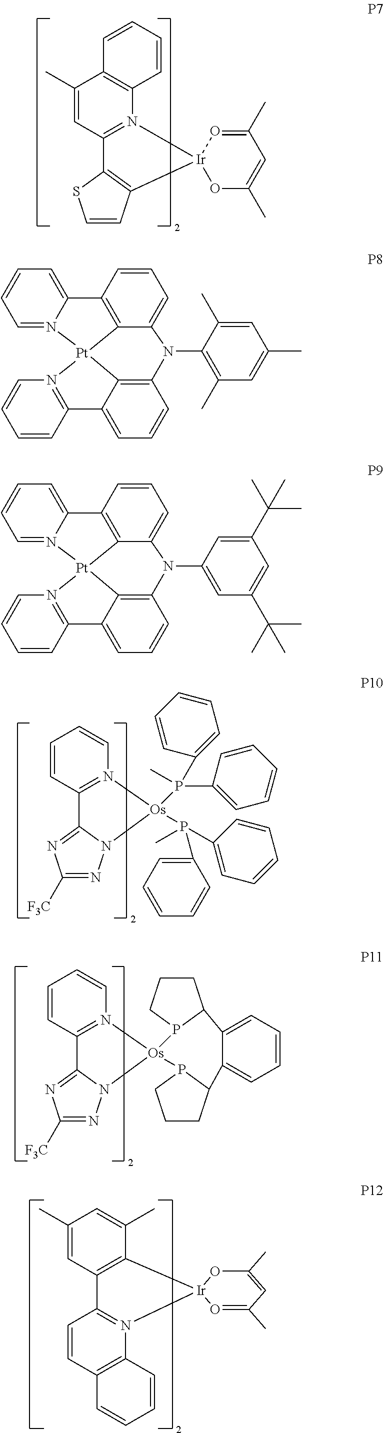

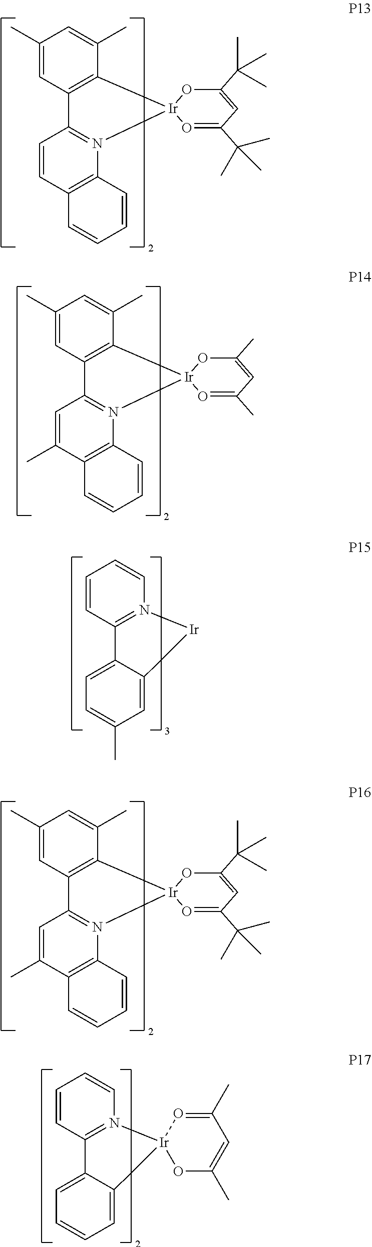

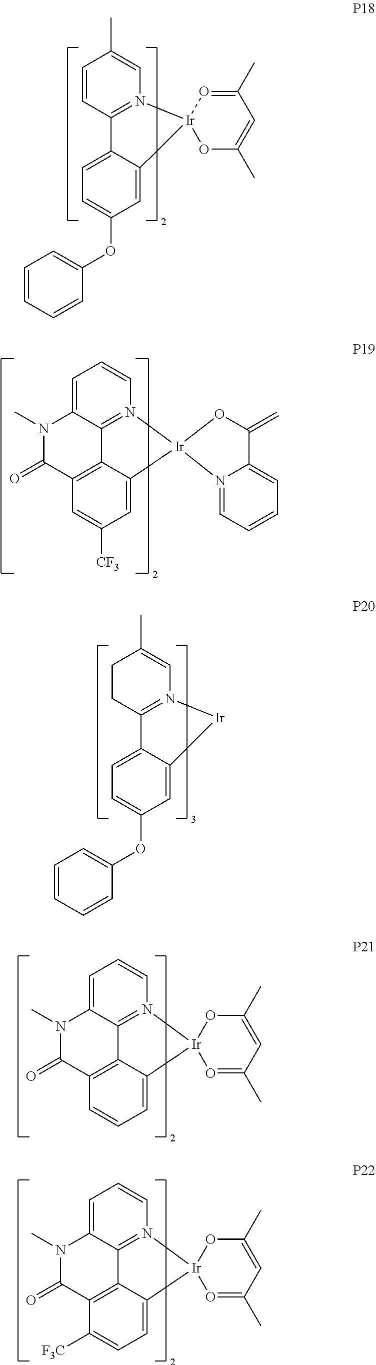

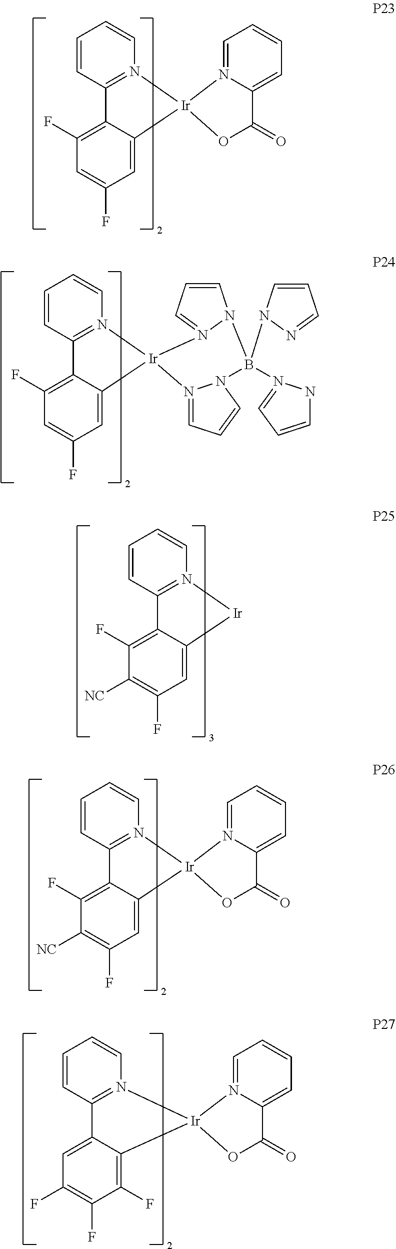

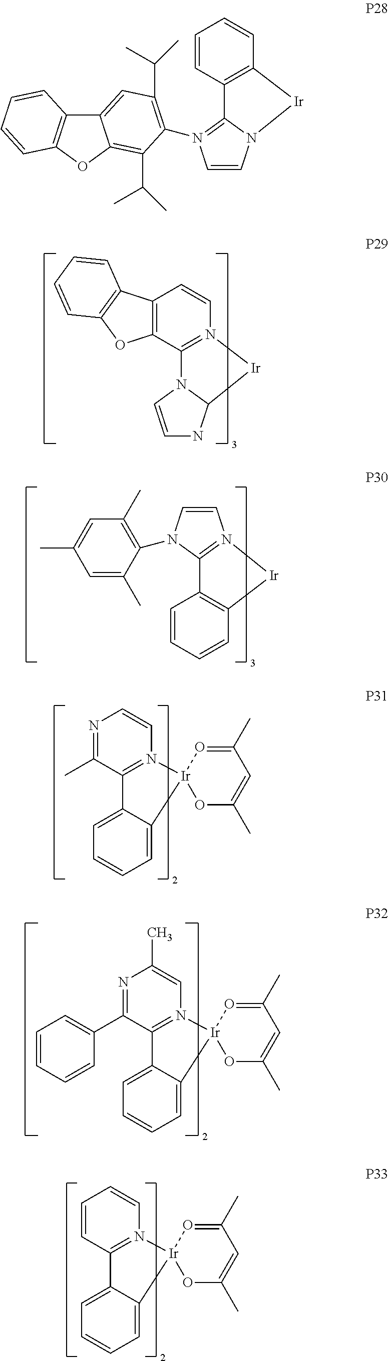

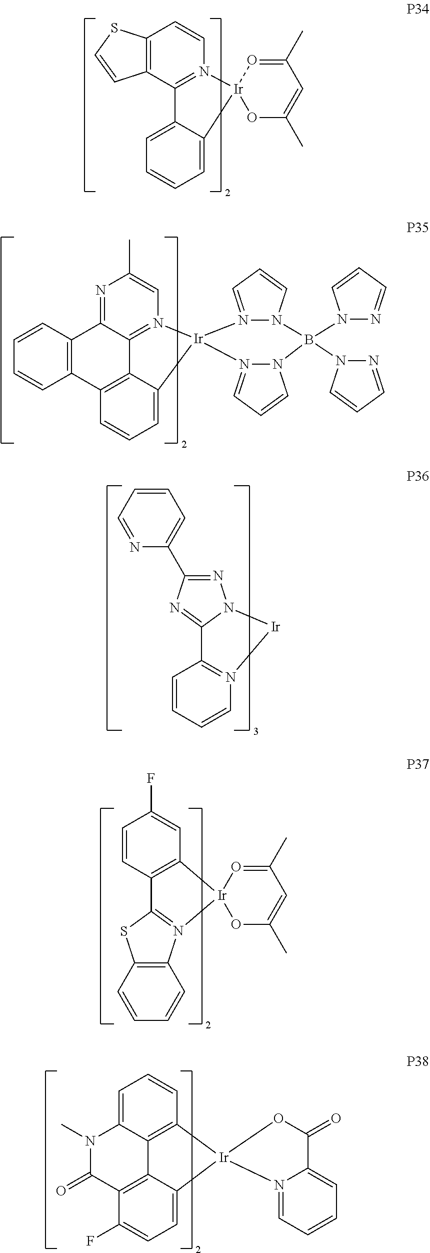

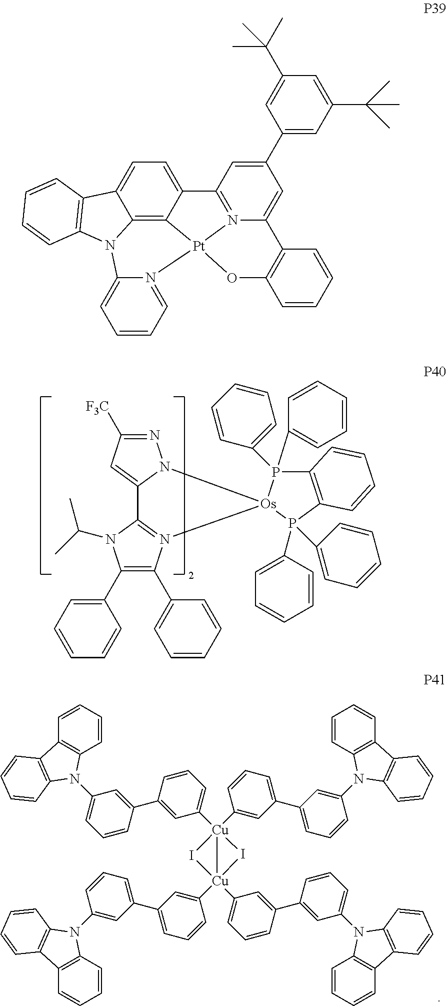

In a specific implementation, the host material may be selected from one of a wide-band-gap material, a TADF material, or a combination of a N-type material and a P-type material.

Where, the wide-band-gap material of the present application is a compound including at least one group of carbazolyl, carbolinyl, spirofluorenyl, fluorenyl, silyl, and phosphonooxy.

The present application does not limit the specific structure of the wide-band-gap material. In an implementation, the wide-band-gap material is selected from a compound represented by one of the following formulas of (w-1) to (w-30):

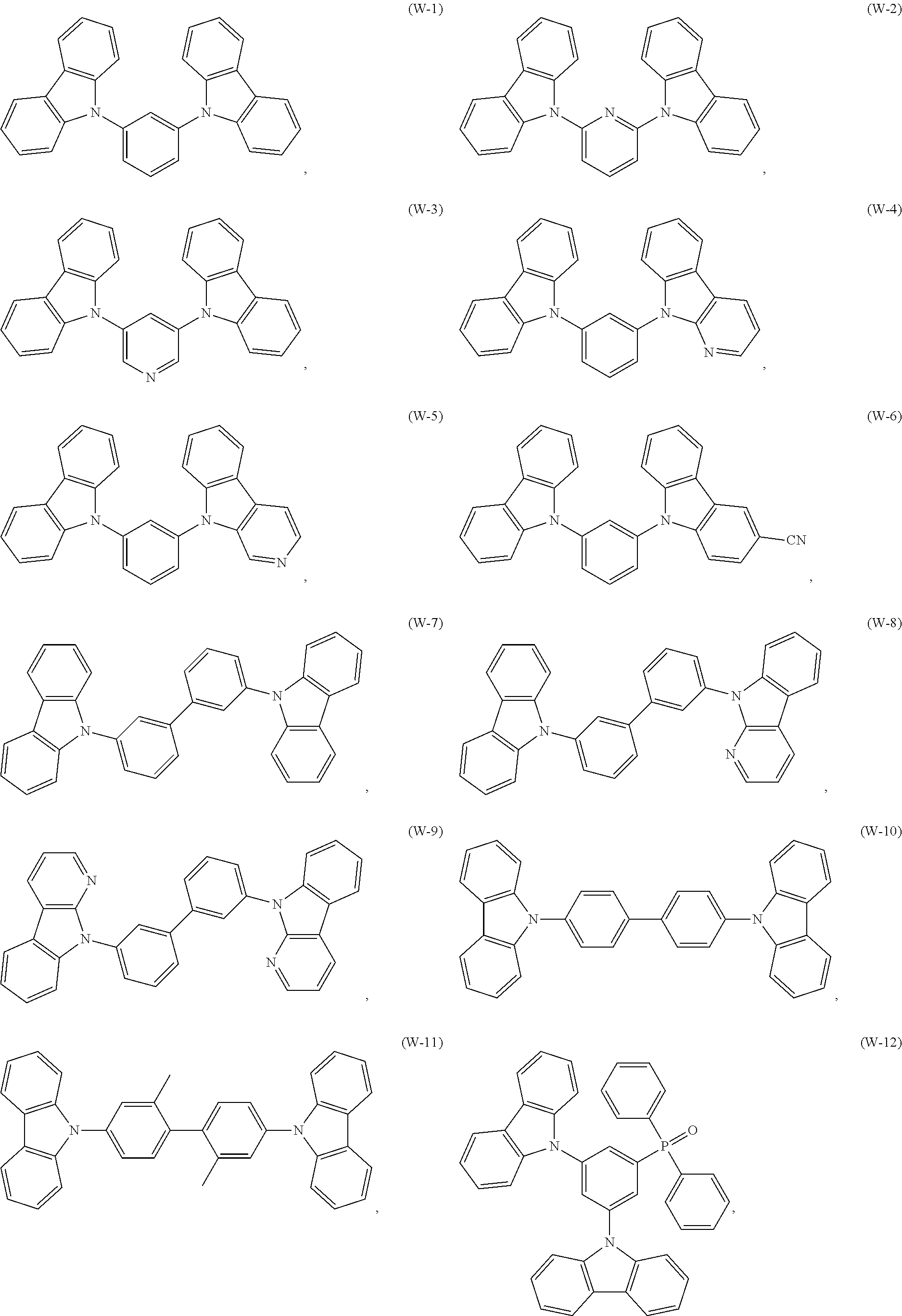

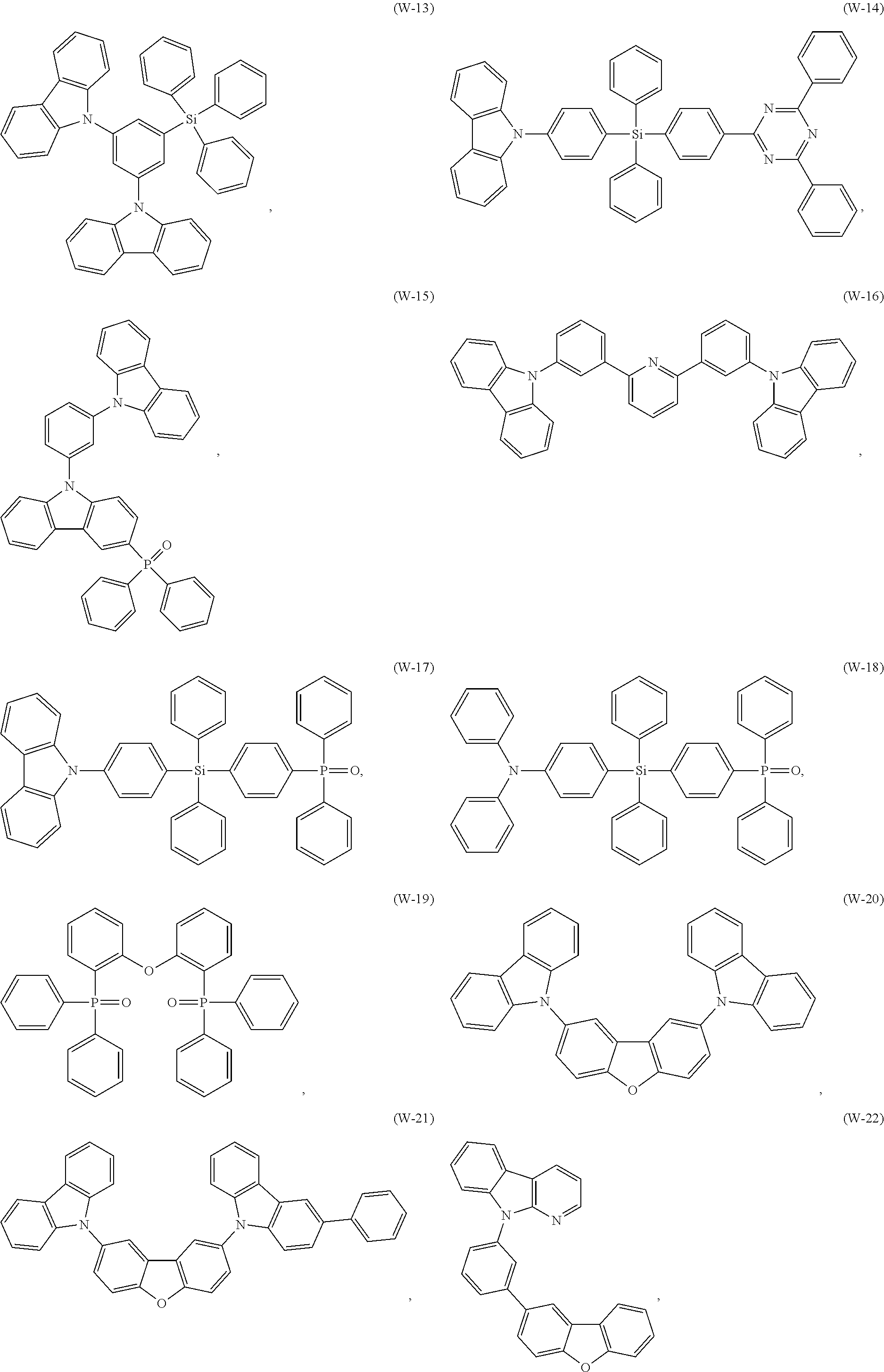

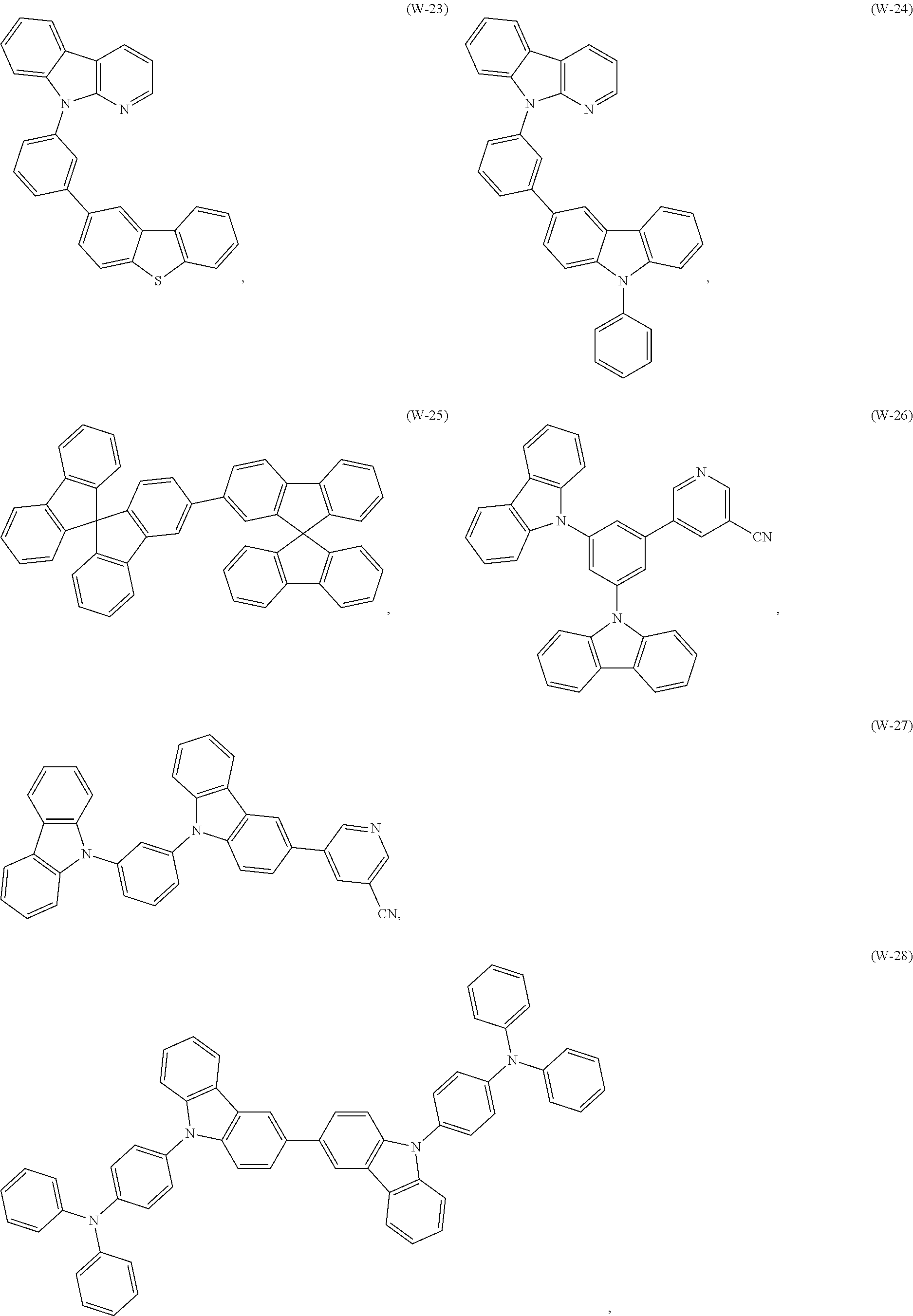

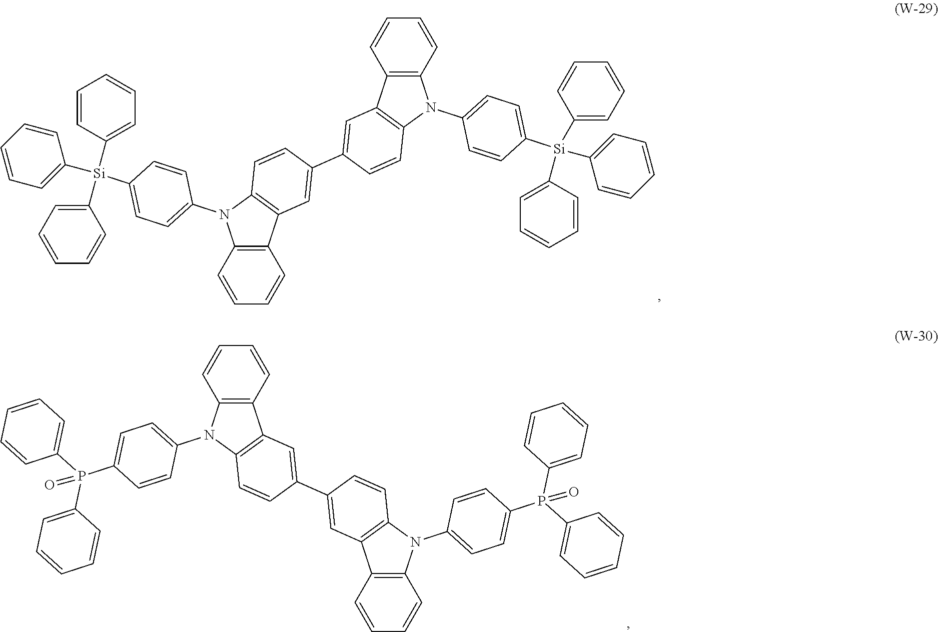

The preset application also does not limit the selection of the TADF material as the host material, for example, it may be selected from at least one of the above compounds of T-1 to T-88. At this time, it should be noted that the energy level of the triplet state of the TADF material as the host material needs to be no lower than that of the TADF material as the sensitizer.

The P-type material is a compound containing at least one group of carbazoly, aromatic amino, silyl, fluorenyl, dibenzothienyl, and dibenzofuranyl aryl and having hole transmission property. Specifically, the P-type material may be and is not limited to a compound represented by one of Formulas (D-1) to (D-19):

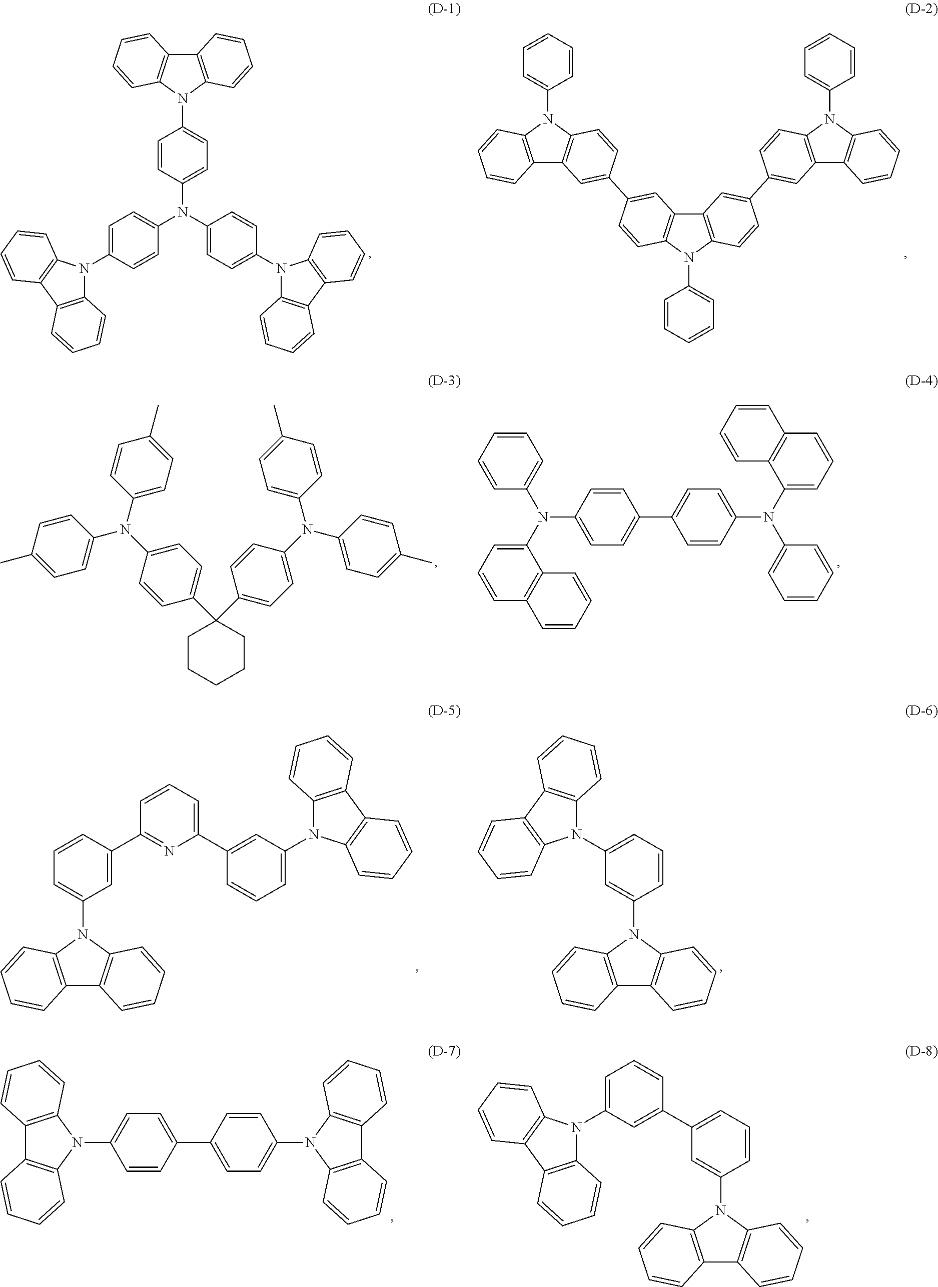

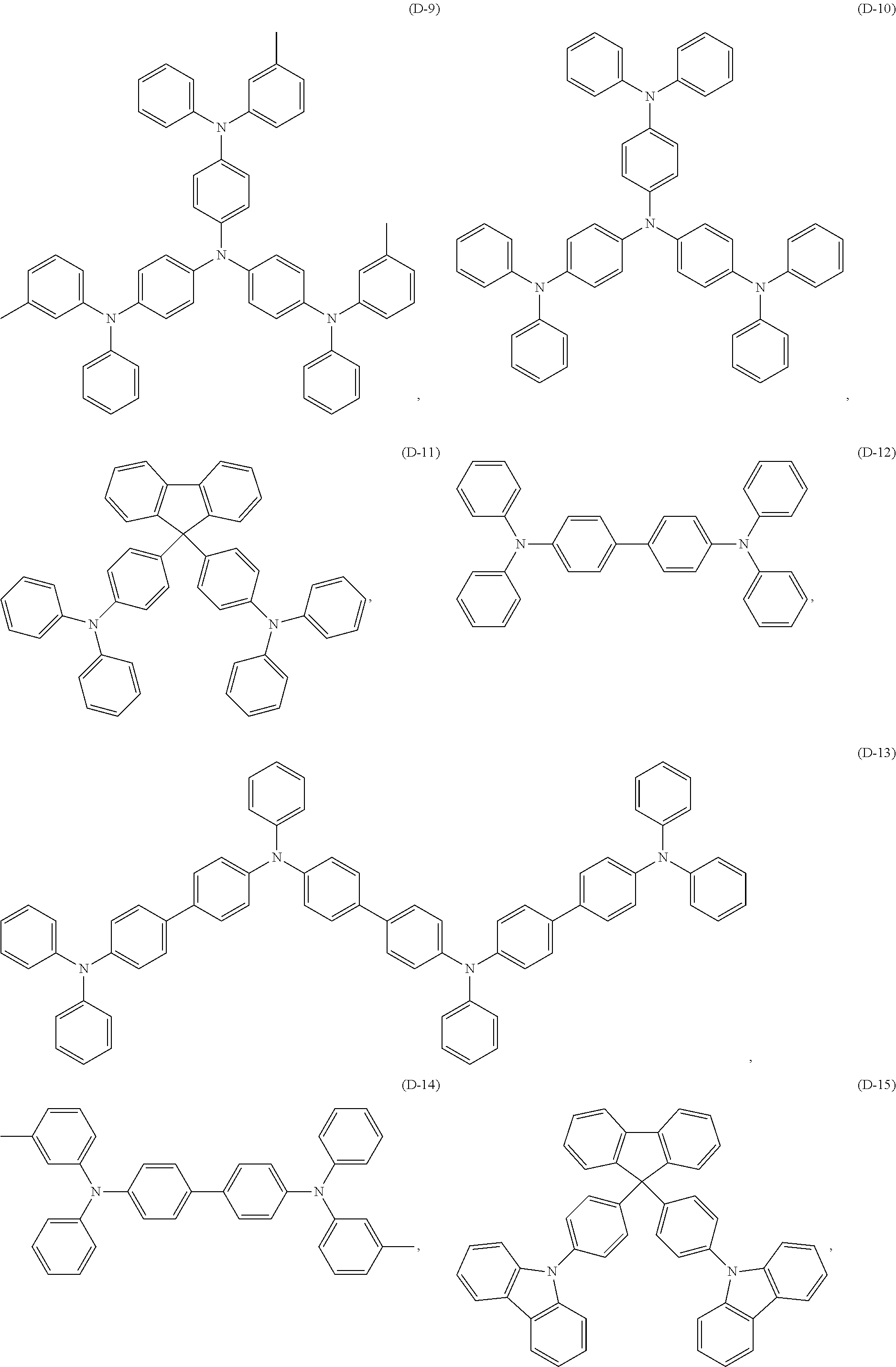

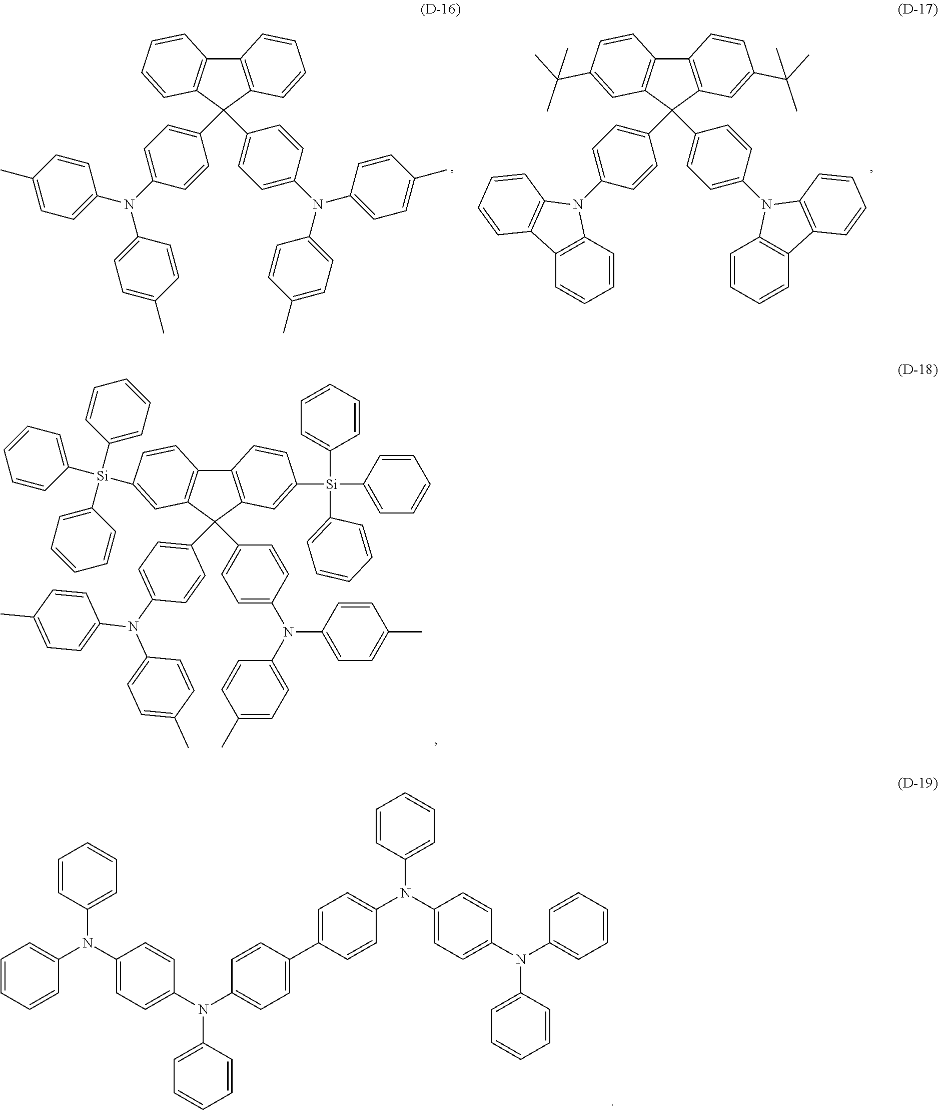

The N-type material is a compound containing at least one group of pyridyl, pyrimidyl, triazinyl, imidazolyl, phenanthrolinyl, sulfuryl, heptanazinyl, oxadiazolyl, cyano, and diphenyl phosphonyl, and having electronic transmission property. Specifically, the N-type material may be and is not limited to, a compound represented by one of the following Formulas (A-1) to (A-19):

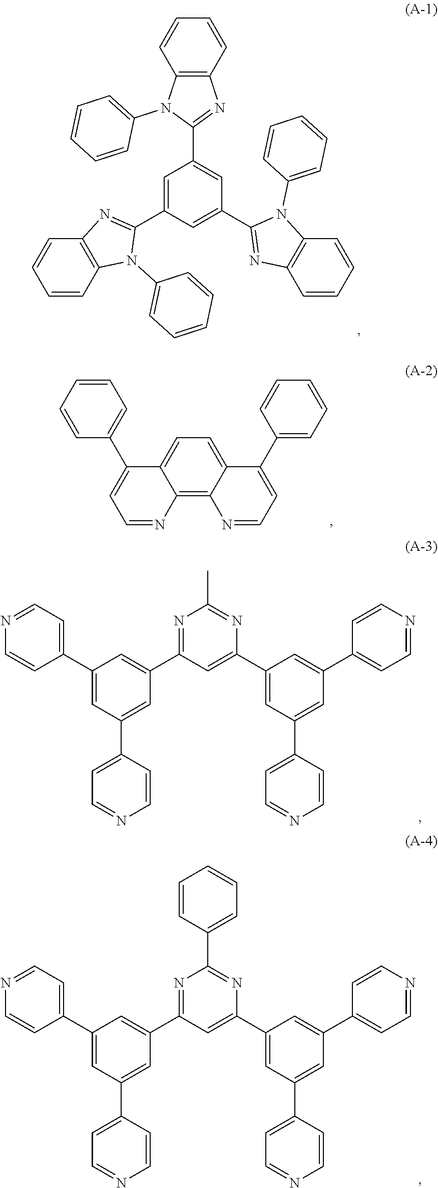 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc(-c2ccnc3c2ccc2c(-c4ccccc4)ccnc23)cc1 ; Cc1nc(-c2cc(-c3ccncc3)cc(-c3ccncc3)c2)cc(-c2cc(-c3ccncc3)cc(-c3ccncc3)c2)n1 ; c1ccc(-c2nc(-c3cc(-c4ccncc4)cc(-c4ccncc4)c3)cc(-c3cc(-c4ccncc4)cc(-c4ccncc4)c3)n2)cc1]

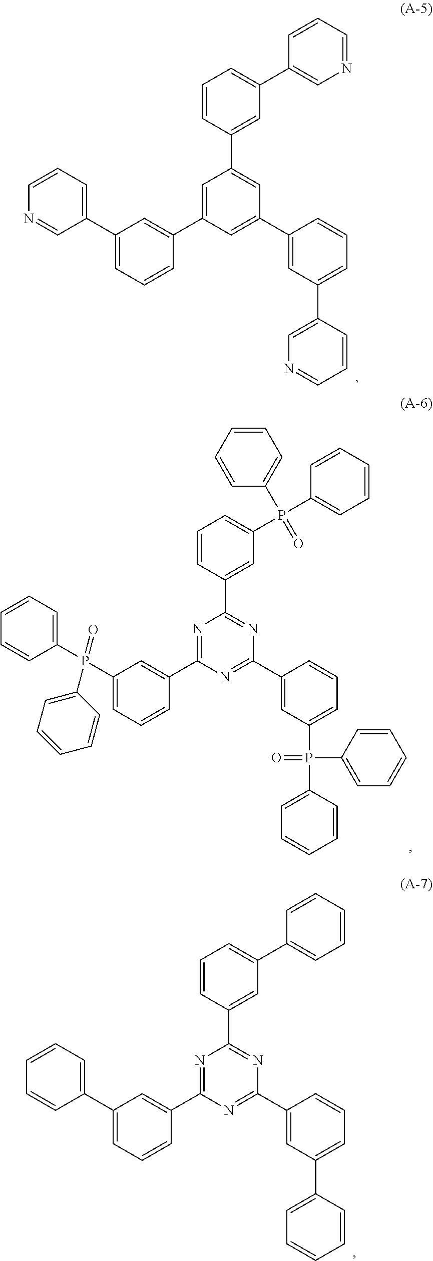

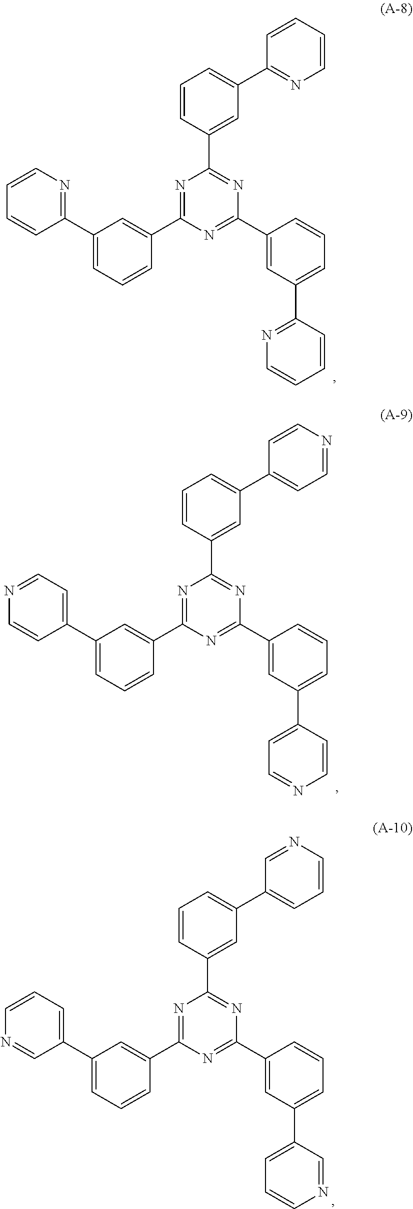

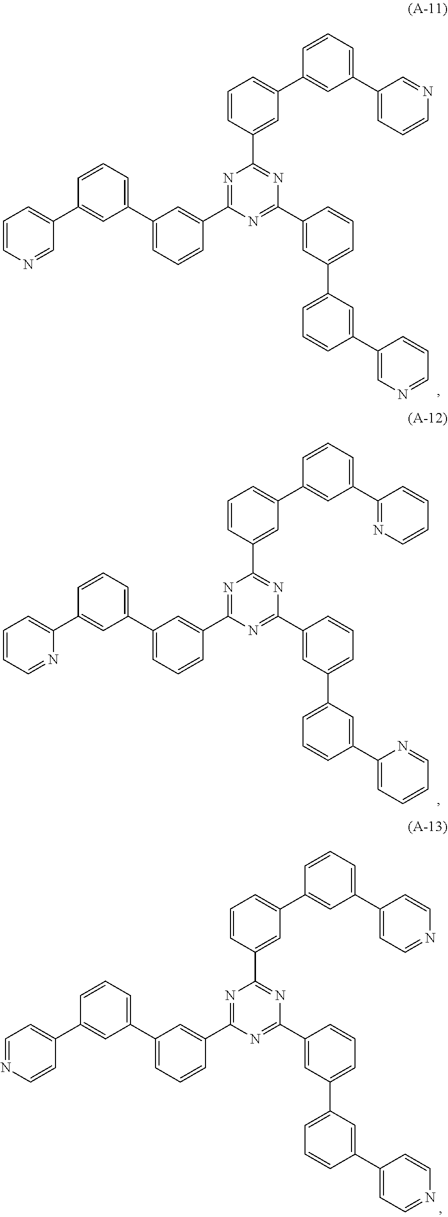 [SMILES: c1cncc(-c2cccc(-c3cccc(-c4nc(-c5cccc(-c6cccc(-c7cccnc7)c6)c5)nc(-c5cccc(-c6cccc(-c7cccnc7)c6)c5)n4)c3)c2)c1 ; c1ccc(-c2cccc(-c3cccc(-c4nc(-c5cccc(-c6cccc(-c7ccccn7)c6)c5)nc(-c5cccc(-c6cccc(-c7ccccn7)c6)c5)n4)c3)c2)nc1 ; c1cc(-c2ccncc2)cc(-c2cccc(-c3nc(-c4cccc(-c5cccc(-c6ccncc6)c5)c4)nc(-c4cccc(-c5cccc(-c6ccncc6)c5)c4)n3)c2)c1]

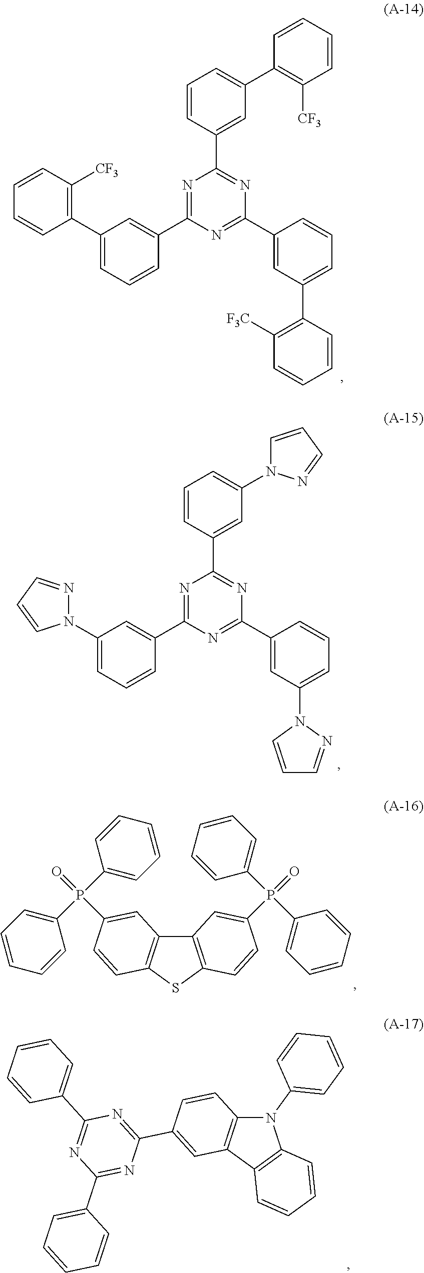

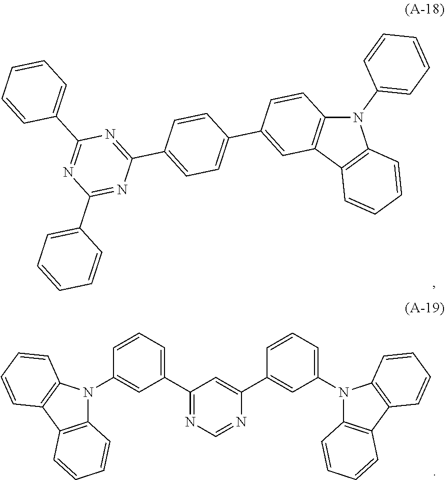 [SMILES: c1ccc(-c2nc(-c3ccccc3)nc(-c3ccc(-c4ccc5c(c4)c4ccccc4n5-c4ccccc4)cc3)n2)cc1 ; c1cc(-c2cc(-c3cccc(-n4c5ccccc5c5ccccc54)c3)ncn2)cc(-n2c3ccccc3c3ccccc32)c1]

In an implementation, suitable P-type material and N-type material can be selected to make the host material be an exciplex having property of reverse intersystem crossing.

In a specific implementation process of the present application, reasonable control of the proportions of the host material, sensitizer, and dye in the light-emitting layer is beneficial to further improve the efficiency of the device and extend its service life. When the mass percentage content of the dye in the light-emitting layer is less than or equal to that of the sensitizer in the light-emitting layer, which is beneficial to improve the luminescence efficiency.

Furthermore, the inventors find that when the light-emitting layer includes 0.1-5% of the dye and 1-50% of the sensitizer based on the mass percentage content, the efficiency of the organic electroluminescent device will be significantly improved.

In above organic electroluminescent device, the thickness of the light-emitting layer is generally controlled to be 10-60 nm, which is conducive to ensuring the luminescence efficiency of the organic electroluminescent device.

In addition, the present application does not limit the materials of the first functional layer and second functional layer, as long as they can achieve the blocking of electrons and holes respectively.

For example, the materials of a hole injection layer, a hole transmission layer and an electron blocking layer can be selected from, but not limited to, a phthalocyanine derivative such as CuPc, a conductive polymer or a polymer containing a conductive dopant, such as polyphenylene vinylene, polyaniline/dodecylbenzene sulfonic acid (Pani/DBSA), poly (3,4-ethylenedioxythiophene)/poly(4-styrene sulfonate) (PEDOT/PSS), polyaniline/camphor sulfonic acid (Pani/CSA), polyaniline/poly(4-styrene sulfonate) (Pani/PSS), an aromatic amine derivative. Where, the aromatic amine derivative is one or more compounds of HT-1 to HT-34 and of PH-47 to PH-86 below.

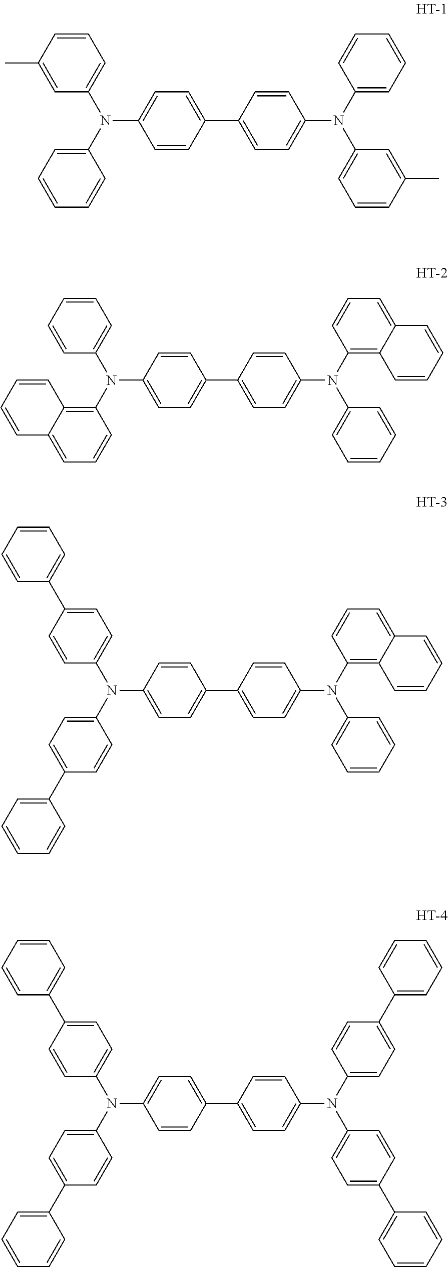

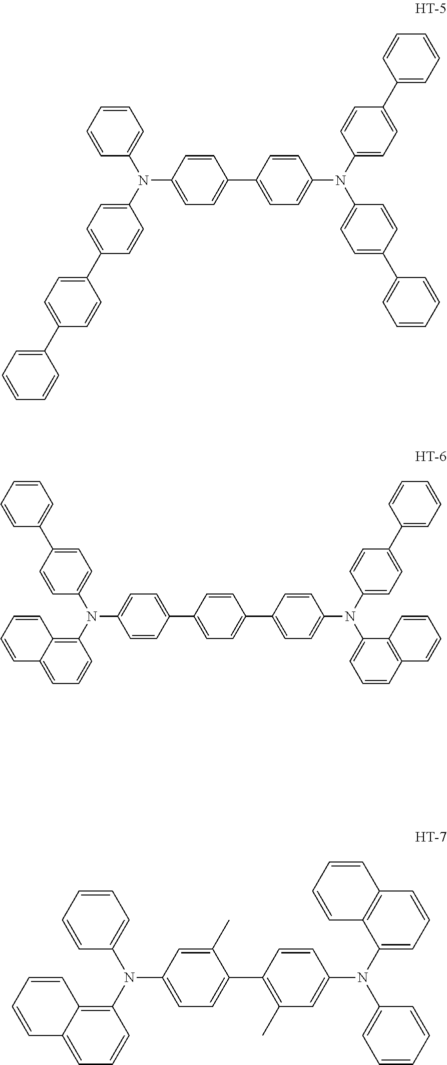 [SMILES: c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccc(-c5ccc(N(c6ccc(-c7ccccc7)cc6)c6cccc7ccccc67)cc5)cc4)cc3)c3cccc4ccccc34)cc2)cc1 ; Cc1cc(N(c2ccccc2)c2cccc3ccccc23)ccc1-c1ccc(N(c2ccccc2)c2cccc3ccccc23)cc1C]

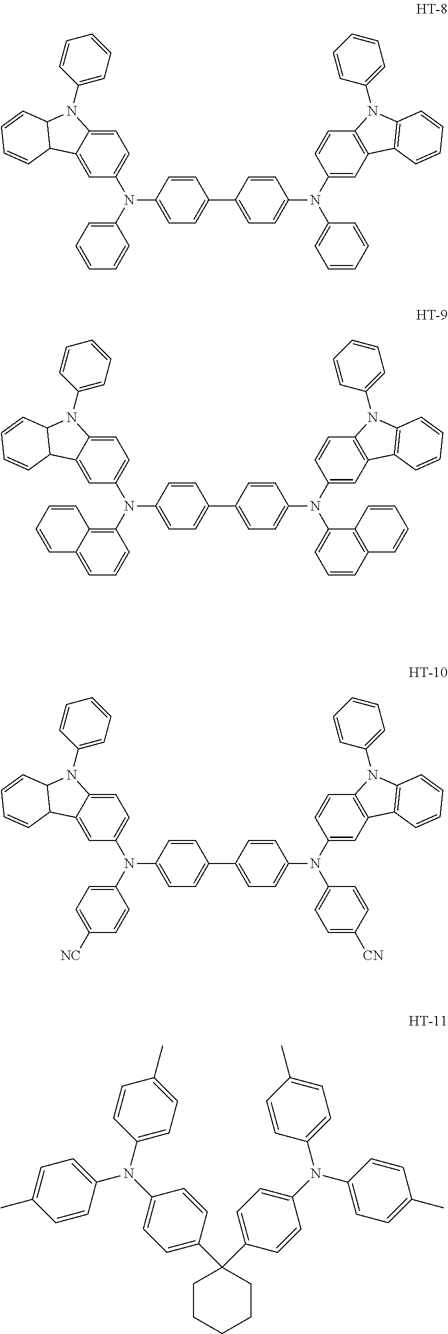

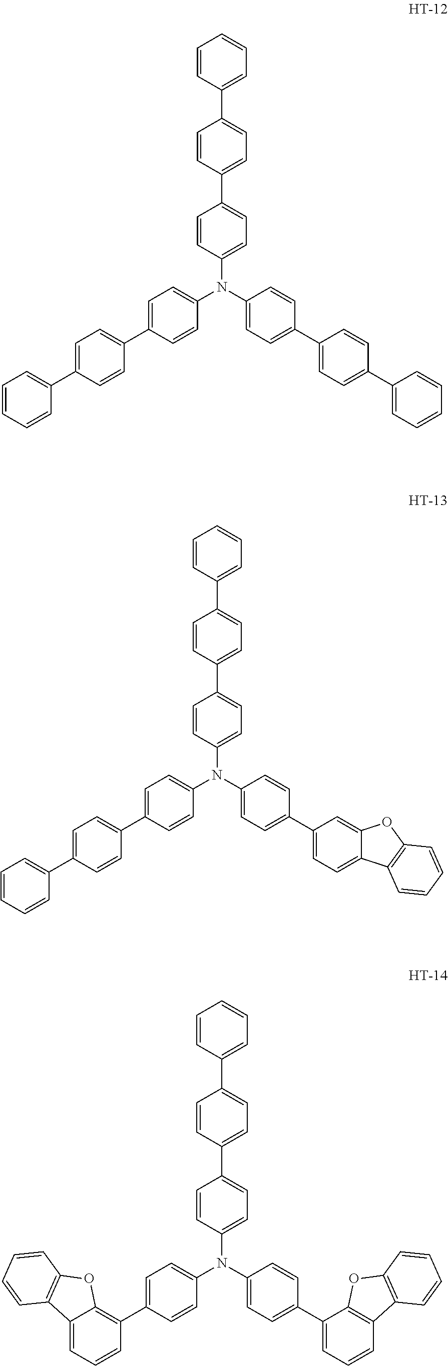 [SMILES: c1ccc(-c2ccc(-c3ccc(N(c4ccc(-c5ccc(-c6ccccc6)cc5)cc4)c4ccc(-c5ccc(-c6ccccc6)cc5)cc4)cc3)cc2)cc1 ; c1ccc(-c2ccc(-c3ccc(N(c4ccc(-c5ccc(-c6ccccc6)cc5)cc4)c4ccc(-c5ccc6c(c5)oc5ccccc56)cc4)cc3)cc2)cc1 ; c1ccc(-c2ccc(-c3ccc(N(c4ccc(-c5cccc6c5oc5ccccc56)cc4)c4ccc(-c5cccc6c5oc5ccccc56)cc4)cc3)cc2)cc1]

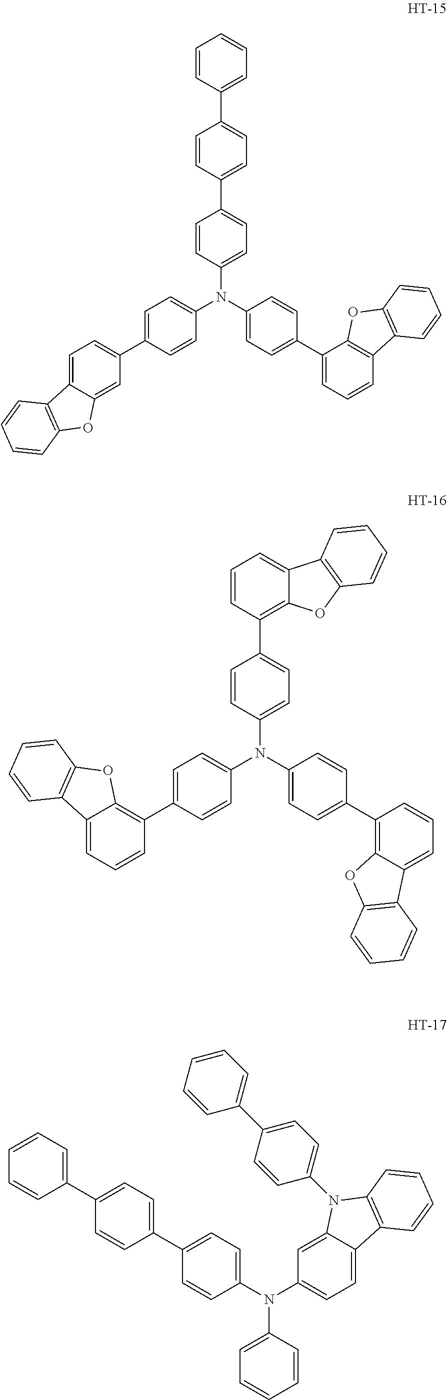 [SMILES: c1ccc(-c2ccc(-c3ccc(N(c4ccc(-c5ccc6c(c5)oc5ccccc56)cc4)c4ccc(-c5cccc6c5oc5ccccc56)cc4)cc3)cc2)cc1 ; c1ccc2c(c1)oc1c(-c3ccc(N(c4ccc(-c5cccc6c5oc5ccccc56)cc4)c4ccc(-c5cccc6c5oc5ccccc56)cc4)cc3)cccc12 ; c1ccc(-c2ccc(-c3ccc(N(c4ccccc4)c4ccc5c6ccccc6n(-c6ccc(-c7ccccc7)cc6)c5c4)cc3)cc2)cc1]

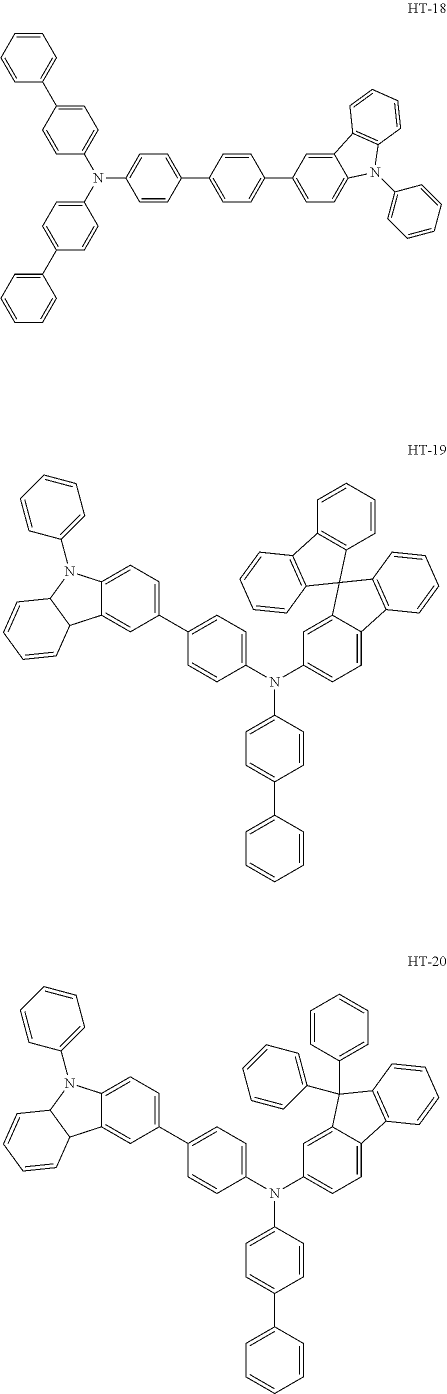 [SMILES: c1ccc(-c2ccc(N(c3ccc(-c4ccccc4)cc3)c3ccc(-c4ccc(-c5ccc6c(c5)c5ccccc5n6-c5ccccc5)cc4)cc3)cc2)cc1 ; C1=CC2c3cc(-c4ccc(N(c5ccc(-c6ccccc6)cc5)c5ccc6c(c5)C5(c7ccccc7-c7ccccc75)c5ccccc5-6)cc4)ccc3N(c3ccccc3)C2C=C1 ; C1=CC2c3cc(-c4ccc(N(c5ccc(-c6ccccc6)cc5)c5ccc6c(c5)C(c5ccccc5)(c5ccccc5)c5ccccc5-6)cc4)ccc3N(c3ccccc3)C2C=C1]

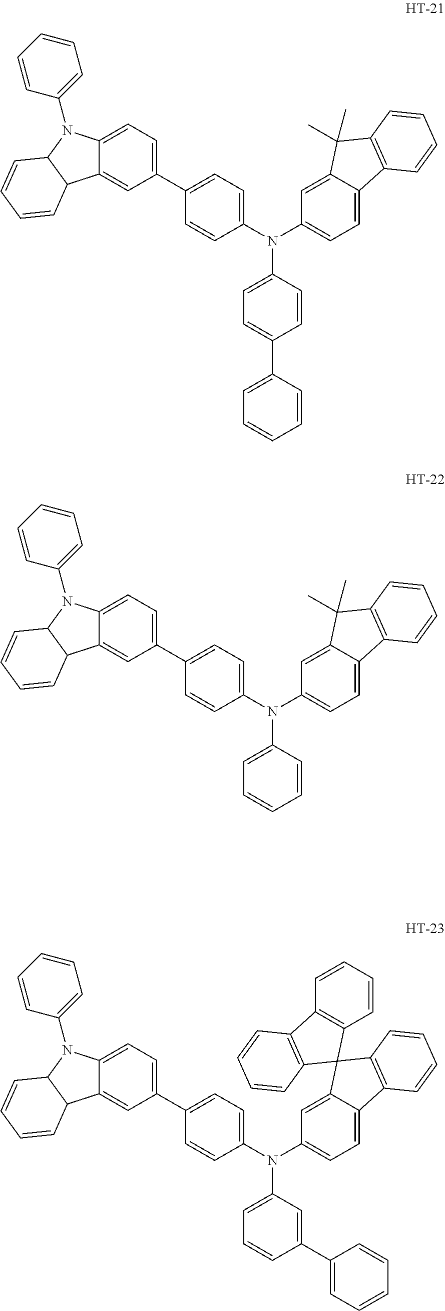 [SMILES: CC1(C)c2ccccc2-c2ccc(N(c3ccc(-c4ccccc4)cc3)c3ccc(-c4ccc5c(c4)C4C=CC=CC4N5c4ccccc4)cc3)cc21 ; CC1(C)c2ccccc2-c2ccc(N(c3ccccc3)c3ccc(-c4ccc5c(c4)C4C=CC=CC4N5c4ccccc4)cc3)cc21 ; C1=CC2c3cc(-c4ccc(N(c5cccc(-c6ccccc6)c5)c5ccc6c(c5)C5(c7ccccc7-c7ccccc75)c5ccccc5-6)cc4)ccc3N(c3ccccc3)C2C=C1]

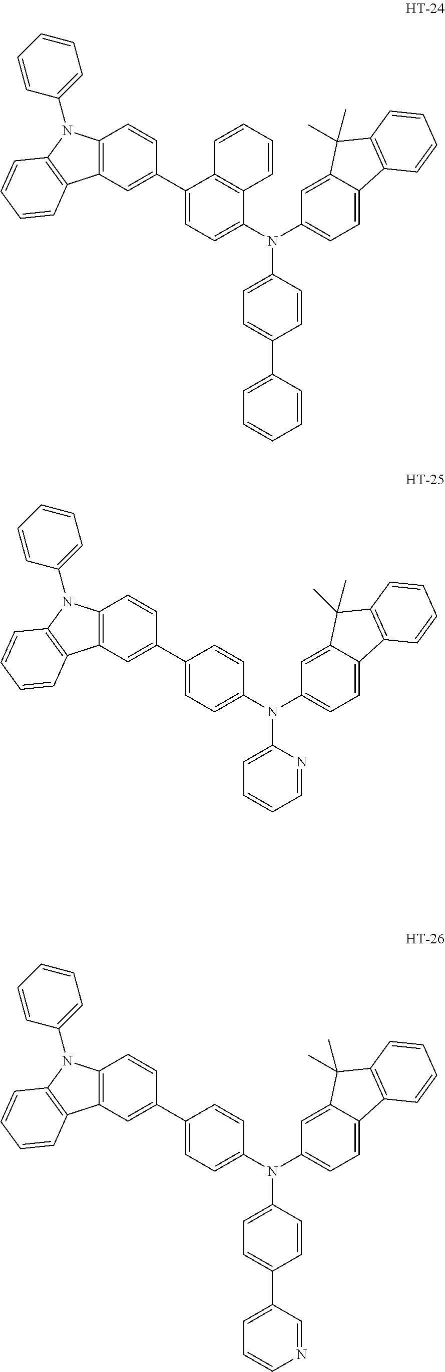 [SMILES: CC1(C)c2ccccc2-c2ccc(N(c3ccc(-c4ccccc4)cc3)c3ccc(-c4ccc5c(c4)c4ccccc4n5-c4ccccc4)c4ccccc34)cc21 ; CC1(C)c2ccccc2-c2ccc(N(c3ccc(-c4ccc5c(c4)c4ccccc4n5-c4ccccc4)cc3)c3ccccn3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

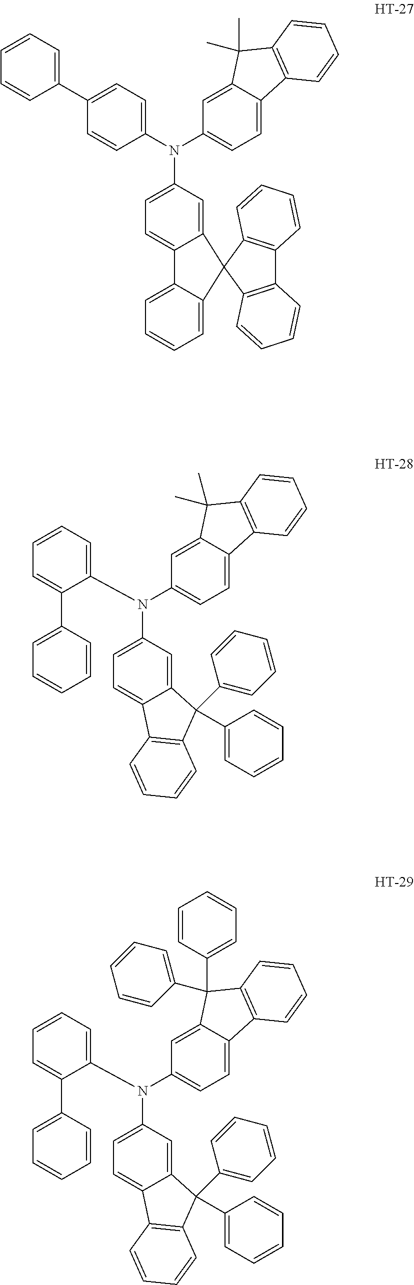 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C(c3ccccc3)(c3ccccc3)c3ccccc3-4)c3ccccc3-c3ccccc3)cc21 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

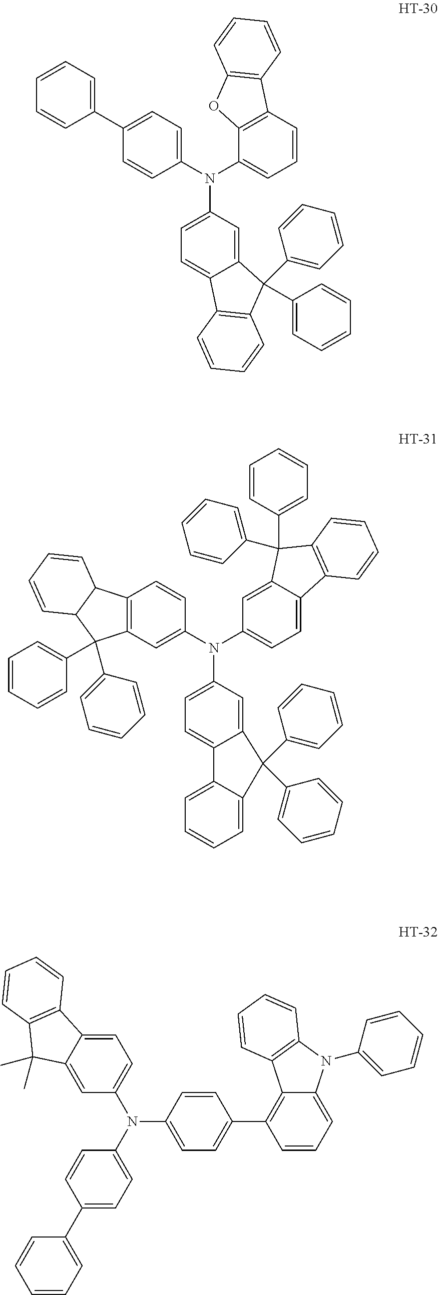 [SMILES: c1ccc(-c2ccc(N(c3ccc4c(c3)C(c3ccccc3)(c3ccccc3)c3ccccc3-4)c3cccc4c3oc3ccccc34)cc2)cc1 ; C1=CC2c3ccc(N(c4ccc5c(c4)C(c4ccccc4)(c4ccccc4)c4ccccc4-5)c4ccc5c(c4)C(c4ccccc4)(c4ccccc4)c4ccccc4-5)cc3C(c3ccccc3)(c3ccccc3)C2C=C1 ; CC1(C)c2ccccc2-c2ccc(N(c3ccc(-c4ccccc4)cc3)c3ccc(-c4cccc5c4c4ccccc4n5-c4ccccc4)cc3)cc21]

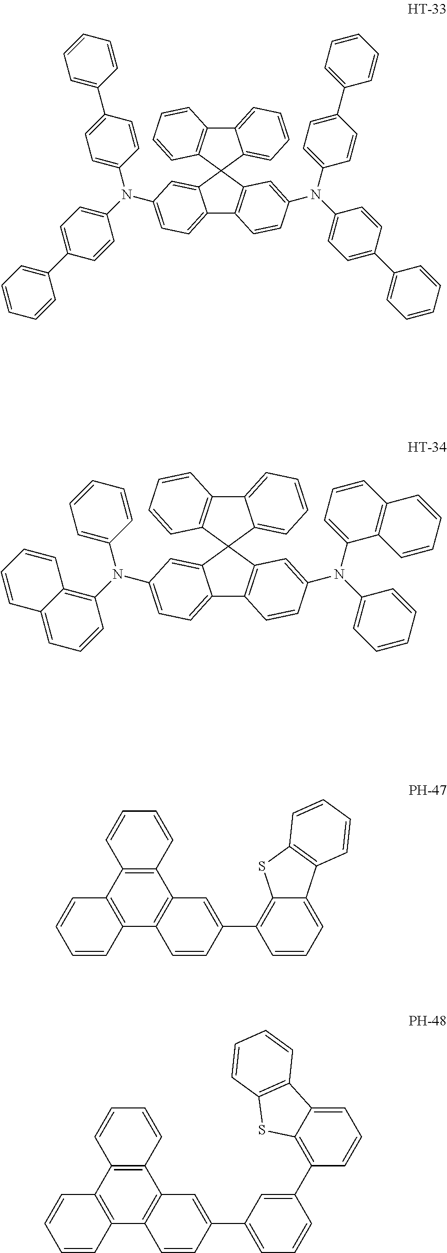 [SMILES: c1ccc(-c2ccc(N(c3ccc(-c4ccccc4)cc3)c3ccc4c(c3)C3(c5ccccc5-c5ccccc53)c3cc(N(c5ccc(-c6ccccc6)cc5)c5ccc(-c6ccccc6)cc5)ccc3-4)cc2)cc1 ; c1ccc(N(c2ccc3c(c2)C2(c4ccccc4-c4ccccc42)c2cc(N(c4ccccc4)c4cccc5ccccc45)ccc2-3)c2cccc3ccccc23)cc1 ; c1ccc2c(c1)sc1c(-c3ccc4c5ccccc5c5ccccc5c4c3)cccc12 ; c1cc(-c2ccc3c4ccccc4c4ccccc4c3c2)cc(-c2cccc3c2sc2ccccc23)c1]

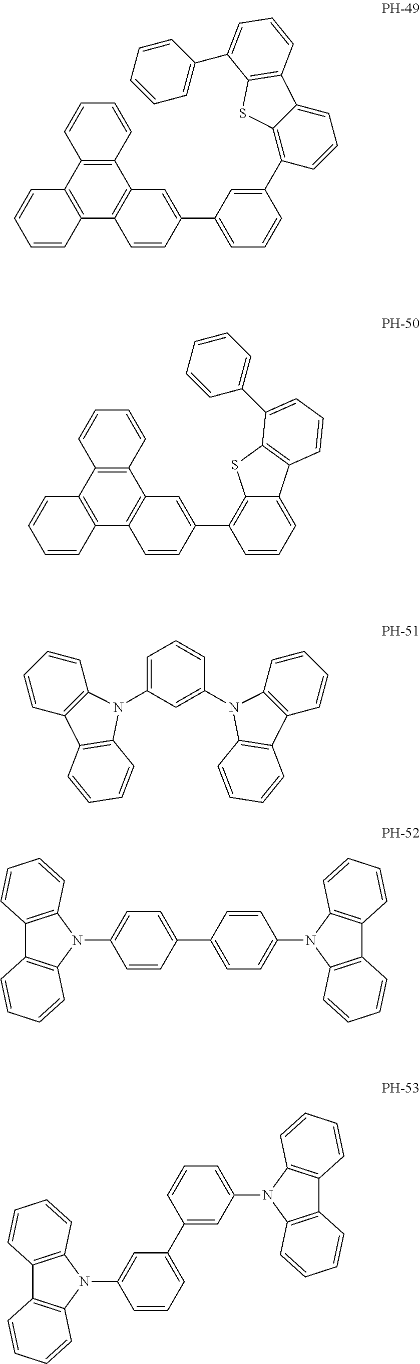 [SMILES: c1ccc(-c2cccc3c2sc2c(-c4cccc(-c5ccc6c7ccccc7c7ccccc7c6c5)c4)cccc23)cc1 ; c1ccc(-c2cccc3c2sc2c(-c4ccc5c6ccccc6c6ccccc6c5c4)cccc23)cc1 ; c1cc(-n2c3ccccc3c3ccccc32)cc(-n2c3ccccc3c3ccccc32)c1 ; c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1]

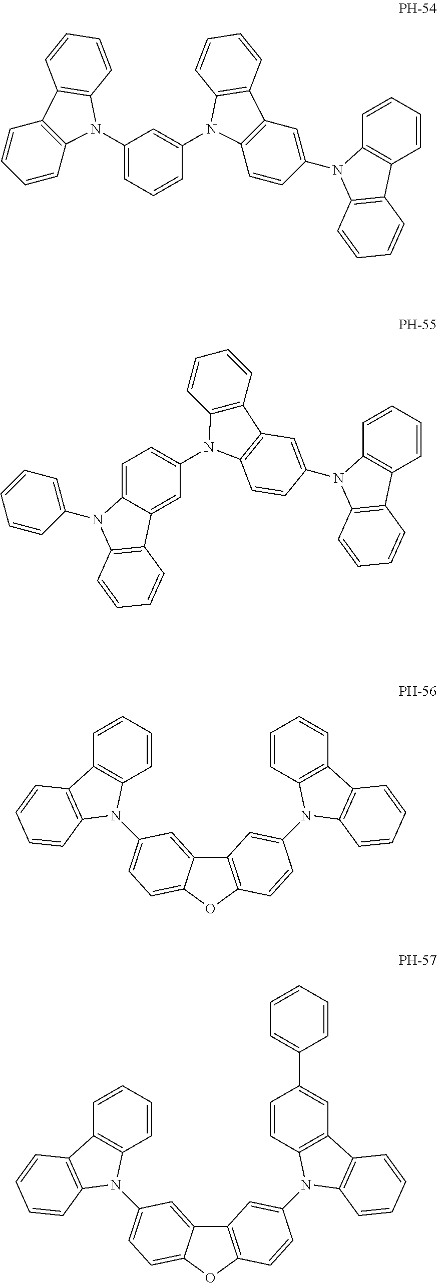 [SMILES: c1cc(-n2c3ccccc3c3ccccc32)cc(-n2c3ccccc3c3cc(-n4c5ccccc5c5ccccc54)ccc32)c1 ; c1ccc(-n2c3ccccc3c3cc(-n4c5ccccc5c5cc(-n6c7ccccc7c7ccccc76)ccc54)ccc32)cc1 ; c1ccc2c(c1)c1ccccc1n2-c1ccc2oc3ccc(-n4c5ccccc5c5ccccc54)cc3c2c1 ; c1ccc(-c2ccc3c(c2)c2ccccc2n3-c2ccc3oc4ccc(-n5c6ccccc6c6ccccc65)cc4c3c2)cc1]

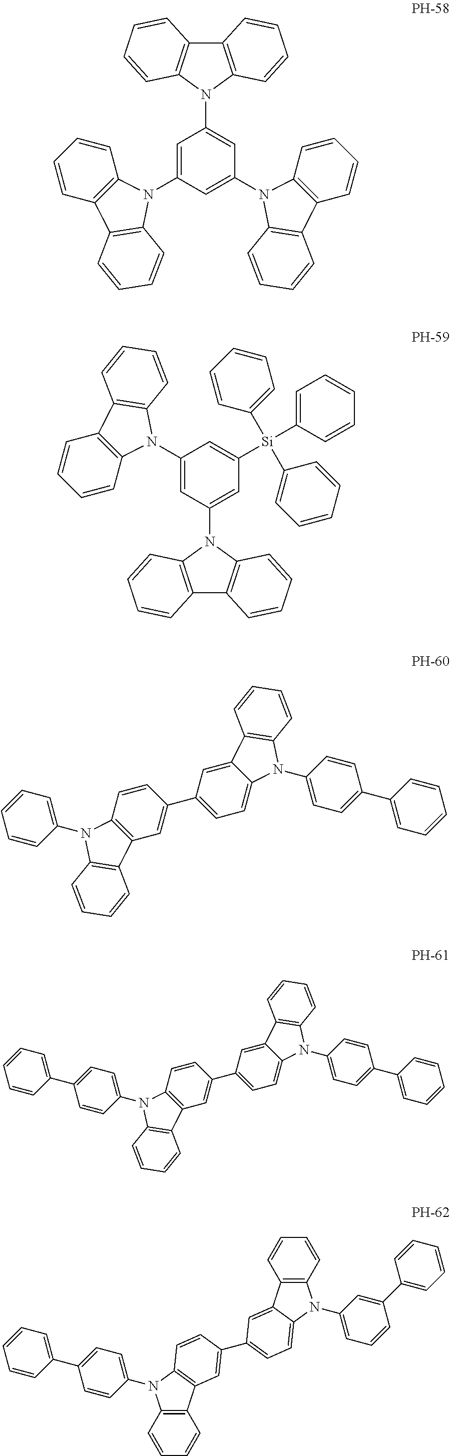 [SMILES: c1ccc2c(c1)c1ccccc1n2-c1cc(-n2c3ccccc3c3ccccc32)cc(-n2c3ccccc3c3ccccc32)c1 ; c1ccc([Si](c2ccccc2)(c2ccccc2)c2cc(-n3c4ccccc4c4ccccc43)cc(-n3c4ccccc4c4ccccc43)c2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2ccc(-n3c4ccccc4c4cc(-c5ccc6c(c5)c5ccccc5n6-c5cccc(-c6ccccc6)c5)ccc43)cc2)cc1]

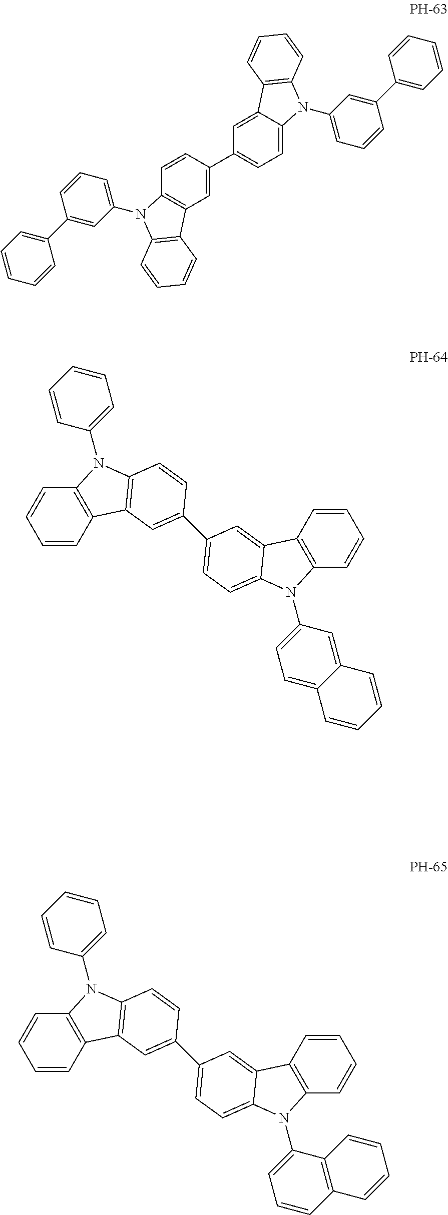 [SMILES: c1ccc(-c2cccc(-n3c4ccccc4c4cc(-c5ccc6c(c5)c5ccccc5n6-c5cccc(-c6ccccc6)c5)ccc43)c2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1]

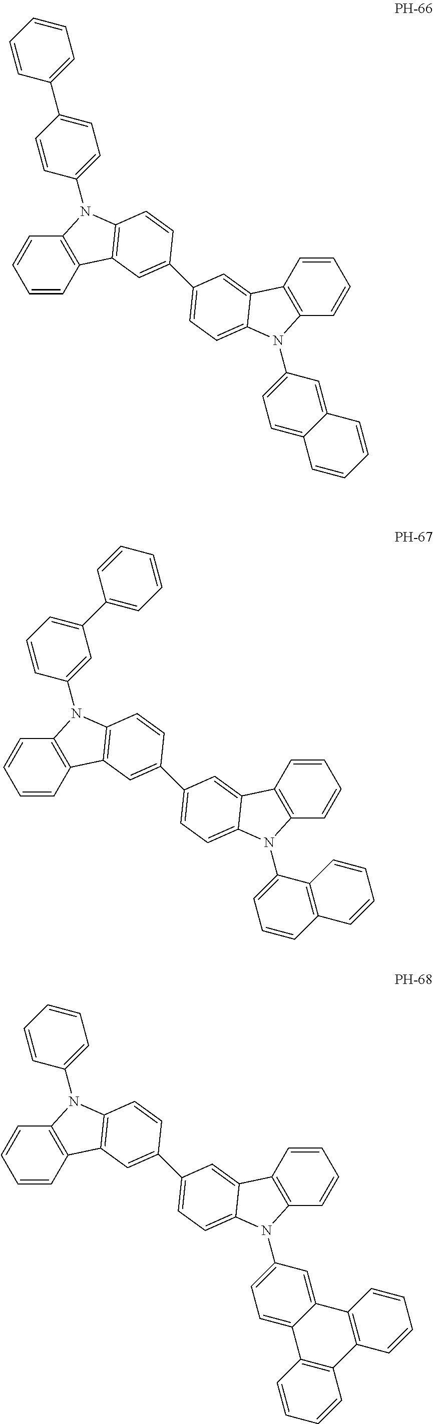 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2cccc(-n3c4ccccc4c4cc(-c5ccc6c(c5)c5ccccc5n6-c5cccc6ccccc56)ccc43)c2)cc1 ; c1ccc(-n2c3ccccc3c3cc(-c4ccc5c(c4)c4ccccc4n5-c4ccc5c6ccccc6c6ccccc6c5c4)ccc32)cc1]

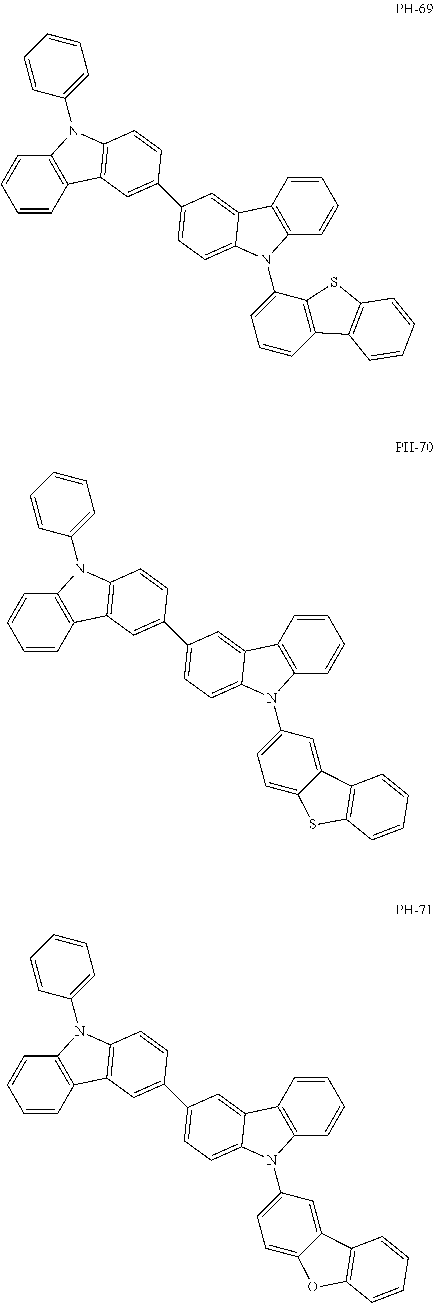 [SMILES: c1ccc(-n2c3ccccc3c3cc(-c4ccc5c(c4)c4ccccc4n5-c4cccc5c4sc4ccccc45)ccc32)cc1 ; c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4ccc5oc6ccccc6c5c4)ccc32)cc1]

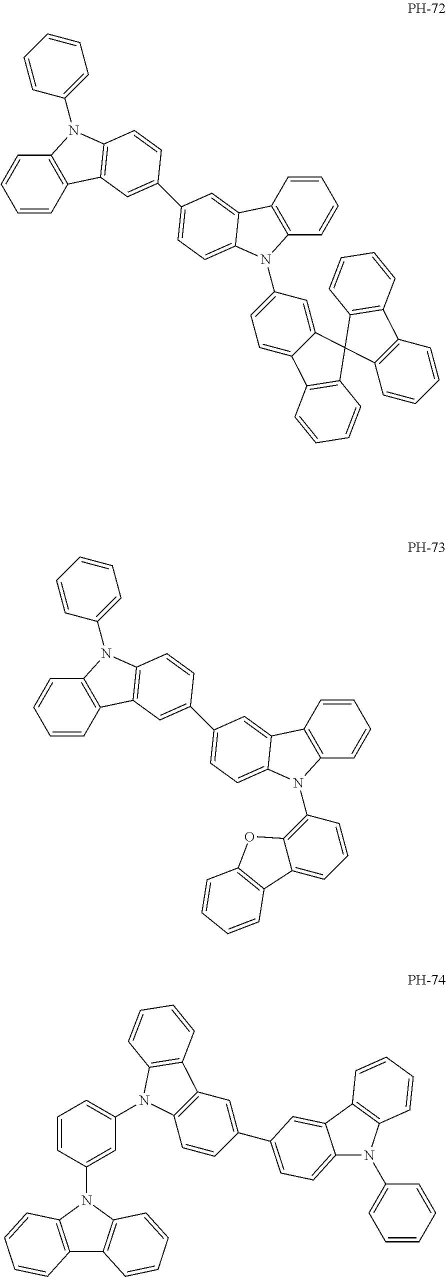 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4cccc(-n5c6ccccc6c6ccccc65)c4)ccc32)cc1]

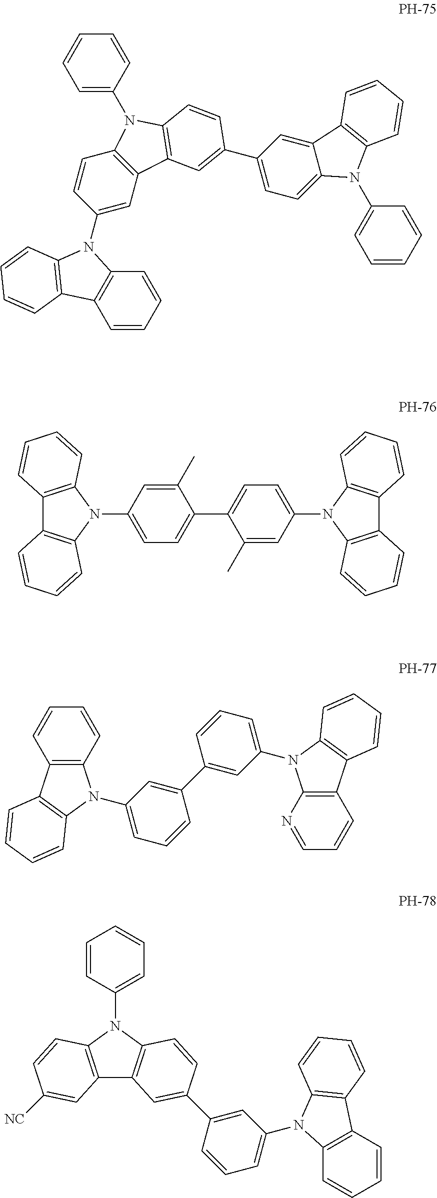 [SMILES: c1ccc(-n2c3ccccc3c3cc(-c4ccc5c(c4)c4cc(-n6c7ccccc7c7ccccc76)ccc4n5-c4ccccc4)ccc32)cc1 ; Cc1cc(-n2c3ccccc3c3ccccc32)ccc1-c1ccc(-n2c3ccccc3c3ccccc32)cc1C ; c1cc(-c2cccc(-n3c4ccccc4c4cccnc43)c2)cc(-n2c3ccccc3c3ccccc32)c1 ; N#Cc1ccc2c(c1)c1cc(-c3cccc(-n4c5ccccc5c5ccccc54)c3)ccc1n2-c1ccccc1]

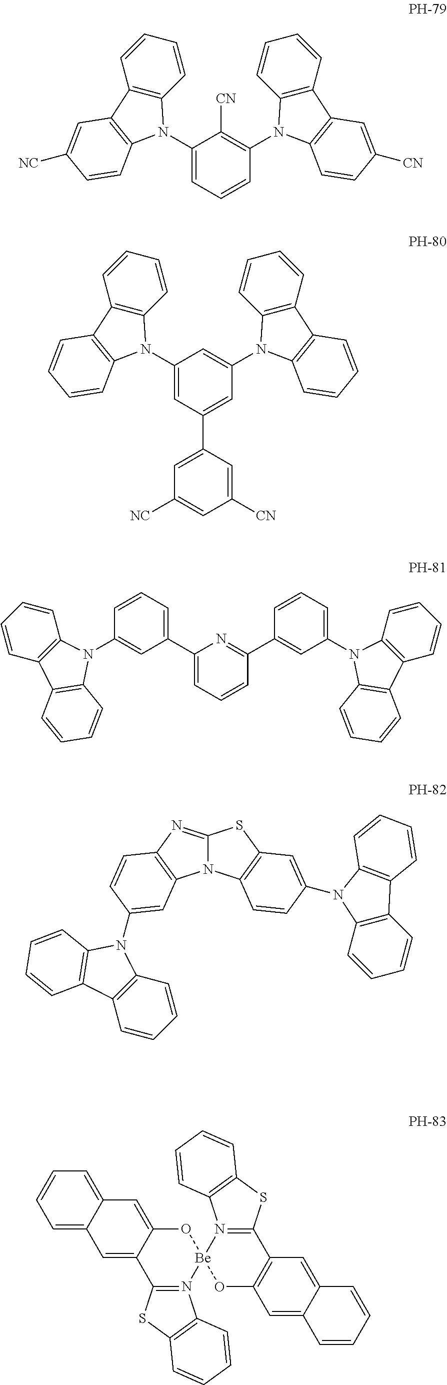

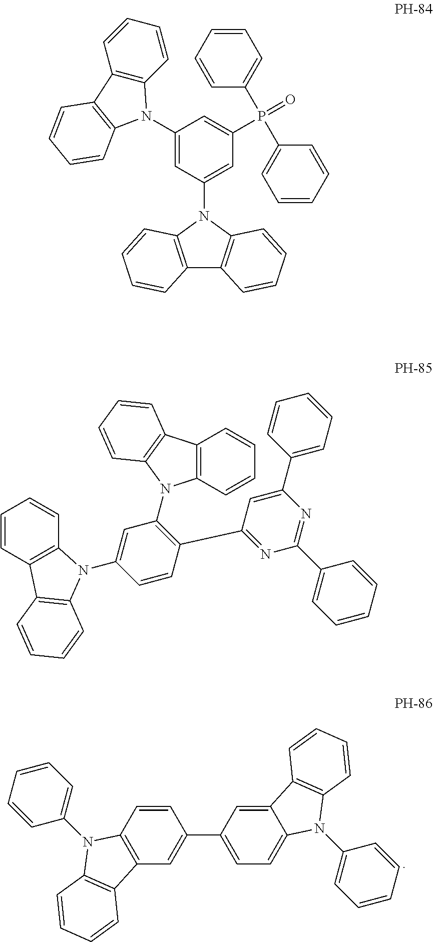 [SMILES: O=P(c1ccccc1)(c1ccccc1)c1cc(-n2c3ccccc3c3ccccc32)cc(-n2c3ccccc3c3ccccc32)c1 ; c1ccc(-c2cc(-c3ccc(-n4c5ccccc5c5ccccc54)cc3-n3c4ccccc4c4ccccc43)nc(-c3ccccc3)n2)cc1 ; c1ccc(-n2c3ccccc3c3cc(-c4ccc5c(c4)c4ccccc4n5-c4ccccc4)ccc32)cc1]

The hole injection layer is located between the anode and the hole transmission layer. The hole injection layer may be a single compound material or a combination of multiple compounds. For example, the hole injection layer may use one or more compounds of above HT-1 to HT-34, or one or more compounds of HI1 to HI3 below; it may also use one or more compounds of HT-1 to HT-34 that are doped with one or more of the following compounds of HI1 to HI3. The thickness of the hole injection layer is generally in a range of 5-30 nm, the thickness of the hole transmission layer is generally in a range of 5-50 nm, and the thickness of the electron blocking layer is generally in a range of 3-100 nm.

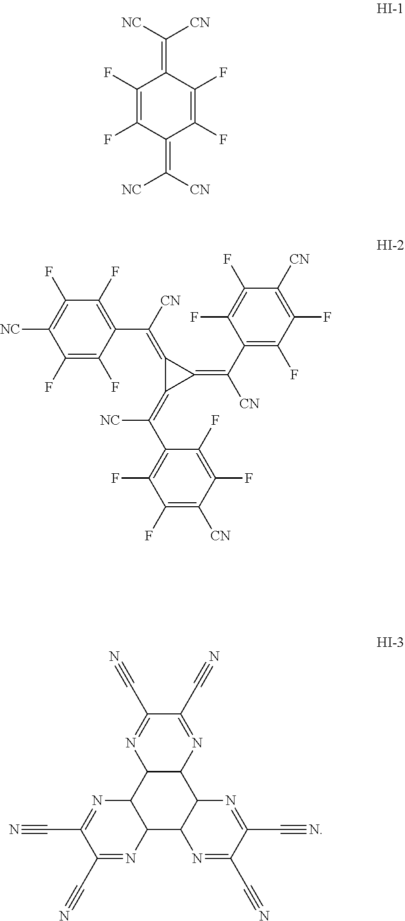 [SMILES: N#CC(C#N)=c1c(F)c(F)c(=C(C#N)C#N)c(F)c1F ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC1=NC2C3N=C(C#N)C(C#N)=NC3C3N=C(C#N)C(C#N)=NC3C2N=C1C#N]

The materials for the electron transmission layer and hole blocking layer can be selected from, but not limited to, one or a combination of more of compounds represented by ET-1 to ET-58, PH-1 to PH-46, and PH-87 that are listed below. The thickness of the electron transmission layer is generally in a range of 3-60 nm, and the thickness of the hole blocking layer is generally in a range of 3-15 nm.

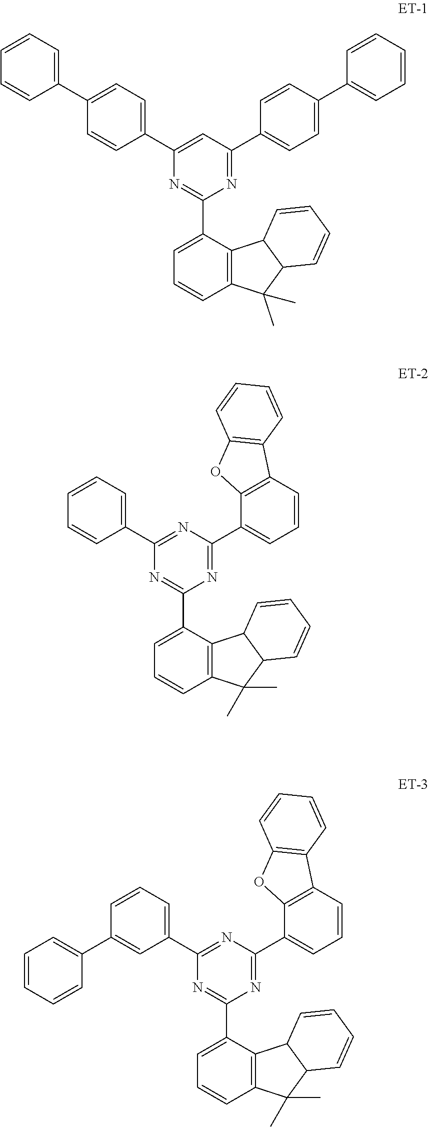 [SMILES: CC1(C)c2cccc(-c3nc(-c4ccc(-c5ccccc5)cc4)cc(-c4ccc(-c5ccccc5)cc4)n3)c2C2C=CC=CC21 ; CC1(C)c2cccc(-c3nc(-c4ccccc4)nc(-c4cccc5c4oc4ccccc45)n3)c2C2C=CC=CC21 ; CC1(C)c2cccc(-c3nc(-c4cccc(-c5ccccc5)c4)nc(-c4cccc5c4oc4ccccc45)n3)c2C2C=CC=CC21]

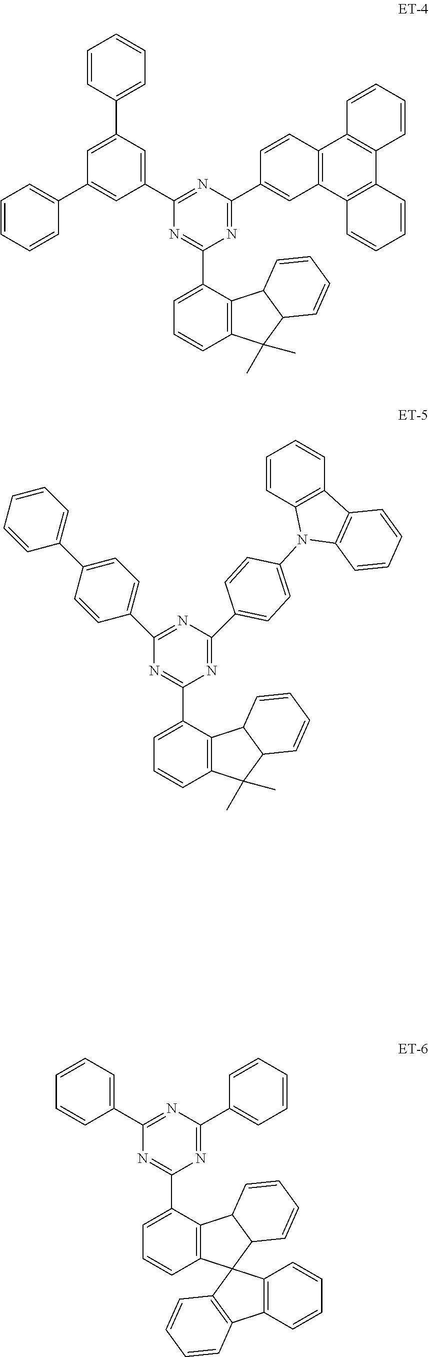 [SMILES: CC1(C)c2cccc(-c3nc(-c4cc(-c5ccccc5)cc(-c5ccccc5)c4)nc(-c4ccc5c6ccccc6c6ccccc6c5c4)n3)c2C2C=CC=CC21 ; CC1(C)c2cccc(-c3nc(-c4ccc(-c5ccccc5)cc4)nc(-c4ccc(-n5c6ccccc6c6ccccc65)cc4)n3)c2C2C=CC=CC21 ; C1=CC2c3c(-c4nc(-c5ccccc5)nc(-c5ccccc5)n4)cccc3C3(c4ccccc4-c4ccccc43)C2C=C1]

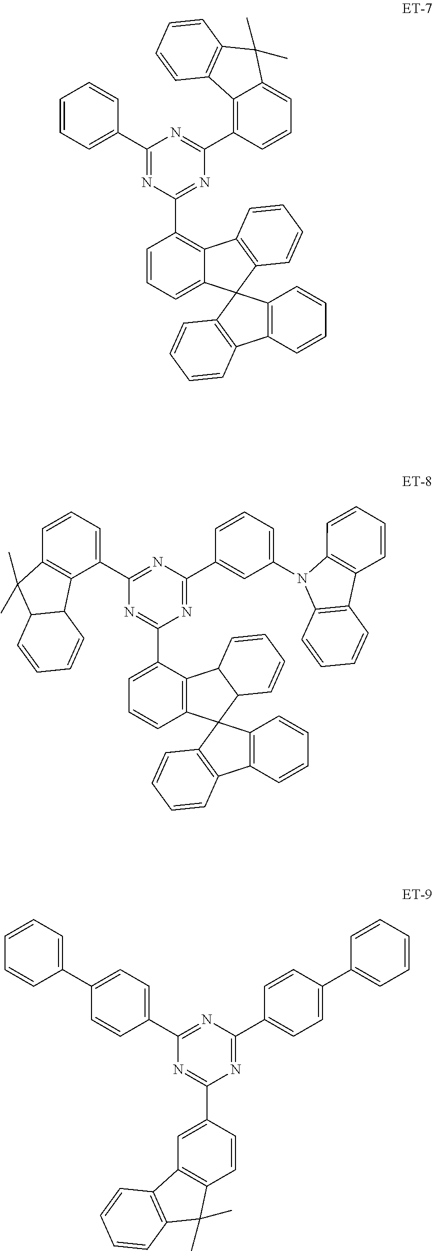 [SMILES: CC1(C)c2ccccc2-c2c(-c3nc(-c4ccccc4)nc(-c4cccc5c4-c4ccccc4C54c5ccccc5-c5ccccc54)n3)cccc21 ; CC1(C)c2cccc(-c3nc(-c4cccc(-n5c6ccccc6c6ccccc65)c4)nc(-c4cccc5c4C4C=CC=CC4C54c5ccccc5-c5ccccc54)n3)c2C2C=CC=CC21 ; CC1(C)c2ccccc2-c2cc(-c3nc(-c4ccc(-c5ccccc5)cc4)nc(-c4ccc(-c5ccccc5)cc4)n3)ccc21]

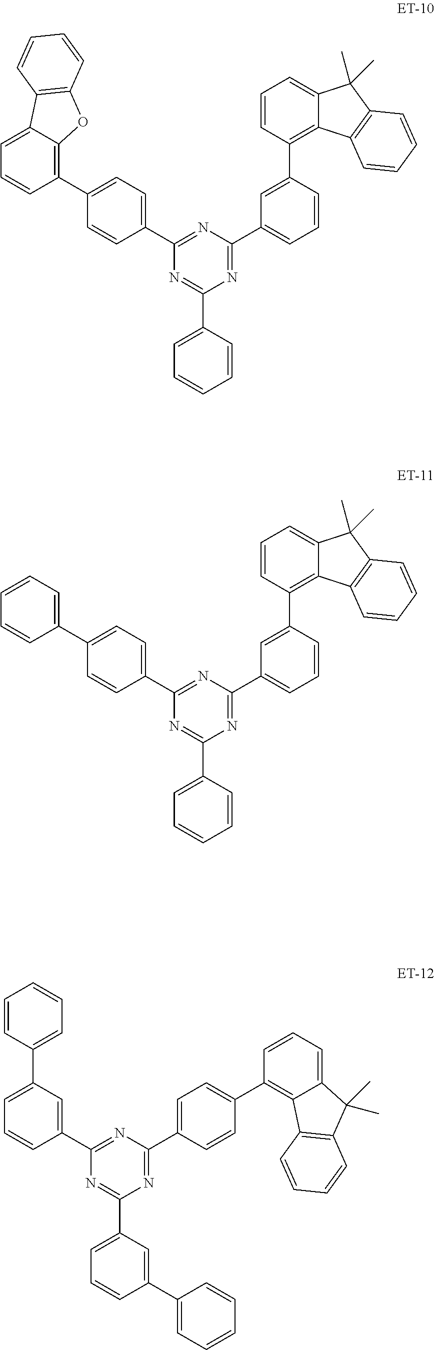 [SMILES: CC1(C)c2ccccc2-c2c(-c3cccc(-c4nc(-c5ccccc5)nc(-c5ccc(-c6cccc7c6oc6ccccc67)cc5)n4)c3)cccc21 ; CC1(C)c2ccccc2-c2c(-c3cccc(-c4nc(-c5ccccc5)nc(-c5ccc(-c6ccccc6)cc5)n4)c3)cccc21 ; CC1(C)c2ccccc2-c2c(-c3ccc(-c4nc(-c5cccc(-c6ccccc6)c5)nc(-c5cccc(-c6ccccc6)c5)n4)cc3)cccc21]

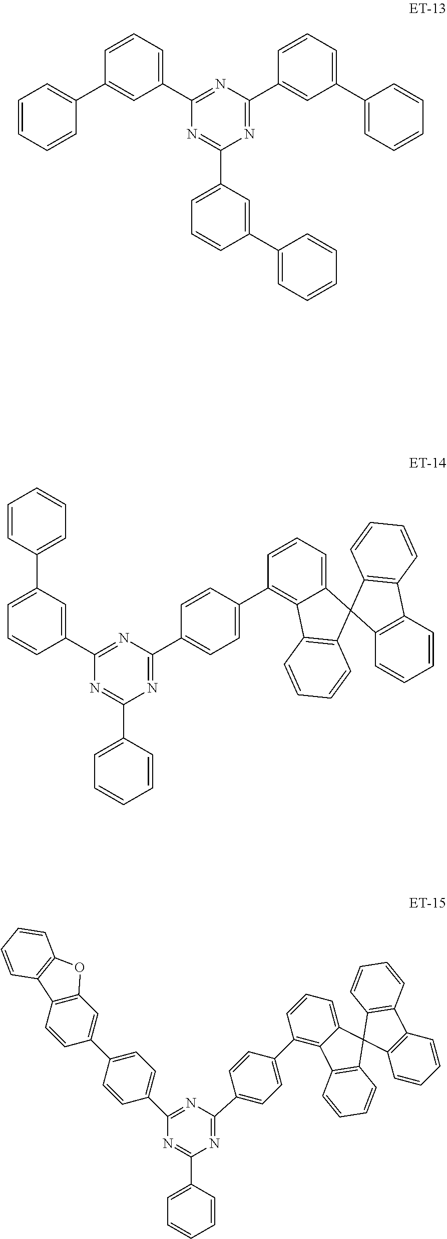 [SMILES: c1ccc(-c2cccc(-c3nc(-c4cccc(-c5ccccc5)c4)nc(-c4cccc(-c5ccccc5)c4)n3)c2)cc1 ; c1ccc(-c2cccc(-c3nc(-c4ccccc4)nc(-c4ccc(-c5cccc6c5-c5ccccc5C65c6ccccc6-c6ccccc65)cc4)n3)c2)cc1 ; c1ccc(-c2nc(-c3ccc(-c4ccc5c(c4)oc4ccccc45)cc3)nc(-c3ccc(-c4cccc5c4-c4ccccc4C54c5ccccc5-c5ccccc54)cc3)n2)cc1]

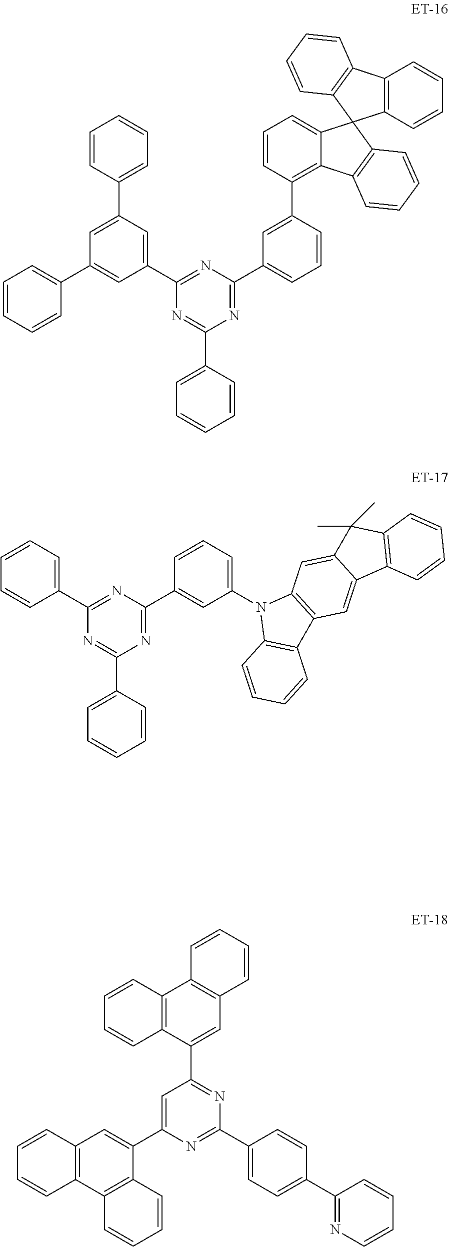 [SMILES: c1ccc(-c2cc(-c3ccccc3)cc(-c3nc(-c4ccccc4)nc(-c4cccc(-c5cccc6c5-c5ccccc5C65c6ccccc6-c6ccccc65)c4)n3)c2)cc1 ; CC1(C)c2ccccc2-c2cc3c4ccccc4n(-c4cccc(-c5nc(-c6ccccc6)nc(-c6ccccc6)n5)c4)c3cc21 ; c1ccc(-c2ccc(-c3nc(-c4cc5ccccc5c5ccccc45)cc(-c4cc5ccccc5c5ccccc45)n3)cc2)nc1]

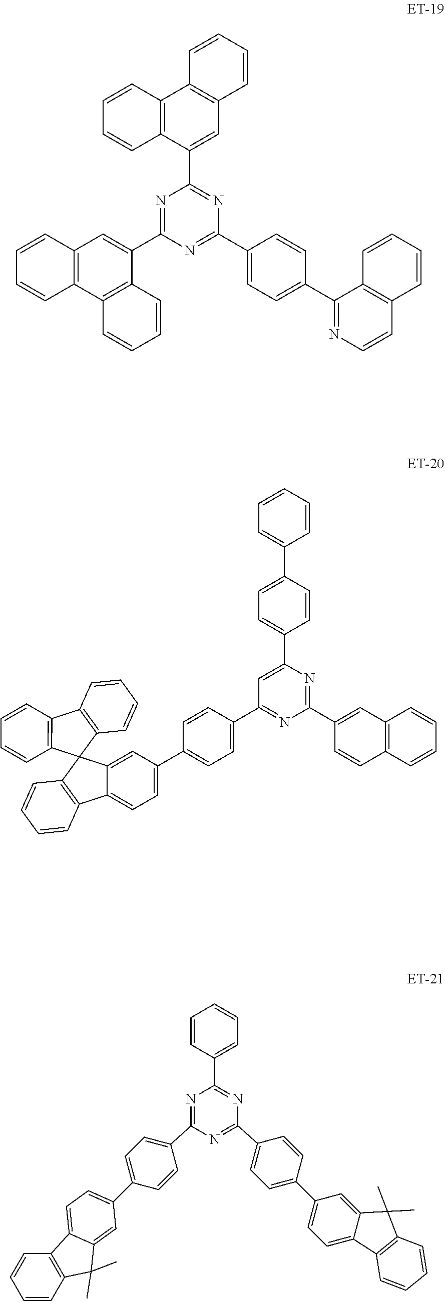 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc(-c2ccc(-c3cc(-c4ccc(-c5ccc6c(c5)C5(c7ccccc7-c7ccccc75)c5ccccc5-6)cc4)nc(-c4ccc5ccccc5c4)n3)cc2)cc1 ; CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21]

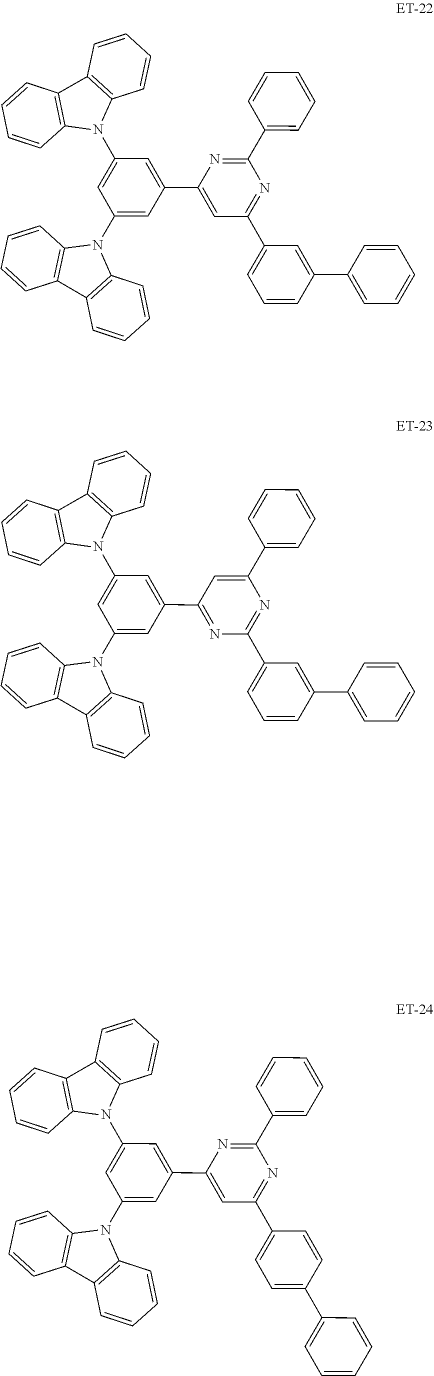 [SMILES: c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cccc(-c3nc(-c4ccccc4)cc(-c4cc(-n5c6ccccc6c6ccccc65)cc(-n5c6ccccc6c6ccccc65)c4)n3)c2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

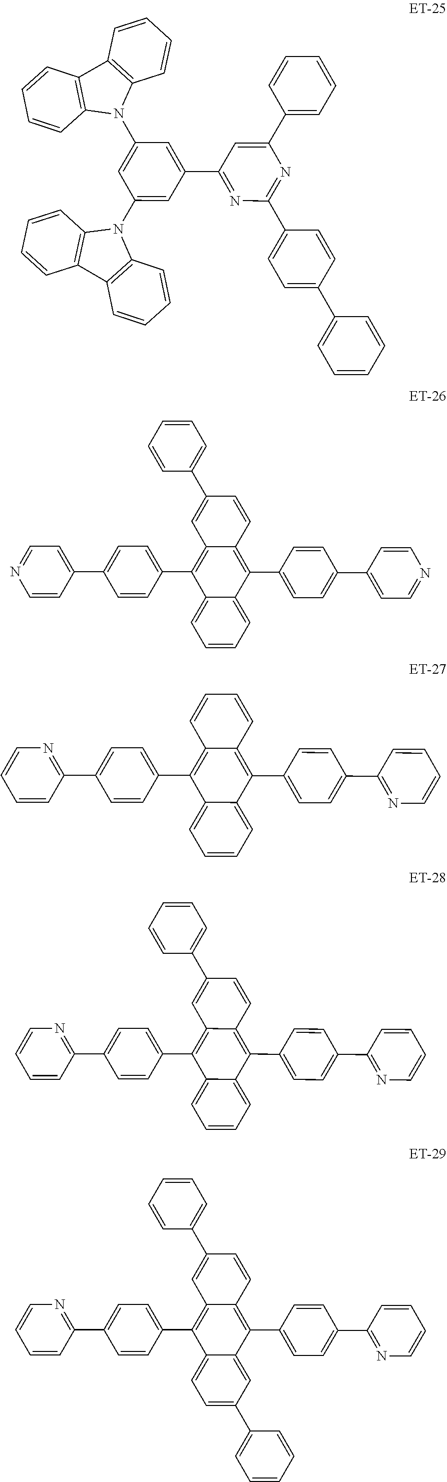 [SMILES: c1ccc(-c2ccc(-c3nc(-c4ccccc4)cc(-c4cc(-n5c6ccccc6c6ccccc65)cc(-n5c6ccccc6c6ccccc65)c4)n3)cc2)cc1 ; c1ccc(-c2ccc3c(-c4ccc(-c5ccncc5)cc4)c4ccccc4c(-c4ccc(-c5ccncc5)cc4)c3c2)cc1 ; c1ccc(-c2ccc(-c3c4ccccc4c(-c4ccc(-c5ccccn5)cc4)c4ccccc34)cc2)nc1 ; c1ccc(-c2ccc3c(-c4ccc(-c5ccccn5)cc4)c4ccccc4c(-c4ccc(-c5ccccn5)cc4)c3c2)cc1 ; c1ccc(-c2ccc3c(-c4ccc(-c5ccccn5)cc4)c4cc(-c5ccccc5)ccc4c(-c4ccc(-c5ccccn5)cc4)c3c2)cc1]

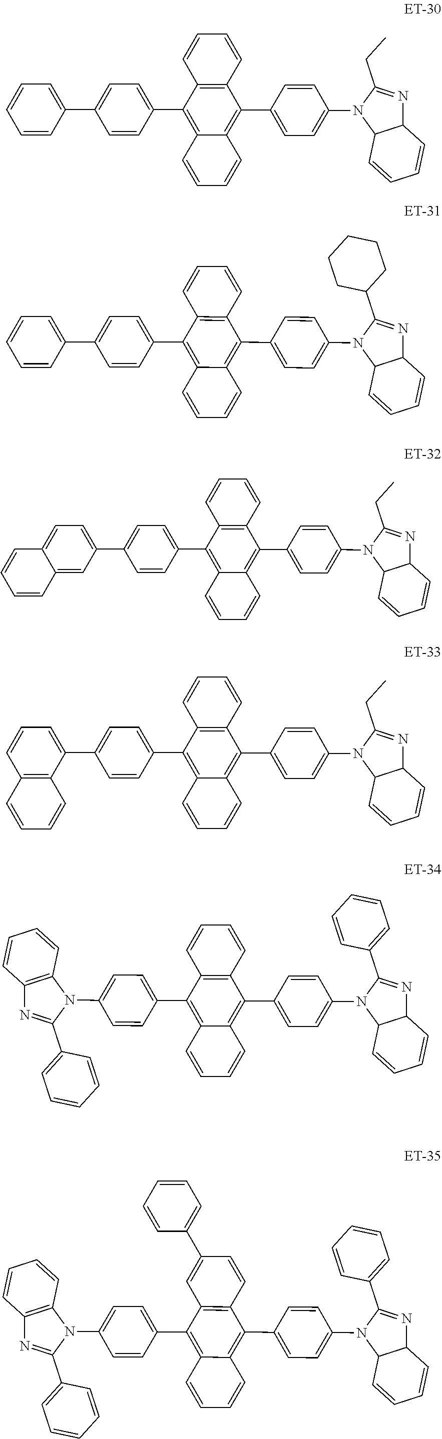

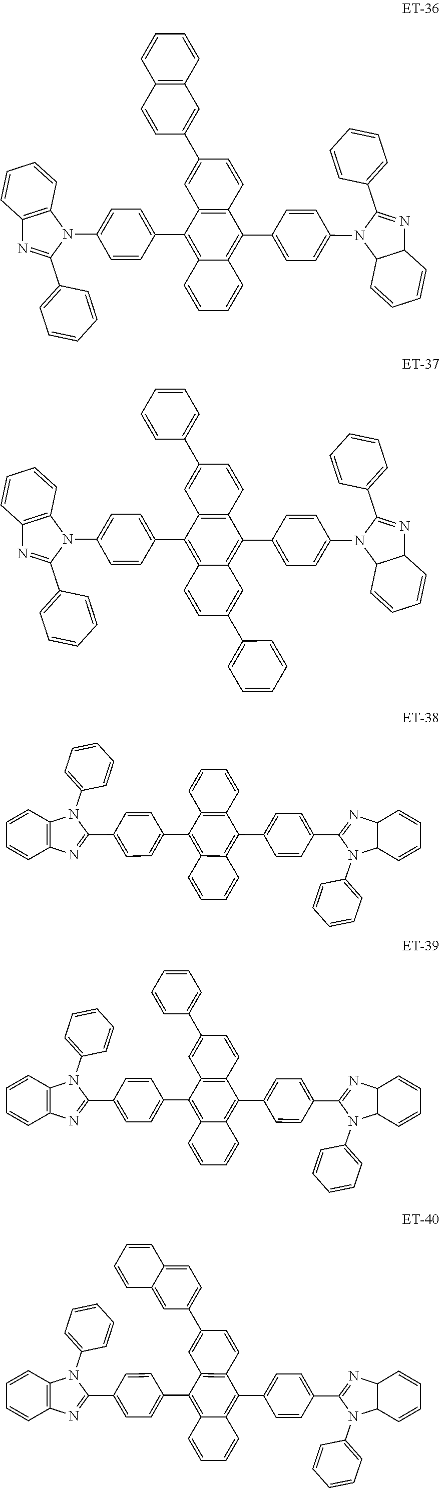

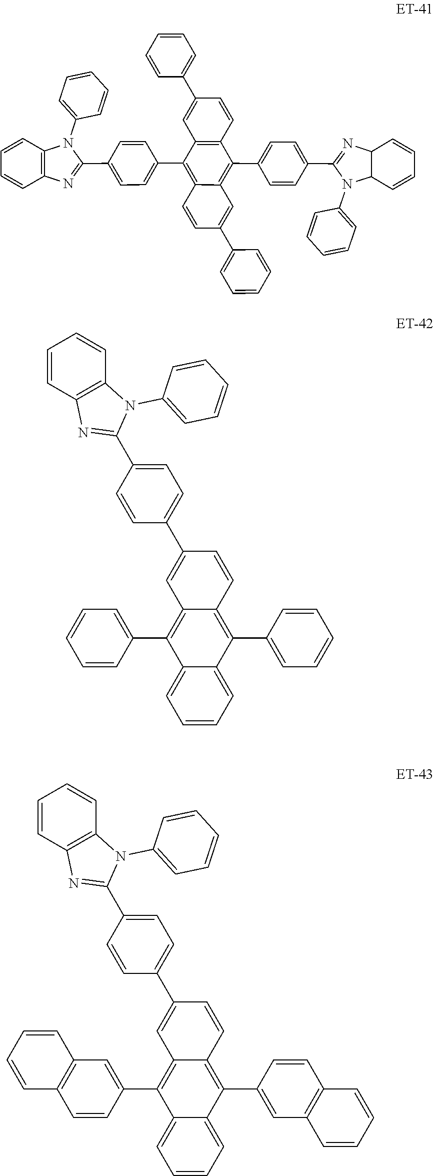 [SMILES: C1=CC2N=C(c3ccc(-c4c5ccc(-c6ccccc6)cc5c(-c5ccc(-c6nc7ccccc7n6-c6ccccc6)cc5)c5ccc(-c6ccccc6)cc45)cc3)N(c3ccccc3)C2C=C1 ; c1ccc(-c2c3ccccc3c(-c3ccccc3)c3cc(-c4ccc(-c5nc6ccccc6n5-c5ccccc5)cc4)ccc23)cc1 ; c1ccc(-n2c(-c3ccc(-c4ccc5c(-c6ccc7ccccc7c6)c6ccccc6c(-c6ccc7ccccc7c6)c5c4)cc3)nc3ccccc32)cc1]

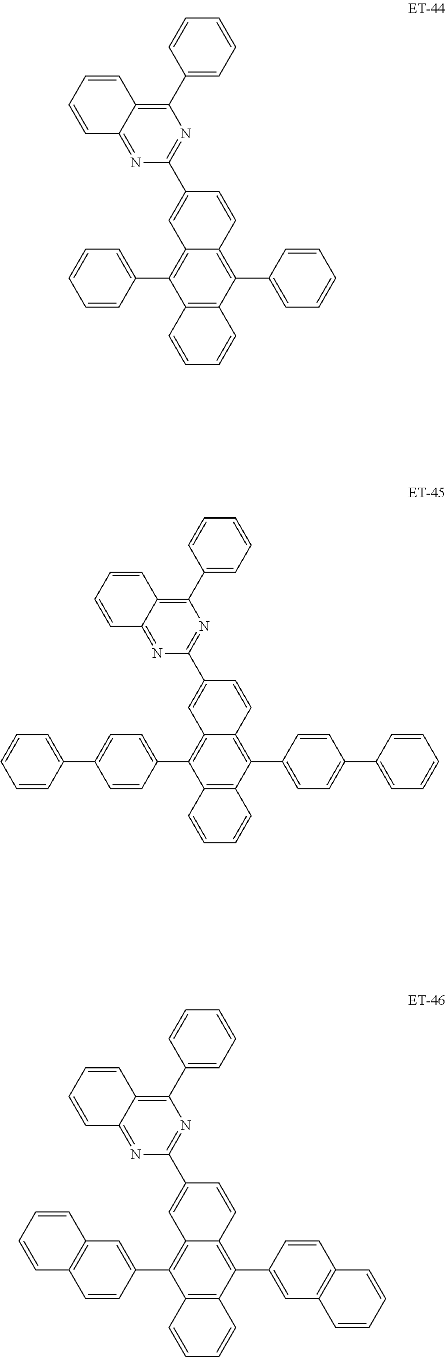 [SMILES: c1ccc(-c2nc(-c3ccc4c(-c5ccccc5)c5ccccc5c(-c5ccccc5)c4c3)nc3ccccc23)cc1 ; c1ccc(-c2ccc(-c3c4ccccc4c(-c4ccc(-c5ccccc5)cc4)c4cc(-c5nc(-c6ccccc6)c6ccccc6n5)ccc34)cc2)cc1 ; c1ccc(-c2nc(-c3ccc4c(-c5ccc6ccccc6c5)c5ccccc5c(-c5ccc6ccccc6c5)c4c3)nc3ccccc23)cc1]

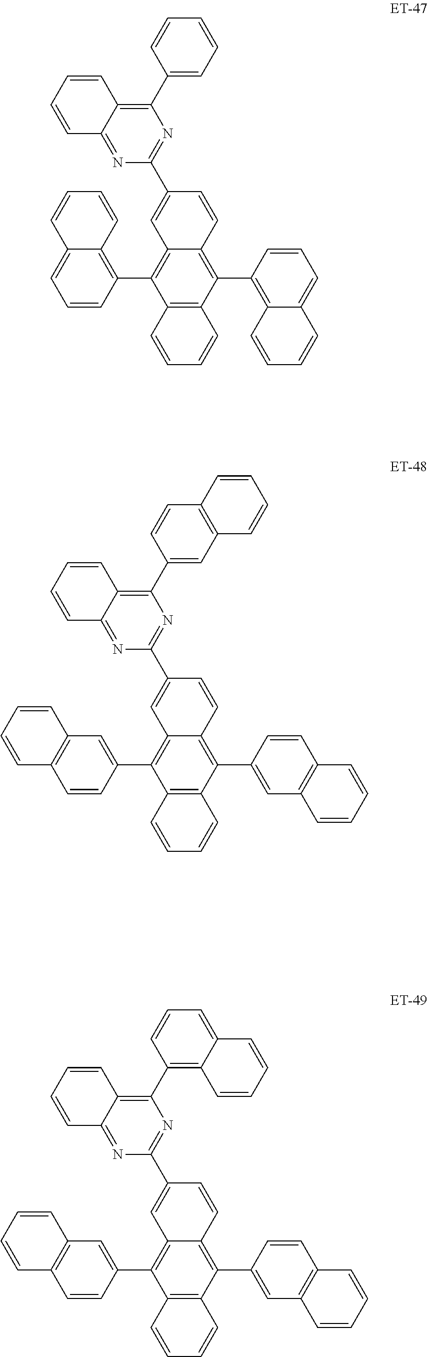 [SMILES: c1ccc(-c2nc(-c3ccc4c(-c5cccc6ccccc56)c5ccccc5c(-c5cccc6ccccc56)c4c3)nc3ccccc23)cc1 ; c1ccc2cc(-c3nc(-c4ccc5c(-c6ccc7ccccc7c6)c6ccccc6c(-c6ccc7ccccc7c6)c5c4)nc4ccccc34)ccc2c1 ; c1ccc2cc(-c3c4ccccc4c(-c4ccc5ccccc5c4)c4cc(-c5nc(-c6cccc7ccccc67)c6ccccc6n5)ccc34)ccc2c1]

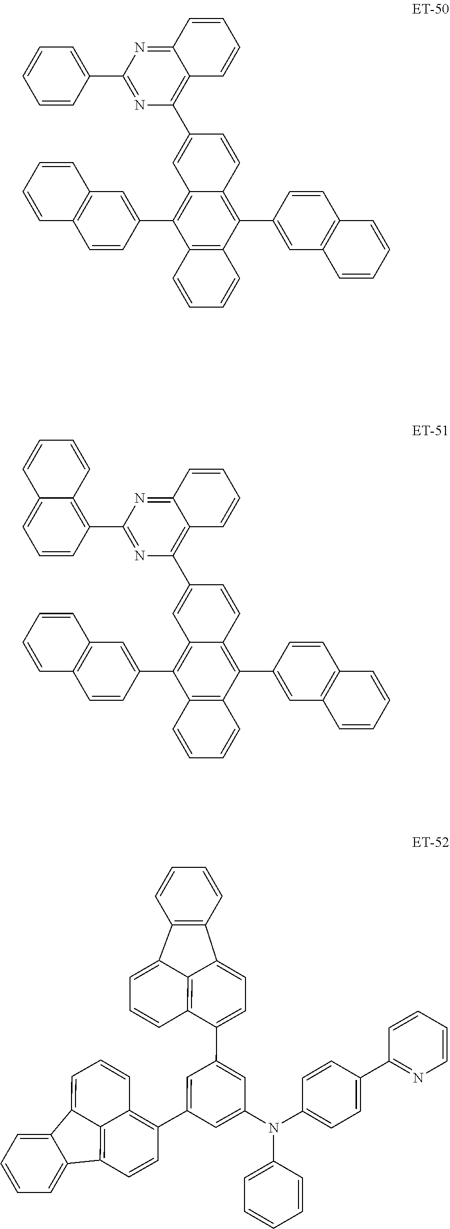 [SMILES: c1ccc(-c2nc(-c3ccc4c(-c5ccc6ccccc6c5)c5ccccc5c(-c5ccc6ccccc6c5)c4c3)c3ccccc3n2)cc1 ; c1ccc2cc(-c3c4ccccc4c(-c4ccc5ccccc5c4)c4cc(-c5nc(-c6cccc7ccccc67)nc6ccccc56)ccc34)ccc2c1 ; c1ccc(N(c2ccc(-c3ccccn3)cc2)c2cc(-c3ccc4c5c(cccc35)-c3ccccc3-4)cc(-c3ccc4c5c(cccc35)-c3ccccc3-4)c2)cc1]

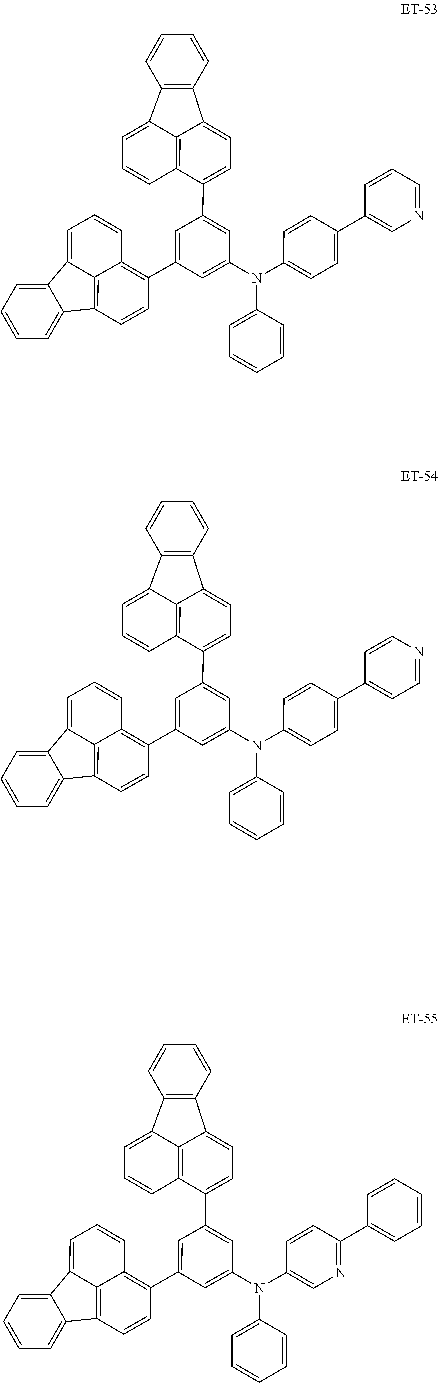 [SMILES: c1ccc(N(c2ccc(-c3cccnc3)cc2)c2cc(-c3ccc4c5c(cccc35)-c3ccccc3-4)cc(-c3ccc4c5c(cccc35)-c3ccccc3-4)c2)cc1 ; c1ccc(N(c2ccc(-c3ccncc3)cc2)c2cc(-c3ccc4c5c(cccc35)-c3ccccc3-4)cc(-c3ccc4c5c(cccc35)-c3ccccc3-4)c2)cc1 ; c1ccc(-c2ccc(N(c3ccccc3)c3cc(-c4ccc5c6c(cccc46)-c4ccccc4-5)cc(-c4ccc5c6c(cccc46)-c4ccccc4-5)c3)cn2)cc1]

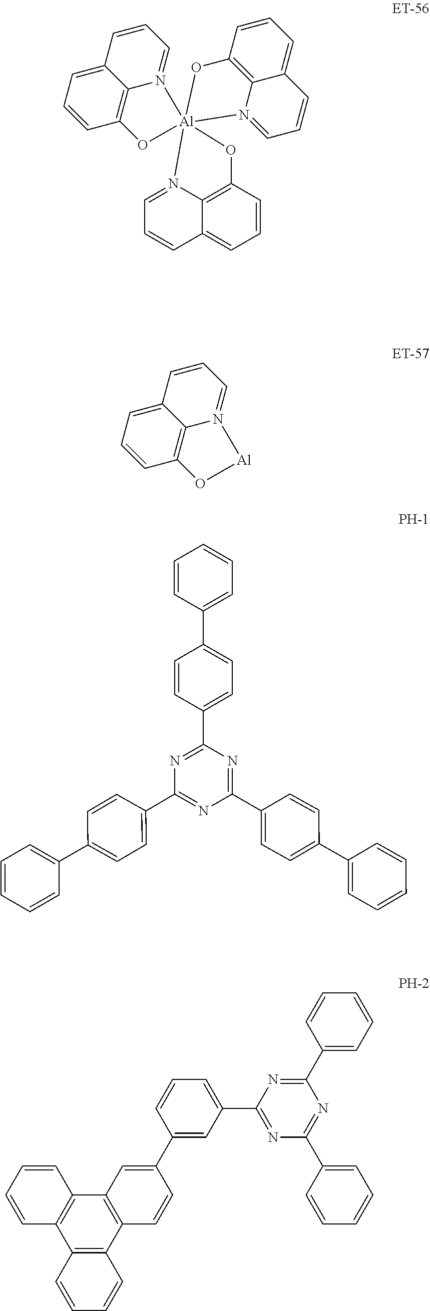

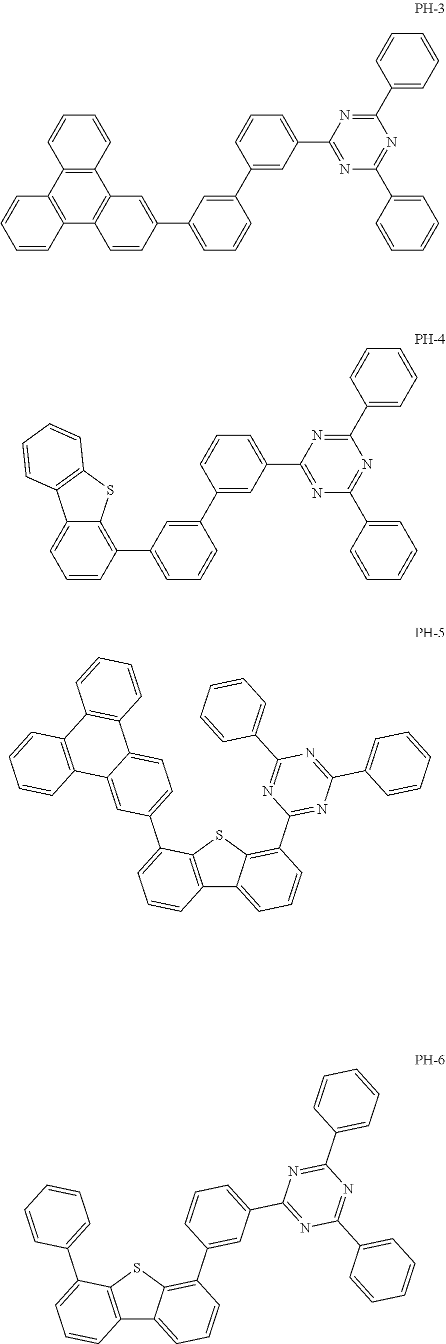 [SMILES: c1ccc(-c2nc(-c3ccccc3)nc(-c3cccc(-c4cccc(-c5ccc6c7ccccc7c7ccccc7c6c5)c4)c3)n2)cc1 ; c1ccc(-c2nc(-c3ccccc3)nc(-c3cccc(-c4cccc(-c5cccc6c5sc5ccccc56)c4)c3)n2)cc1 ; c1ccc(-c2nc(-c3ccccc3)nc(-c3cccc4c3sc3c(-c5ccc6c7ccccc7c7ccccc7c6c5)cccc34)n2)cc1 ; c1ccc(-c2nc(-c3ccccc3)nc(-c3cccc(-c4cccc5c4sc4c(-c6ccccc6)cccc45)c3)n2)cc1]

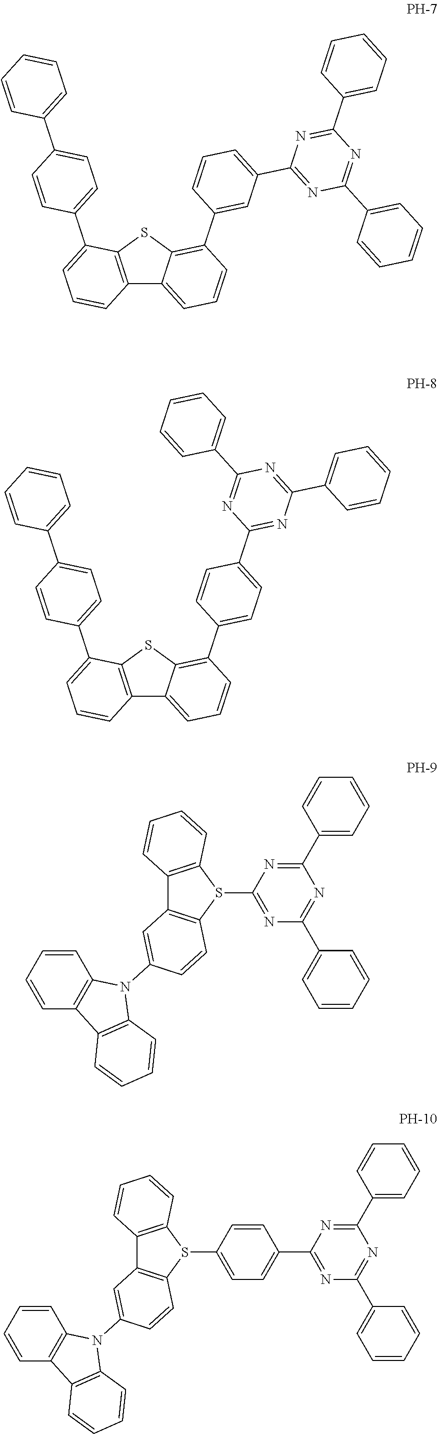

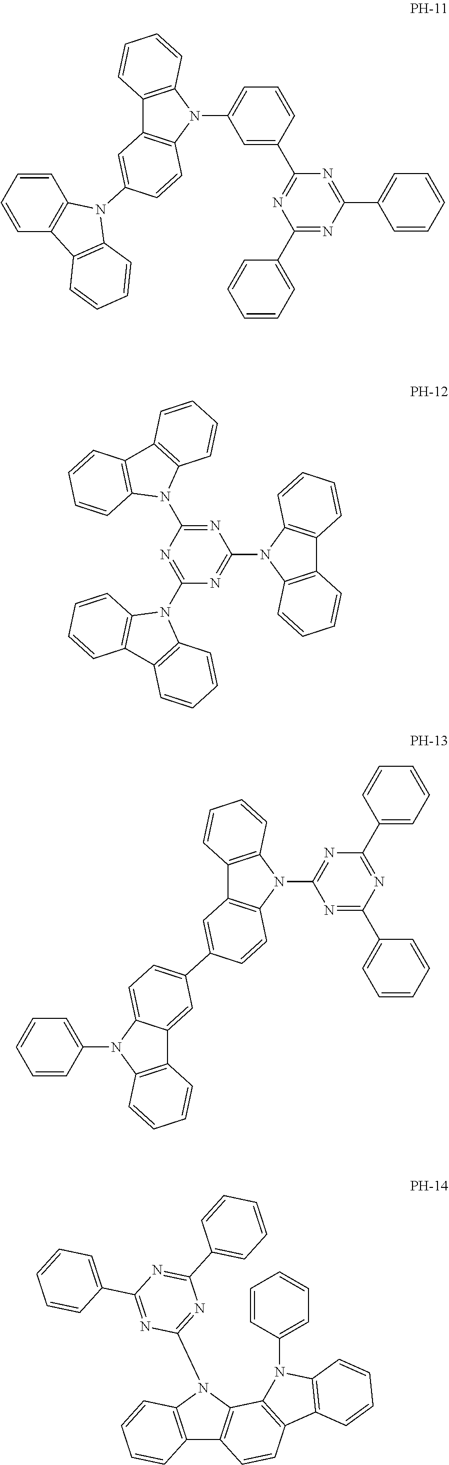 [SMILES: c1ccc(-c2nc(-c3ccccc3)nc(-c3cccc(-n4c5ccccc5c5cc(-n6c7ccccc7c7ccccc76)ccc54)c3)n2)cc1 ; c1ccc2c(c1)c1ccccc1n2-c1nc(-n2c3ccccc3c3ccccc32)nc(-n2c3ccccc3c3ccccc32)n1 ; c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-n3c4ccccc4c4ccc5c6ccccc6n(-c6ccccc6)c5c43)n2)cc1]

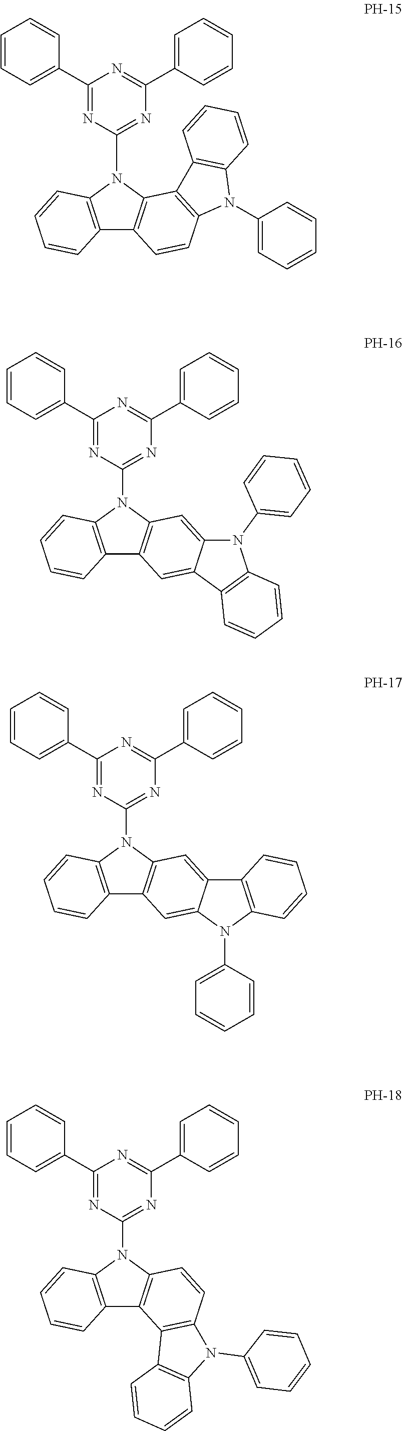 [SMILES: c1ccc(-c2nc(-c3ccccc3)nc(-n3c4ccccc4c4ccc5c(c6ccccc6n5-c5ccccc5)c43)n2)cc1 ; c1ccc(-c2nc(-c3ccccc3)nc(-n3c4ccccc4c4cc5c6ccccc6n(-c6ccccc6)c5cc43)n2)cc1 ; c1ccc(-c2nc(-c3ccccc3)nc(-n3c4ccccc4c4cc5c(cc43)c3ccccc3n5-c3ccccc3)n2)cc1 ; c1ccc(-c2nc(-c3ccccc3)nc(-n3c4ccccc4c4c5c6ccccc6n(-c6ccccc6)c5ccc43)n2)cc1]

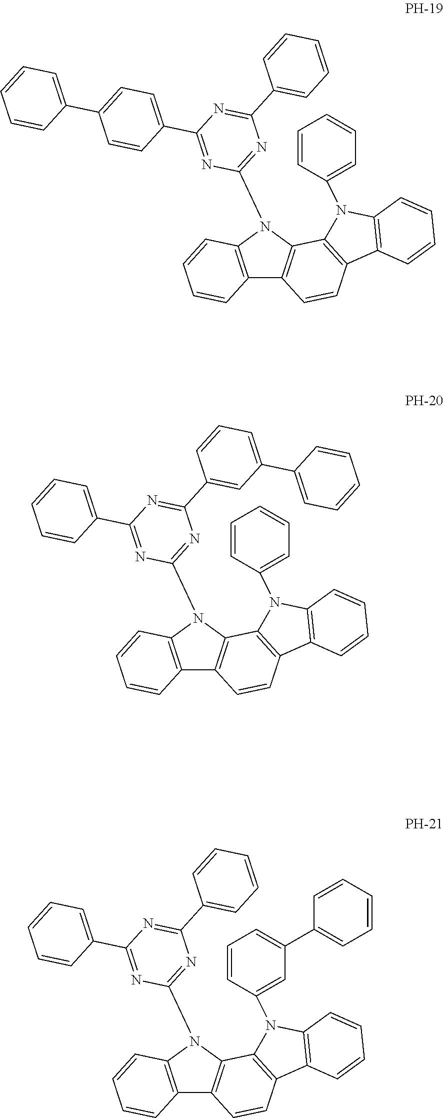 [SMILES: c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-c2cccc(-c3nc(-c4ccccc4)nc(-n4c5ccccc5c5ccc6c7ccccc7n(-c7ccccc7)c6c54)n3)c2)cc1 ; c1ccc(-c2cccc(-n3c4ccccc4c4ccc5c6ccccc6n(-c6nc(-c7ccccc7)nc(-c7ccccc7)n6)c5c43)c2)cc1]

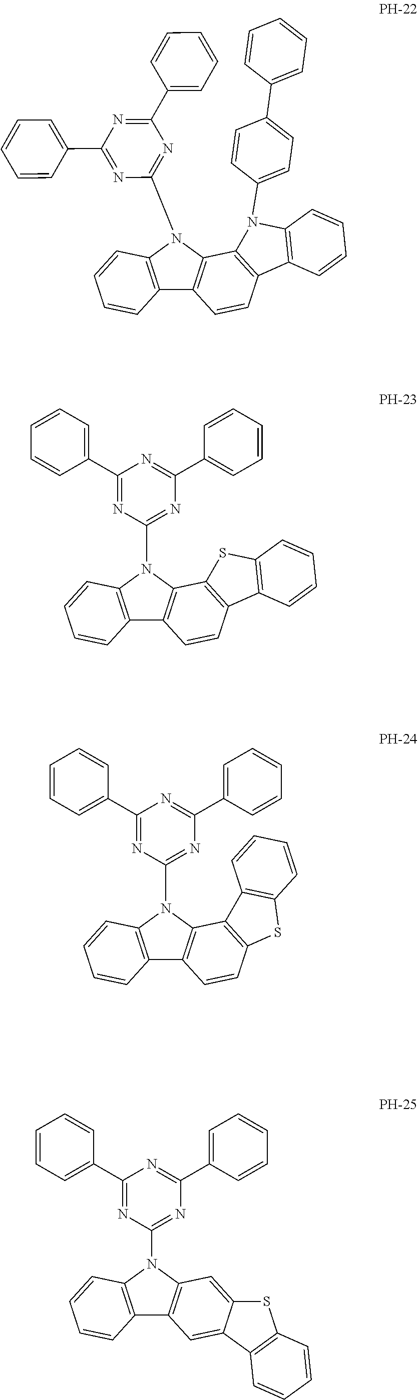 [SMILES: c1ccc(-c2ccc(-n3c4ccccc4c4ccc5c6ccccc6n(-c6nc(-c7ccccc7)nc(-c7ccccc7)n6)c5c43)cc2)cc1 ; c1ccc(-c2nc(-c3ccccc3)nc(-n3c4ccccc4c4ccc5c6ccccc6sc5c43)n2)cc1 ; c1ccc(-c2nc(-c3ccccc3)nc(-n3c4ccccc4c4ccc5sc6ccccc6c5c43)n2)cc1 ; c1ccc(-c2nc(-c3ccccc3)nc(-n3c4ccccc4c4cc5c(cc43)sc3ccccc35)n2)cc1]

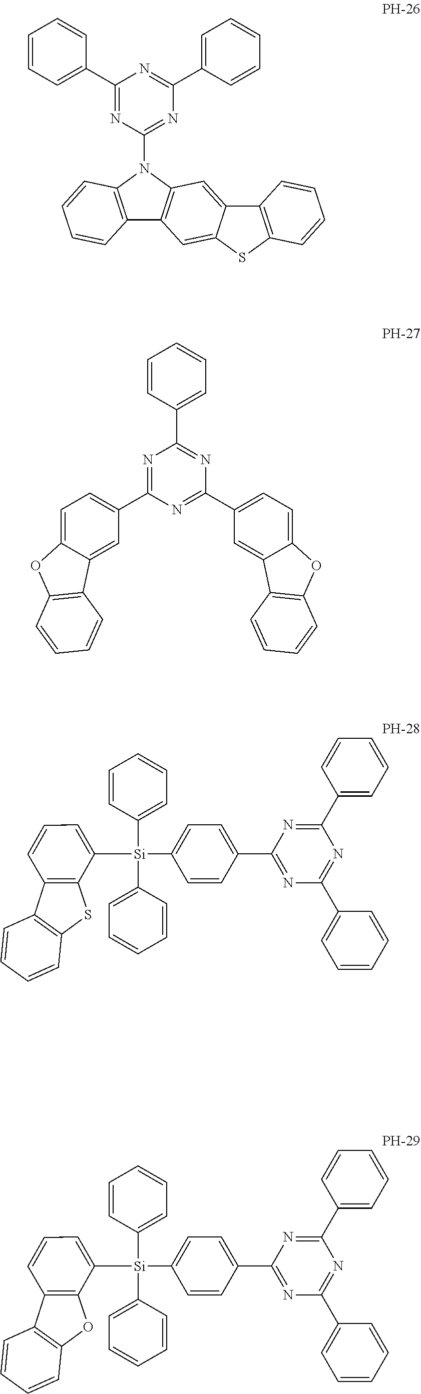 [SMILES: c1ccc(-c2nc(-c3ccccc3)nc(-n3c4ccccc4c4cc5sc6ccccc6c5cc43)n2)cc1 ; c1ccc(-c2nc(-c3ccc4oc5ccccc5c4c3)nc(-c3ccc4oc5ccccc5c4c3)n2)cc1 ; c1ccc(-c2nc(-c3ccccc3)nc(-c3ccc([Si](c4ccccc4)(c4ccccc4)c4cccc5c4sc4ccccc45)cc3)n2)cc1 ; c1ccc(-c2nc(-c3ccccc3)nc(-c3ccc([Si](c4ccccc4)(c4ccccc4)c4cccc5c4oc4ccccc45)cc3)n2)cc1]

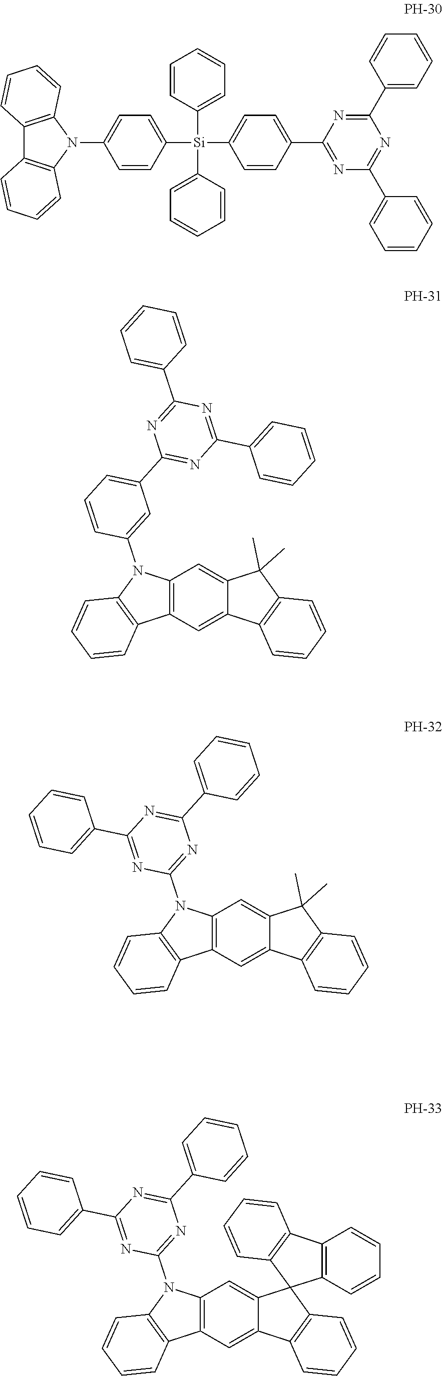 [SMILES: c1ccc(-c2nc(-c3ccccc3)nc(-c3ccc([Si](c4ccccc4)(c4ccccc4)c4ccc(-n5c6ccccc6c6ccccc65)cc4)cc3)n2)cc1 ; CC1(C)c2ccccc2-c2cc3c4ccccc4n(-c4cccc(-c5nc(-c6ccccc6)nc(-c6ccccc6)n5)c4)c3cc21 ; CC1(C)c2ccccc2-c2cc3c4ccccc4n(-c4nc(-c5ccccc5)nc(-c5ccccc5)n4)c3cc21 ; c1ccc(-c2nc(-c3ccccc3)nc(-n3c4ccccc4c4cc5c(cc43)C3(c4ccccc4-c4ccccc43)c3ccccc3-5)n2)cc1]

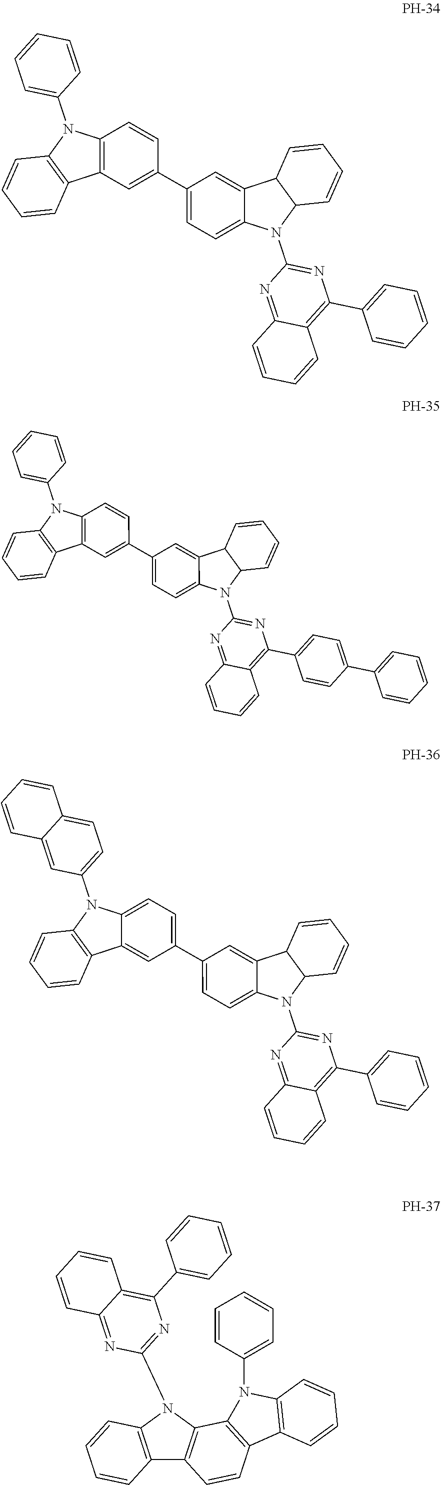 [SMILES: C1=CC2c3cc(-c4ccc5c(c4)c4ccccc4n5-c4ccccc4)ccc3N(c3nc(-c4ccccc4)c4ccccc4n3)C2C=C1 ; C1=CC2c3cc(-c4ccc5c(c4)c4ccccc4n5-c4ccccc4)ccc3N(c3nc(-c4ccc(-c5ccccc5)cc4)c4ccccc4n3)C2C=C1 ; C1=CC2c3cc(-c4ccc5c(c4)c4ccccc4n5-c4ccc5ccccc5c4)ccc3N(c3nc(-c4ccccc4)c4ccccc4n3)C2C=C1 ; c1ccc(-c2nc(-n3c4ccccc4c4ccc5c6ccccc6n(-c6ccccc6)c5c43)nc3ccccc23)cc1]

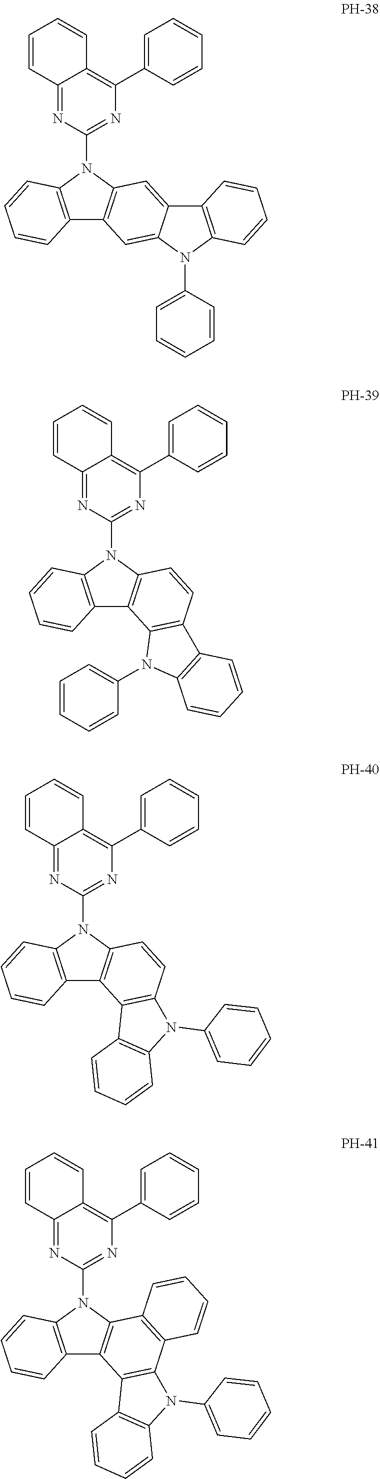 [SMILES: c1ccc(-c2nc(-n3c4ccccc4c4cc5c(cc43)c3ccccc3n5-c3ccccc3)nc3ccccc23)cc1 ; c1ccc(-c2nc(-n3c4ccccc4c4c3ccc3c5ccccc5n(-c5ccccc5)c34)nc3ccccc23)cc1 ; c1ccc(-c2nc(-n3c4ccccc4c4c5c6ccccc6n(-c6ccccc6)c5ccc43)nc3ccccc23)cc1 ; c1ccc(-c2nc(-n3c4ccccc4c4c5c6ccccc6n(-c6ccccc6)c5c5ccccc5c43)nc3ccccc23)cc1]

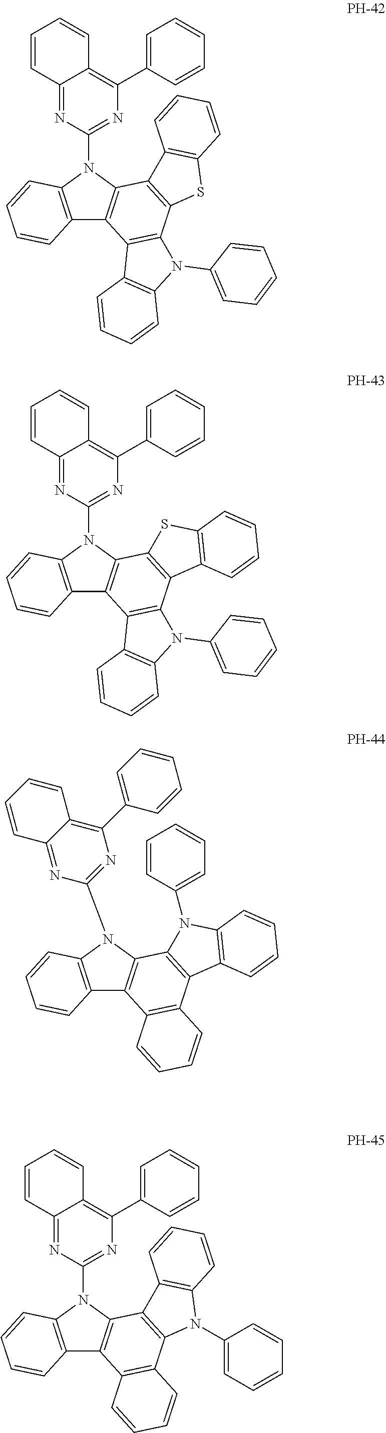

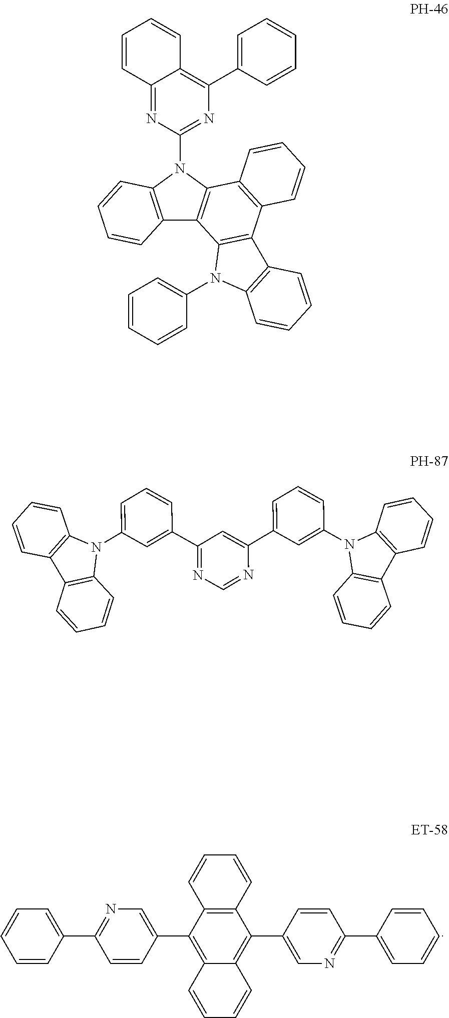 [SMILES: c1ccc(-c2nc(-n3c4ccccc4c4c3c3ccccc3c3c5ccccc5n(-c5ccccc5)c34)nc3ccccc23)cc1 ; c1cc(-c2cc(-c3cccc(-n4c5ccccc5c5ccccc54)c3)ncn2)cc(-n2c3ccccc3c3ccccc32)c1 ; c1ccc(-c2ccc(-c3c4ccccc4c(-c4ccc(-c5ccccc5)nc4)c4ccccc34)cn2)cc1]

The structure of the electroluminescent device may further include an electron injection layer located between the electron transmission layer and the cathode, and the electron injection layer material includes, but is not limited to, one or a combination of more of the below: LiQ, LiF, NaCl, CsF, Li₂O, Cs₂CO₃, BaO, Na, Li, Ca. The thickness of the electron injection layer is generally in a range of 0.5-5 nm.

The thickness of the above respective layers can be the conventional thickness of these layers in the art.

The present application does not limit the preparation method of the organic electroluminescent device, including sequentially depositing an anode, a first functional layer, an light-emitting layer, a second functional layer, and a cathode on a substrate, and then sealing. Where, when preparing the light-emitting layer, the distribution of dye can be orderly regulated by adjusting the arrangement order of the host material source, sensitizer source and dye source, the distance between respective sources, the discharge ranges of respective sources, etc.

The embodiment of the present application further provides a display device, including the organic electroluminescent device as provided above. Specifically, the display device can be an OLED display and other display parts, as well as any product or component with a display function such as televisions, digital cameras, mobile phones, tablets, etc. that includes the display device. The display device has the same advantages as the aforementioned organic electroluminescent device compared to existing technologies, which will not be further elaborated here.

Below, the organic electroluminescent device of the present application will be introduced in detail through specific embodiments.

### Example 1

Example 1 provides an organic electroluminescent device with the following structure: ITO/HI-3 (10 nm)/HT-2 (30 nm)/PH-86 (10 nm)/light-emitting layer/PH-87 (10 nm)/ET-58: Liq (30 nm)/LiF (0.5 nm)/Al (150 nm).

Its specific preparation method is as follows:
(1) A glass plate coated with ITO/Ag/ITO conductive layer was ultrasonically treated in a commercial cleaning agent, rinsed in deionized water, ultrasonically degreased in a mixed solvent of acetone and ethanol, baked in a clean environment until the water was completely removed, and cleaned with ultraviolet light and ozone, and the cleaned surface was bombarded with a low energy cation beam;
(2) The glass plate with anode was placed in a vacuum chamber and then vacuumed to less than 1×10⁻⁵ Pa, HI-3 was deposited by evaporation onto the anode layer film as a hole injection layer, with an evaporation rate of 0.1 nm/s and an evaporation film thickness of 10 nm;
(3) A hole transmission layer HT-2 was placed on the hole injection layer by vacuum evaporation, with an evaporation rate of 0.1 nm/s and a total evaporation film thickness of 30 nm;
(4) An electron blocking layer PH-86 was placed on the hole transmission layer by vacuum evaporation, with an evaporation rate of 0.1 nm/s and a total evaporation film thickness of 10 nm;
(5) An light-emitting layer was placed on the electron blocking layer by vacuum co-evaporation, where, the light-emitting layer included a host material (w-7), a sensitizer T-89 and a dye T17, and the dye is subjected to evaporation according to 3% doping ratio (mass ratio) using a multi-source co-evaporation method.

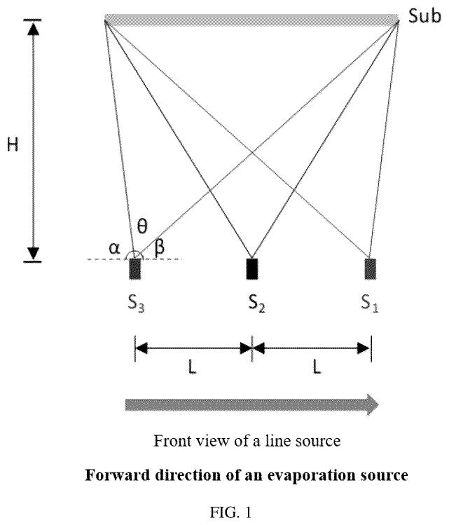

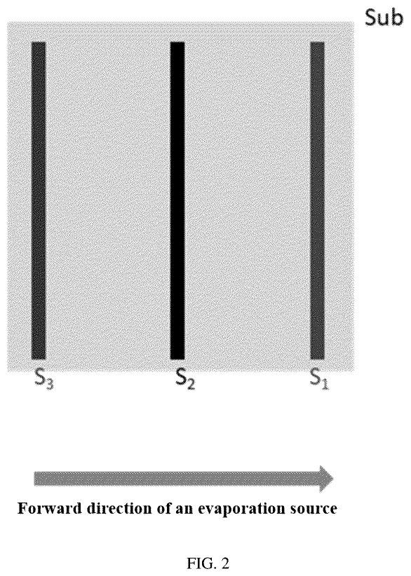

FIG. 1 is a front view of the multi-source co-evaporation of the light-emitting layer of the organic electroluminescent device in Example 1 of the present application. FIG. 2 is a top view of FIG. 1. Where, the three material line sources S1 (main source), S2 (dye source), and S3 (sensitizer source) are located below the evaporation carrier Sub, and the distance between any two of the three material line sources is L, and the vertical distance between the three material line sources and the evaporation carrier is H. During the evaporation process, the three material line sources move in a forward direction of the evaporation source, where the evaporation angle of the S3 material line source to the evaporation carrier is θ, which is achieved by controlling separately α and β. Specifically, α is an angle between one side of the evaporation angle θ and the arrangement direction of the three material line sources (an arrangement direction of S3 pointing towards S1 in FIG. 1), β is an angle between the other side of the evaporation angle θ and the arrangement direction of the three material line sources (an arrangement direction of S3 pointing towards S1 in FIG. 1). The specific evaporation parameters are shown in Table 1.
(6) A hole blocking layer of PH-87 is placed on the light-emitting layer by vacuum evaporation, with an evaporation rate of 0.1 nm/s and a total evaporation film thickness of 10 nm;
(7) ET-58: Liq (mass ratio of 1:1) was plated on hole blocking layer via vacuum evaporation to form an electron transmission layer, with an evaporation rate of 0.1 nm/s and a total evaporation film thickness of 30 nm;
(8) LiF was plated on the electron transmission layer via vacuum evaporation to form an electron injection layer, with a thickness of 0.5 nm;
(9) Al was plated on the electron injection layer via evaporation to form the cathode of the device, with a thickness of 150 nm.

### Examples 2-27

The specific composition of the light-emitting layer in Examples 2-27 is shown in Table 1, and the composition of other functional layers is the same as that of Example 1.

The schematic diagram of evaporation for Examples 2-27 is same as that of Example 1, and the specific evaporation parameters are shown in Table 1.

### Comparative Examples 1-2

The specific composition of the light-emitting layer in Comparative Examples 1-2 is shown in Table 1, and the composition of other functional layers is same as that of Example 1.

Where, the schematic diagram of evaporation for Comparative Example 2 is same as that of the Example 1, and the specific evaporation parameters are shown in Table 1.

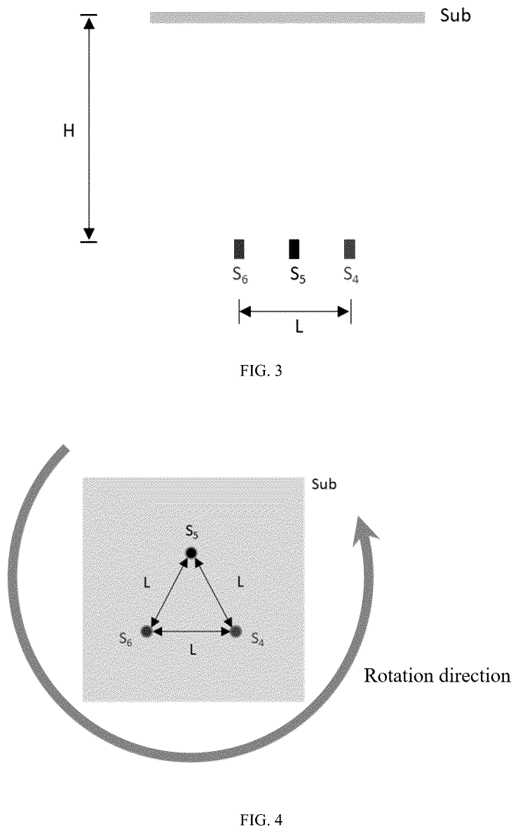

FIG. 3 is a front view of multi-source co-evaporation of a light-emitting layer of an organic electroluminescent device according to Comparative Example 1 of the present application. FIG. 4 is a top view of FIG. 3. Where, the three material point sources S4, S5 and S6 arranged in an equilateral triangle are located below the evaporation carrier Sub, and the distance between any two of the three material point sources is L, and the vertical distance between the three material point sources and the evaporation carrier is H; during the evaporation process, the evaporation carrier rotates counterclockwise. The specific evaporation parameters are shown in Table 1.

The electrical properties of the above device were tested using the Japanese Hamamatsu C9920-12 absolute electroluminescence quantum efficiency testing system equipped with Keithley 2400. The specific test results are shown in Table 1.

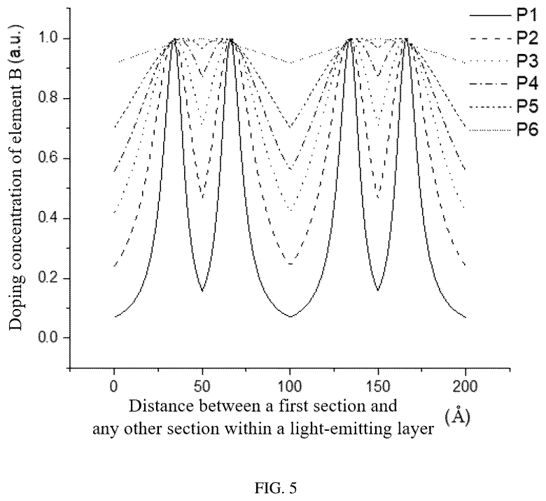

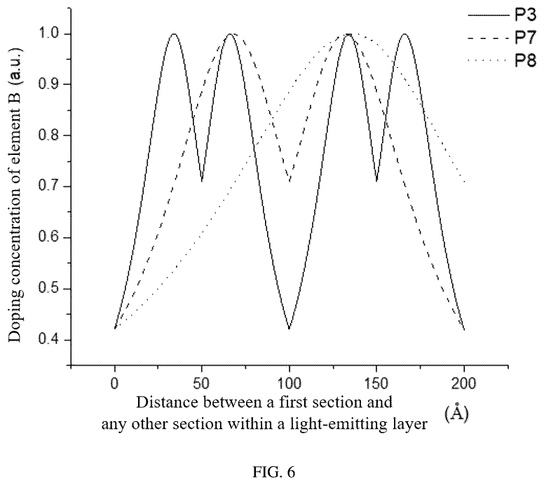

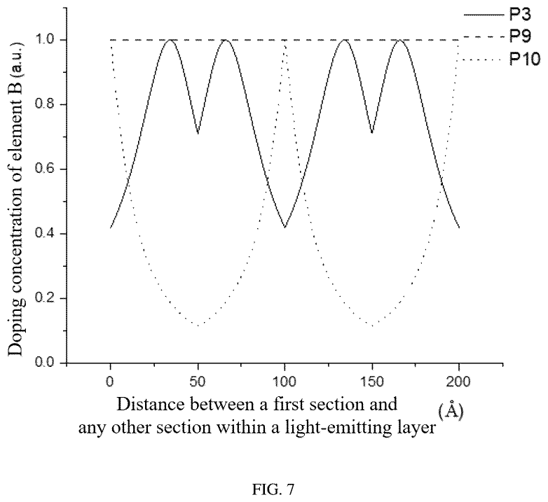

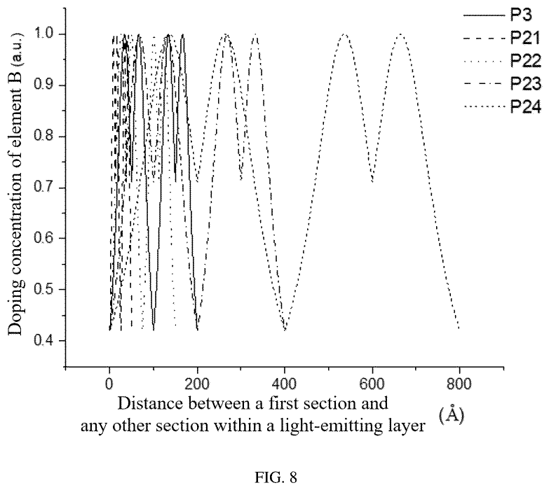

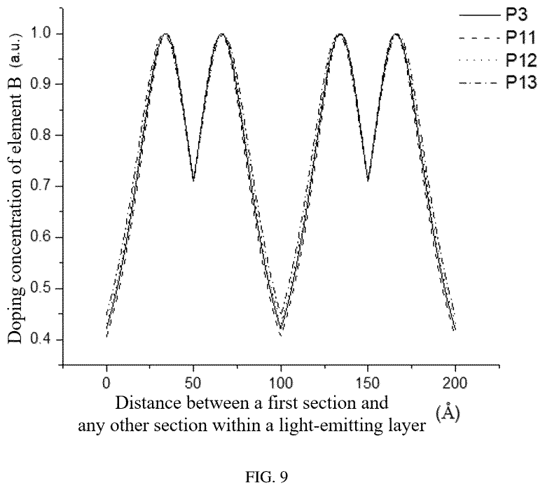

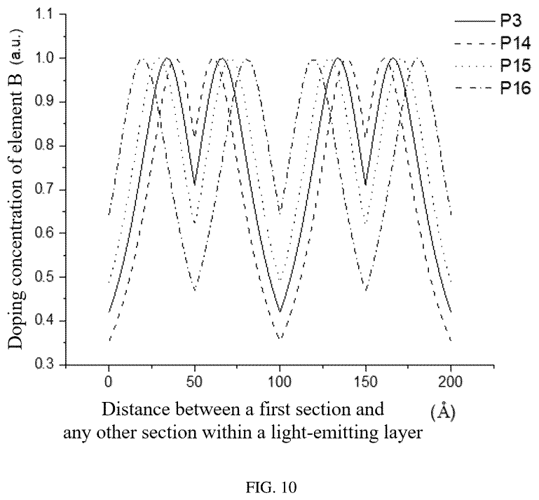

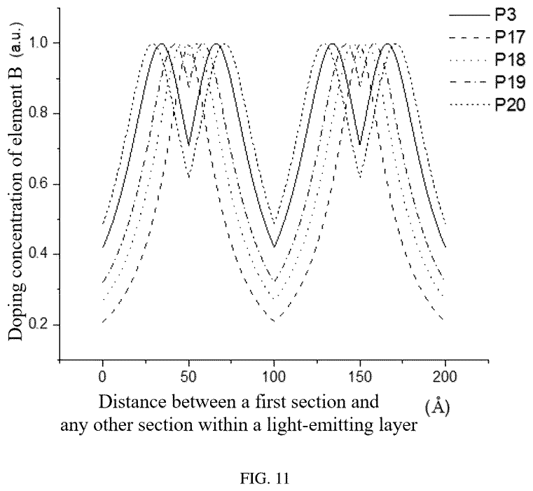

The TOF-SIMS 5-100 instrument (ION-TOF GmbH, Germany) was used to conduct Time of Flight Secondary Ion Mass Spectrometer (TOF-SIMS) to detect the intensity distribution of the element B in the light-emitting layer. FIG. 5 is a schematic diagram of distribution patterns (P1 to P6) of the dye content in a light-emitting layer of an organic electroluminescent device according to an embodiment of the present application. FIG. 6 is a schematic diagram of distribution patterns (P3, P7 and P8) of the dye content in a light-emitting layer of an organic electroluminescent device according to an embodiment of the present application. FIG. 7 is a schematic diagram of distribution patterns (P3, P9 and P10) of the dye content in a light-emitting layer of an organic electroluminescent device according to an embodiment of the present application. FIG. 8 is a schematic diagram of distribution patterns (P3 and P21 to P24) of the dye content in a light-emitting layer of an organic electroluminescent device according to an embodiment of the present application. FIG. 9 is a schematic diagram of distribution patterns (P3 and P11 to P13) of the dye content in a light-emitting layer of an organic electroluminescent device according to an embodiment of the present application. FIG. 10 is a schematic diagram of distribution patterns (P3 and P14 to P16) of the dye content in a light-emitting layer of an organic electroluminescent device according to an embodiment of the present application. FIG. 11 a schematic diagram of distribution patterns (P3 and P17 to P20) of the dye content in a light-emitting layer of an organic electroluminescent device according to an embodiment of the present application. Examples 1-6 and 9-27, and Comparative Example 2 are scanned for two cycles in a forward direction of the evaporation source (one cycle is that the line source travels to the critical point in the forward direction of the evaporation source and then returns to the initial point); Example 7 is scanned for one cycle; and Example 8 is scanned for half a cycle (i.e., the line source does not return after traveling to the critical point in the forward direction of the evaporation source). The Examples and Comparative Examples of the present application achieve the distribution patterns of the dye content of the light-emitting layer for each Example and Comparative Example by controlling the evaporation parameters (H, L a, R and the number of cycles), that is, the control of the distribution of dye content in the light-emitting layer is achieved.

TABLE 1

| | Light-emitting layer | | | | | | |
|---|---|---|---|---|---|---|---|
| | | Main | Sensitizer/ | Sensitizer | Dye/ | Dye | Thickness/ |
| | Host material | source | content wt % | source | content % | source | nm |
| Example 1 | (w-7) | S1 | T-89/30 | S3 | T17/3 | S2 | 20 |
| Example 2 | (w-7) | S1 | T-89/30 | S3 | T17/3 | S2 | 20 |
| Example 3 | (w-7) | S1 | T-89/30 | S3 | T17/3 | S2 | 20 |
| Example 4 | (w-7) | S1 | T-89/30 | S3 | T17/3 | S2 | 20 |
| Example 5 | (w-7) | S1 | T-89/30 | S3 | T17/3 | S2 | 20 |
| Example 6 | (w-7) | S1 | T-89/30 | S3 | T17/3 | S2 | 20 |
| Example 7 | (w-7) | S1 | T-89/30 | S3 | I17/3 | S2 | 20 |
| Example 8 | (w-7) | S1 | T-89/30 | S3 | T17/3 | S2 | 20 |
| Example 9 | (w-7) | S1 | T-89/30 | S3 | T17/3 | S2 | 5 |
| Example 10 | (w-7) | S1 | T-89/30 | S3 | T17/3 | S2 | 15 |
| Example 11 | (w-7) | S1 | T-89/30 | S3 | T17/3 | S2 | 40 |
| Example 12 | (w-7) | S1 | T-89/30 | S3 | T17/3 | S2 | 80 |
| Example 13 | (w-7) | S1 | T-89/30 | S3 | T17/0.05 | S2 | 20 |
| Example 14 | (w-7) | S1 | T-89/30 | S3 | T17/5 | S2 | 20 |
| Example 15 | (w-7) | S1 | T-89/30 | S3 | T17/8 | S2 | 20 |
| Example 16 | (w-7) | S1 | T-89/20 | S3 | T17/3 | S2 | 20 |
| Example 17 | (w-7) | S1 | T-89/40 | S3 | T17/3 | S2 | 20 |
| Example 18 | (w-7) | S1 | T-89/60 | S3 | T17/3 | S2 | 20 |
| Example 19 | (w-10) | S1 | T-17/30 | S3 | T18/3 | S2 | 20 |
| Example 20 | T-32 | S1 | P6/30 | S3 | T18/3 | S2 | 20 |
| Example 21 | T-32 | S1 | P6/1 | S3 | T18/3 | S2 | 20 |
| Example 22 | T-32 | S1 | P6/8 | S3 | T18/3 | S2 | 20 |
| Example 23 | T-32 | S1 | P6/15 | S3 | T18/3 | S2 | 20 |
| Example 24 | T-32 | S1 | P6/40 | S3 | T18/3 | S2 | 20 |
| Example 25 | (w-10) | S1 | T-70/30 | S3 | B-15/3 | S2 | 20 |
| Example 26 | (D-8):(A-19) | S1 | T-70/30 | S3 | B-15/3 | S2 | 20 |
| | (mass ratio | | | | | | |
| | 1:1) | | | | | | |
| Example 27 | (D-8):(A-19) | S1 | T-89/30 | S3 | T17/3 | S2 | 20 |
| | (Mass ratio | | | | | | |
| | 1:1) | | | | | | |
| Comparative | (D-8) | S4 | T-89/30 | S5 | T17/3 | S6 | 20 |
| Example 1 | | | | | | | |
| Comparative | (D-8) | S2 | T-89/30 | S3 | T17/3 | S1 | 20 |
| Example 2 | | | | | | | |

| | Light-emitting layer | | | | | | | Maximum |
|---|---|---|---|---|---|---|---|---|
| | Content distribution | H | L | α | β | D₁/ | D₂/ | external quantum |
| | pattern of dye | mm | mm | ° | ° | Dₘₐₓ | Dₘₐₓ | efficiency % |
| Example 1 | P1 | 200 | 200 | 80.0 | 24.7 | 0.07 | 0.07 | 20.1 |
| Example 2 | P2 | 300 | 200 | 80.0 | 33.5 | 0.24 | 0.24 | 24.8 |
| Example 3 | P3 | 400 | 200 | 80.0 | 40.4 | 0.42 | 0.42 | 29.7 |
| Example 4 | P4 | 500 | 200 | 80.0 | 45.7 | 0.56 | 0.56 | 29.3 |
| Example 5 | P5 | 500 | 150 | 80.0 | 52.1 | 0.70 | 0.70 | 28.1 |
| Example 6 | P6 | 500 | 70 | 85.0 | 69.8 | 0.92 | 0.92 | 22.0 |
| Example 7 | P7 | 400 | 200 | 80.0 | 40.4 | 0.42 | 0.42 | 27.6 |
| Example 8 | P8 | 400 | 200 | 80.0 | 40.4 | 0.42 | 1.00 | 23.0 |
| Example 9 | P21 | 400 | 200 | 80.0 | 40.4 | 0.42 | 0.42 | 20.5 |
| Example 10 | P22 | 400 | 200 | 80.0 | 40.4 | 0.42 | 0.42 | 27.3 |
| Example 11 | P23 | 400 | 200 | 80.0 | 40.4 | 0.42 | 0.42 | 28.0 |
| Example 12 | P24 | 400 | 200 | 80.0 | 40.4 | 0.42 | 0.42 | 22.7 |
| Example 13 | P11 | 400 | 200 | 80.0 | 40.4 | 0.40 | 0.40 | 20.1 |
| Example 14 | P12 | 400 | 200 | 80.0 | 40.4 | 0.43 | 0.43 | 26.1 |
| Example 15 | P13 | 400 | 200 | 80.0 | 40.4 | 0.45 | 0.45 | 21.7 |
| Example 16 | P14 | 400 | 200 | 80.0 | 40.4 | 0.35 | 0.35 | 25.5 |
| Example 17 | P15 | 400 | 200 | 80.0 | 40.4 | 0.49 | 0.49 | 32.4 |
| Example 18 | P16 | 400 | 200 | 80.0 | 40.4 | 0.64 | 0.64 | 21.0 |
| Example 19 | P3 | 400 | 200 | 80.0 | 40.4 | 0.42 | 0.42 | 24.5 |
| Example 20 | P3 | 400 | 200 | 80.0 | 40.4 | 0.42 | 0.42 | 27.9 |
| Example 21 | P17 | 400 | 200 | 80.0 | 40.4 | 0.21 | 0.21 | 19.8 |
| Example 22 | P18 | 400 | 200 | 80.0 | 40.4 | 0.27 | 0.27 | 20.6 |
| Example 23 | P19 | 400 | 200 | 80.0 | 40.4 | 0.32 | 0.32 | 25.7 |
| Example 24 | P20 | 400 | 200 | 80.0 | 40.4 | 0.49 | 0.49 | 24.4 |
| Example 25 | P3 | 400 | 200 | 80.0 | 40.4 | 0.42 | 0.42 | 23.4 |
| Example 26 | P3 | 400 | 200 | 80.0 | 40.4 | 0.42 | 0.42 | 25.0 |
| Example 27 | P3 | 400 | 200 | 80.0 | 40.4 | 0.42 | 0.42 | 32.1 |
| Comparative | P9 | 400 | 100 | / | / | 1.00 | 1.00 | 18.4 |
| Example 1 | | | | | | | | |
| Comparative | P10 | 400 | 200 | 80.0 | 40.4 | 1.00 | 1.00 | 14.0 |
| Example 2 | | | | | | | | |

From Table 1, it can be seen that:
1. Compared to Comparative Examples 1-2, the Examples of the present application can effectively improve the luminescence efficiency of the organic electroluminescent device by controlling the contents of dye in various sections of the light-emitting layer;
2. According to the comparison between Examples 3 and 9-12, it can be seen that when the thickness of the light-emitting layer is in a range of 10-60 nm, the luminescence efficiency of the organic electroluminescent device is more excellent;
3. According to the comparison between Examples 3 and 13-15, it can be seen that when the mass percentage content of the dye in the light-emitting layer is 0.1-5%, the luminescence efficiency of the organic electroluminescent device has a more excellent performance;
4. According to the comparison of Examples 3, 16-18, and 20-24, it can be seen that when the mass percentage of the sensitizer is greater than that of the dye, and the mass percentage of the sensitizer in the light-emitting layer is 1-50%, the luminescence efficiency of the organic electroluminescent device has more excellent performance.

Finally, it should be noted that the above embodiments are only used to illustrate the technical solution of the present application and not to limit it; although the present application has been described in detail with reference to the aforementioned embodiments, ordinary technical personnel in the art should understand that they can still make modifications on the technical solutions recorded in the aforementioned embodiments, or make equivalent replacements of some or all of the technical features; and these modifications or replacements do not make the essence of the corresponding technical solutions deviate from the scope of the technical solutions of various embodiments of the present application.

What is claimed is:

1. An organic electroluminescent device, comprising: a first functional layer, a light-emitting layer, and a second functional layer that are sequentially stacked, wherein the light-emitting layer comprises a host material, a sensitizer, and a dye; and
the light-emitting layer comprises N sections in a stacking direction, with a first section being in contact with the first functional layer and a N^{th} section being in contact with the second functional layer, N>1; among the N sections, a section with the highest dye content is the highest critical section,
wherein D1<Dₘₐₓ and D₁≤Dₒₜₕₑᵣ; and/or D_{N}<Dₘₐₓ and D_{N}≤Dₒₜₕₑᵣ, and
wherein D₁ is a dye content in the first section, D_{N} is a dye content in the N^{th} section, Dₘₐₓ is a dye content in the highest critical section, and Dₒₜₕₑᵣ is a dye content in other section.

2. The organic electroluminescent device according to claim 1, wherein 0.1≤D₁/Dₘₐₓ≤0.9.

3. The organic electroluminescent device according to claim 1, wherein 0.1≤D_{N}/Dₘₐₓ≤0.9.

4. The organic electroluminescent device according to claim 2, wherein 0.2≤D₁/Dₘₐₓ≤0.8.

5. The organic electroluminescent device according to claim 2, wherein 0.2≤D_{N}/Dₘₐₓ≤0.8.

6. The organic electroluminescent device according to claim 1, wherein the dye is a fluorescent dye containing boron element.

7. The organic electroluminescent device according to claim 6, wherein the fluorescent dye containing boron element has a structure represented by General Formula I or General Formula II, 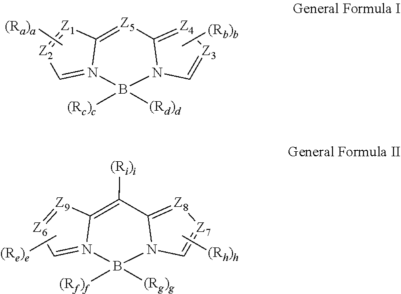
in General Formula I and General Formula II, Z₁, Z₂, Z₃, Z₄, Z₅, Z₆, Z₇, Z₅, and Z₉ are each independently selected from N or *—CR;
R, Rₐ, R_{b}, R_{c}, R_{d}, Rₑ, R_{f}, R_{g}, Rₕ, and Rᵢ are each independently selected from hydrogen atom, deuterium atom, halogen atom, cyano, hydroxyl, nitryl, amino, amidino, hydrazino, hydrazonoyl, carboxylic group or its salt, sulfonic group or its salt, phosphate group or its salt, substituted or unsubstituted silyl, substituted or unsubstituted alkyl of 1-60 carbon atoms, substituted or unsubstituted cycloalkyl of 3-30 carbon atoms, substituted or unsubstituted alkenyl of 2-60 carbon atoms, substituted or unsubstituted alkynyl of 2-60 carbon atoms, substituted or unsubstituted alkoxy of 1-60 carbon atoms, substituted or unsubstituted heterocyclic alkyl of 3-10 carbon atoms, substituted or unsubstituted cycloalkenyl of 3-10 carbon atoms, substituted or unsubstituted heterocyclic alkenyl of 1-10 carbon atoms, substituted or unsubstituted aryloxy of 6-60 carbon atoms, substituted or unsubstituted aryl thiol of 6-60 carbon atoms, substituted or unsubstituted aryl of 6-60 ring-forming carbon atoms, or substituted or unsubstituted heteroaryl of 2-60 ring-forming carbon atoms, substituted or unsubstituted group capable of binding to adjacent group to form a ring, *—Si(Q₁)(Q₂)(Q₃), *—B(Q₁)(Q₂), *—N(Q₁)(Q₂), *—P(Q₁)(Q₂), *—C(═O)(Q₁), *—S₂(Q₁)(Q₃), *—P(═O)(Q₁)(Q₂), and *—P(═S)(Q₁)(Q₂); Q₁, Q₂, and Q₃ are each independently selected from hydrogen atom, deuterium atom, halogen atom, cyano, hydroxyl, nitryl, amino, amidino, hydrazino, hydrazonoyl, C1-C60 alkyl, C2-C60 alkenyl, C2-C60 alkynyl, C1-C60 alkoxy, C3-C10 cycloalkyl, C1-C10 heterocyclic alkyl, C3-C10 cycloalkenyl, C1-C10 heterocyclic alkenyl, C6-C60 aryl, C6-C60 aryloxy, C6-C60 aryl thiol, C1-C60 heteroaryl, C1-C60 heteroaryloxy, C1-C60 heteroaryl thiol, univalent non-aromatic fused polycyclic group, univalent non-aromatic fused heteropolycyclic group, biphenyl group, and triphenyl group; and
a. b, c, d, e, f, g, h, and i are each independently an integer greater than or equal to 0.

8. The organic electroluminescent device according to claim 7, wherein a compound of the fluorescent dye containing boron element is selected from compounds represented by B-1 to B-17,

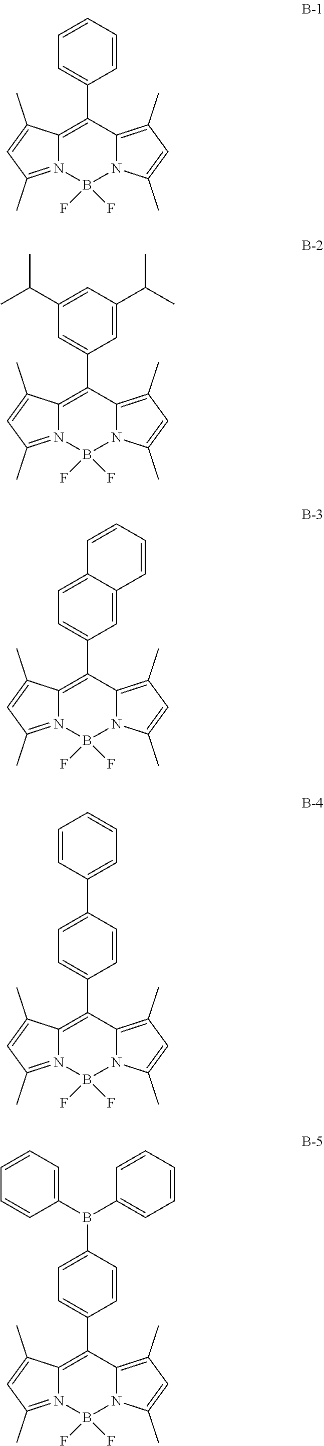

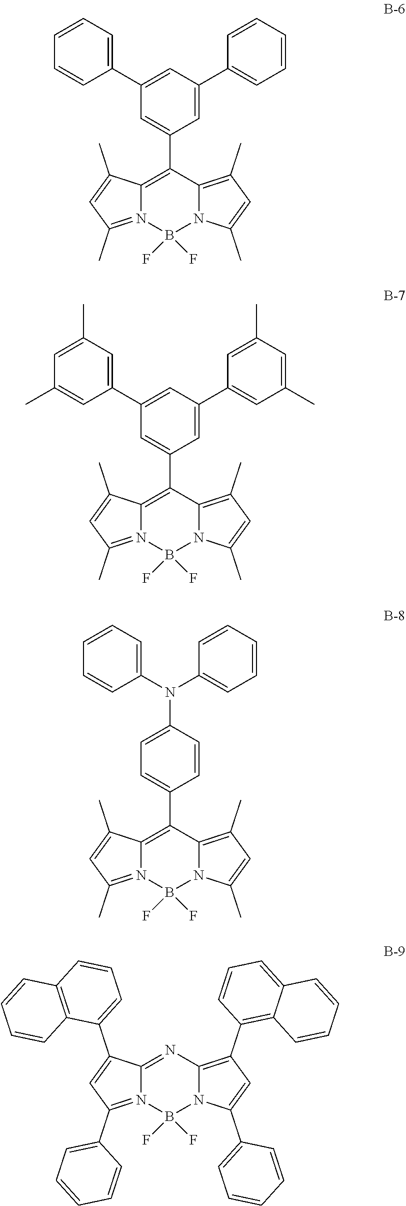

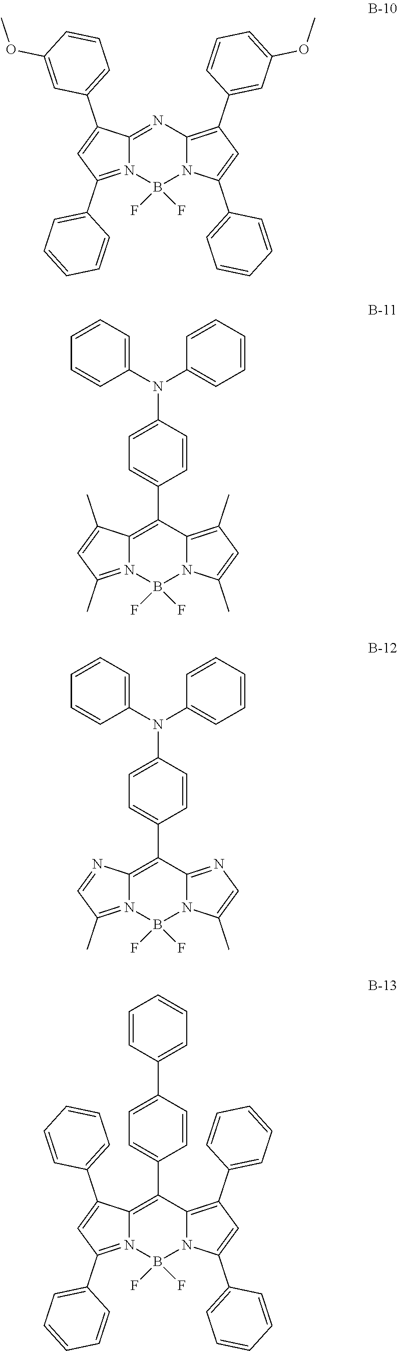

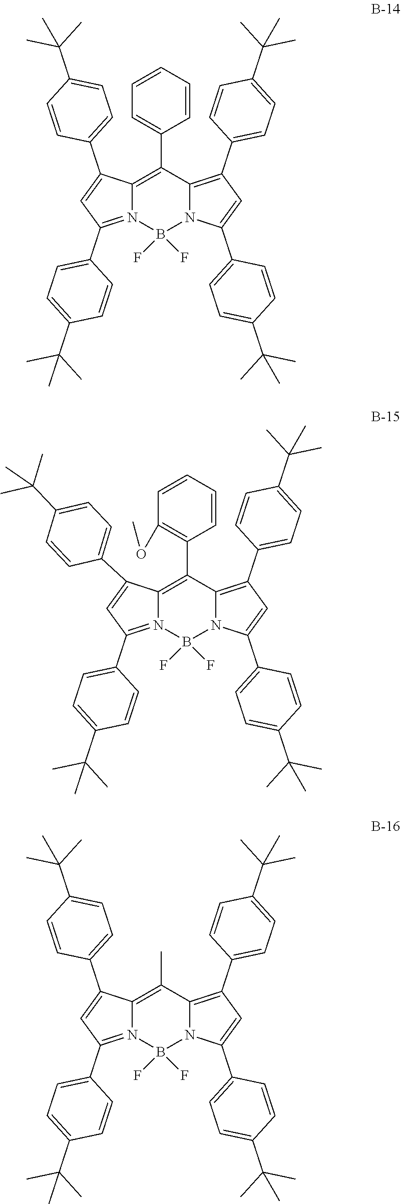

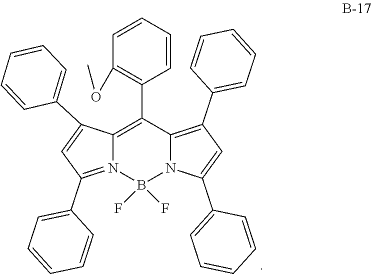

9. The organic electroluminescent device according to claim 1, wherein the dye is a resonant type TADF material containing boron element.

10. The organic electroluminescent device according to claim 9, wherein the resonant type TADF material containing boron element has a structure represented by General Formula III, General Formula IV, or General Formula V, 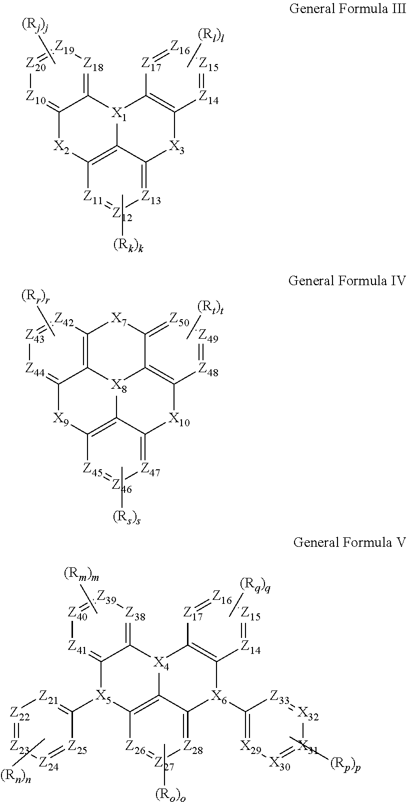
in General Formula III, General Formula IV, and General Formula V, X₁, X₄, X₅, X₆, and X₈ are each independently selected from B, N, P, P═O, *—P═S, Al, Ga, As, *—SiR₁, or *—GeR₁, with at least one B atom being present; R₁ is an aryl with a carbon number of 6-12 or an alkyl with a carbon number of 1-6; X₂, X₃, X₇, X₉, and X₁₀ are each independently selected from O, *—NR₂, S, or Se; R₂ is an aryl with a carbon number of 6-12, a heteroaryl with a carbon number of 2-15, or an alkyl with a carbon number of 1-6; Z₁-Z₅₀ are each independently selected from N or *—CR; the definitions of R and Rⱼ-Rₜ are same as those of R and Rₐ-Rᵢ in the General Formula I respectively, and j to t are each independently an integer greater than or equal to 0.

11. The organic electroluminescent device according to claim 1, wherein the sensitizer is selected from a TADF material or a phosphorescent material.

12. The organic electroluminescent device according to claim 1, wherein the host material is selected from one of a wide-band-gap material, a TADF material, or a combination of a N-type material and a P-type material.

13. The organic electroluminescent device according to claim 12, wherein the host material is an exciplex comprising the P-type material and the N-type material.

14. The organic electroluminescent device according to claim 1, wherein a mass percentage content of the dye in the light-emitting layer is less than or equal to that of the sensitizer in the light-emitting layer.

15. The organic electroluminescent device according to claim 1, wherein a mass percentage content of the dye in the light-emitting layer is 0.1-5%, and a mass percentage content of the sensitizer in the light-emitting layer is 1-50%.

16. The organic electroluminescent device according to claim 1, wherein the light-emitting layer has a thickness of 10-60 nm.

17. A display device, comprising the organic electroluminescent device according to claim 1.

18. The display device according to claim 17, wherein 0.1≤D₁/Dₘₐₓ≤0.9.

19. The display device according to claim 17, wherein 0.1≤D_{N}/Dₘₐₓ≤0.9.

20. The display device according to claim 18, wherein 0.2≤D₁/Dₘₐₓ≤0.8.
